(19) United States
(12) Patent Application Publication
(10) Pub. No.: US 2014/0319591 A1
(43) Pub. Date: Oct. 30, 2014

(54) SEMICONDUCTOR DEVICE AND MANUFACTURING METHOD THEREOF

(71) Applicant: Renesas Electronics Corporation, Kawasaki-shi (JP)

(72) Inventor: Takeshi TODA, Kanagawa (JP)

(73) Assignee: Renesas Electronics Corporation, Kawasaki-shi (JP)

(21) Appl. No.: 14/251,947

(22) Filed: Apr. 14, 2014

(30) Foreign Application Priority Data
Apr. 24, 2013 (JP) 2013-091693

(51) Int. Cl. H01L 27/07; H01L 49/02; H01L 21/8234

(52) U.S. Cl. CPC H01L 27/0733; H01L 21/8234; H01L 28/40
USPC 257/296; 438/241

(57) ABSTRACT

In an interlayer insulating film in which contact plugs are embedded, a capacitor element is formed which has electrodes each formed of a metal. Over a substrate, the interlayer insulating film is formed. The interlayer insulating film includes a first insulating film and a second insulating film. In the second insulating film, the first and second contact plugs are formed. The first and second contact plugs extend through the second insulating film to reach first and second gate electrodes. In a surface of the substrate, an isolation film is formed. Within a region overlapping the isolation film in planar view, the capacitor element is formed. The capacitor element includes the lower and upper electrodes. Each of the lower and upper electrodes contains a metal. The lower and upper electrodes of the capacitor element are formed over the first insulating film to be embedded in the second insulating film.

### CROSS-REFERENCE TO RELATED APPLICATIONS

The disclosure of Japanese Patent Application No. 2013-091693 filed on Apr. 24, 2013 including the specification, drawings and abstract is incorporated herein by reference in its entirety.

### BACKGROUND

The present invention relates to a semiconductor device and a manufacturing method thereof and is a technology applicable to, e.g., an analog circuit.

For a semiconductor device including a capacitor element, various structures have been proposed at present. In Patent Documents 1 to 5, semiconductor devices each including a capacitor element are described. In each of the semiconductor devices described in Patent documents 1 and 2, the capacitor element is formed between interlayer insulations formed with a MISFET (Metal-Insulator-Semiconductor Field-Effect Transistor). In each of the semiconductor devices described in Patent Documents 1 and 2, the gate electrode of the MISFET and the upper electrode of the capacitor element are formed of the same material. Also, in each of the semiconductor devices described in Patent Documents 1 and 2, for the gate electrode and the upper electrode of the capacitor element, polysilicon is used.

In the semiconductor device described in Patent Document 3, the capacitor element is formed in an interlayer insulating film formed with a transistor. In the semiconductor device described in Patent Document 3, the transistor includes a first gate electrode and a second gate electrode. The second gate electrode is formed over the first gate electrode. On the other hand, the capacitor element includes a lower electrode and an upper electrode. In the semiconductor device described in Patent Document 3, the first gate electrode and the lower electrode are formed of the same material, while the second gate electrode and the upper electrode are formed of the same material.

In the semiconductor device described in Patent Document 4, the capacitor element is formed in an interlayer insulating film formed with a CMOS (Complementary Metal Oxide Semiconductor). In the semiconductor device described in Patent Document 4, the CMOS includes a first gate electrode and a second gate electrode. The second gate electrode is formed over the first gate electrode. On the other hand, the capacitor element includes a lower electrode and an upper electrode. In the semiconductor device described in Patent Document 4, the first gate electrode and the lower electrode are formed of the same material, while the second gate electrode and the upper electrode are formed of the same material.

In the semiconductor device described in Patent Document 5, the capacitor element is formed over a field oxide film. The field oxide film has a lattice-shaped insulating layer in a range where the lattice-shaped insulating layer overlaps the lower electrode of the capacitor element. The lattice-shaped insulating layer has a trench formed in a two-dimensional lattice shape. The trench is filled with an insulating material.

### RELATED ART DOCUMENTS

### Patent Documents

### [Patent Document 1]

Japanese Unexamined Patent Publication No. 2005-203455

### [Patent Document 2]

Japanese Unexamined Patent Publication No. 2012-99530

### [Patent Document 3]

Japanese Unexamined Patent Publication No. 2010-10507

### [Patent Document 4]

Japanese Unexamined Patent Publication No. 2005-150712

### [Patent Document 5]Japanese Patent No. 4159692

### SUMMARY

In an interlayer insulating film formed with a contact plug coupled to the gate electrode of a transistor, a capacitor element may be formed. In this case, each of the electrodes of the capacitor element preferably contains a metal. The present inventors have studied a configuration for forming each of the electrodes of such a capacitor element of a metal.

Other problems and novel features of the present invention will become apparent from a statement in the present specification and the accompanying drawings.

According to an embodiment, an interlayer insulating film is formed over a substrate. The interlayer insulating film includes a first insulating film and a second insulating film. The second insulating film is formed over the first insulating film. The second insulating film is formed with a contact plug. The contact plug extends through the second insulating film to reach the gate electrode of a transistor. The gate electrode contains a metal. In a surface of the substrate, an isolation film is formed. Within a region overlapping the isolation film in planar view, a capacitor element is formed. The capacitor element includes a lower electrode and an upper electrode. Each of the lower electrode and the upper electrode contains a metal. The upper electrode is formed over the lower electrode. Each of the lower electrode and the upper electrode of the capacitor element is formed over the first insulating film to be embedded in the second insulating film.

According to another example, a first transistor and a second transistor are formed over a substrate. The channel of the first transistor and the channel of the second transistor have different conductivity types. The first transistor and the second transistor respectively include a first gate electrode and a second gate electrode. Each of the first gate electrode and the second gate electrode contains a metal. The lower electrode of the capacitor element and the first gate electrode of the first transistor are formed of the same material. The upper electrode of the capacitor element and the second gate electrode of the second transistor are formed of the same material.

According to still another example, the first insulating film has a sidewall formed within a region overlapping the isolation film in planar view. The first insulating film is formed with an opening defined by an inner wall of the sidewall. The lower electrode of the capacitor element is formed to be embedded in the opening.

According to the embodiment, in the interlayer insulating film having the contact plug embedded therein, a capacitor element can be formed which has electrodes each containing a metal.

### BRIEF DESCRIPTION OF THE DRAWINGS

FIG. 1A is a cross-sectional view showing a semiconductor device according to a first embodiment, and FIG. 1B is a two-dimensional perspective view of the semiconductor device according to the first embodiment;

FIGS. 2A and 2B are cross-sectional views each showing a manufacturing method of the semiconductor device shown in FIGS. 1A and 1B;

FIGS. 3A and 3B are cross-sectional views each showing the manufacturing method of the semiconductor device shown in FIGS. 1A and 1B;

FIGS. 4A and 4B are cross-sectional views each showing the manufacturing method of the semiconductor device shown in FIGS. 1A and 1B;

FIGS. 5A and 5B are cross-sectional views each showing the manufacturing method of the semiconductor device shown in FIGS. 1A and 1B;

FIGS. 6A and 6B are cross-sectional views each showing the manufacturing method of the semiconductor device shown in FIGS. 1A and 1B;

FIGS. 7A and 7B are cross-sectional views each showing the manufacturing method of the semiconductor device shown in FIGS. 1A and 1B;

FIGS. 8A and 8B are cross-sectional views each showing the manufacturing method of the semiconductor device shown in FIGS. 1A and 1B;

FIGS. 9A and 9B are cross-sectional views each showing the manufacturing method of the semiconductor device shown in FIGS. 1A and 1B;

FIGS. 10A and 10B are cross-sectional views each showing the manufacturing method of the semiconductor device shown in FIGS. 1A and 1B;

FIGS. 11A and 11B are cross-sectional views each showing the manufacturing method of the semiconductor device shown in FIGS. 1A and 1B;

FIGS. 12A and 12B are cross-sectional views each showing the manufacturing method of the semiconductor device shown in FIGS. 1A and 1B;

FIG. 13A is a cross-sectional view showing a semiconductor device according to another example of the first embodiment, and FIG. 13B is a two-dimensional perspective view of the semiconductor device according to the other example of the first embodiment;

FIGS. 14A and 14B are cross-sectional views each showing a manufacturing method of the semiconductor device shown in FIGS. 13A and 13B;

FIG. 15A is a cross-sectional view showing a semiconductor device according to still another example of the first embodiment, and FIG. 15B is a two-dimensional perspective view of the semiconductor device according to the still other example of the first embodiment;

FIGS. 16A and 16B are cross-sectional views each showing a manufacturing method of the semiconductor device shown in FIGS. 15A and 15B;

FIG. 17A is a cross-sectional view showing a semiconductor device according to a second embodiment, and FIG. 17B is a two-dimensional perspective view of the semiconductor device according to the second embodiment;

FIGS. 18A and 18B are cross-sectional views each showing a manufacturing method of the semiconductor device shown in FIGS. 17A and 17B;

FIGS. 19A and 19B are cross-sectional views each showing the manufacturing method of the semiconductor device shown in FIGS. 17A and 17B;

FIGS. 20A and 20B are cross-sectional views each showing the manufacturing method of the semiconductor device shown in FIGS. 17A and 17B;

FIG. 21A is a cross-sectional view showing a semiconductor device according to another example of the second embodiment, and FIG. 21B is a two-dimensional perspective view of the semiconductor device according to the other example of the second embodiment;

FIG. 22A is a cross-sectional view showing a semiconductor device according to still another example of the second embodiment, and FIG. 22B is a two-dimensional perspective view of the semiconductor device according to the still other example of the second embodiment;

FIG. 23A is a cross-sectional view showing a semiconductor device according to a third embodiment, and FIG. 23B is a two-dimensional perspective view of the semiconductor device according to the third embodiment;

FIGS. 24A and 24B are cross-sectional views each showing a manufacturing method of the semiconductor device shown in FIGS. 23A and 23B;

FIGS. 25A and 25B are cross-sectional views each showing the manufacturing method of the semiconductor device shown in FIGS. 23A and 23B;

FIGS. 26A and 26B are cross-sectional views each showing the manufacturing method of the semiconductor device shown in FIGS. 23A and 23B;

FIGS. 27A and 27B are cross-sectional views each showing the manufacturing method of the semiconductor device shown in FIGS. 23A and 23B;

FIGS. 28A and 28B are cross-sectional views each showing the manufacturing method of the semiconductor device shown in FIGS. 23A and 23B;

FIGS. 29A and 29B are cross-sectional views each showing the manufacturing method of the semiconductor device shown in FIGS. 23A and 23B;

FIGS. 30A and 30B are cross-sectional views each showing the manufacturing method of the semiconductor device shown in FIGS. 23A and 23B;

FIGS. 31A and 31A are cross-sectional views each showing the manufacturing method of the semiconductor device shown in FIGS. 23A and 23B;

FIGS. 32A and 32B are cross-sectional views each showing the manufacturing method of the semiconductor device shown in FIGS. 23A and 23B;

FIG. 33A is a cross-sectional view showing a semiconductor device according to another example of the third embodiment, and FIG. 33B is a two-dimensional perspective view of the semiconductor device according to the other example of the third embodiment;

FIGS. 34A and 34B are cross-sectional views each showing a manufacturing method of the semiconductor device shown in FIGS. 33A and 33B;

FIG. 35A is a cross-sectional view showing a semiconductor device according to still another example of the third embodiment, and FIG. 35B is a two-dimensional perspective view of the semiconductor device according to the still other example of the third embodiment;

FIGS. 36A and 36B are cross-sectional views each showing a manufacturing method of the semiconductor device shown in FIGS. 35A and 35B;

FIG. 37A is a cross-sectional view showing a semiconductor device according to a fourth embodiment, and FIG. 37B is a two-dimensional perspective view of the semiconductor device according to the fourth embodiment;

FIGS. 38A and 38B are cross-sectional views each showing a manufacturing method of the semiconductor device shown in FIGS. 37A and 37B;

FIGS. 39A and 39B are cross-sectional views each showing the manufacturing method of the semiconductor device shown in FIGS. 37A and 37B;

FIGS. 40A and 40B are cross-sectional views each showing the manufacturing method of the semiconductor device shown in FIGS. 37A and 37B;

FIGS. 41A and 41B are cross-sectional views each showing the manufacturing method of the semiconductor device shown in FIGS. 37A and 37B;

FIGS. 42A and 42B are cross-sectional views each showing the manufacturing method of the semiconductor device shown in FIGS. 37A and 37B;

FIGS. 43A and 43B are cross-sectional views each showing the manufacturing method of the semiconductor device shown in FIGS. 37A and 37B;

FIGS. 44A and 44B are cross-sectional views each showing the manufacturing method of the semiconductor device shown in FIGS. 37A and 37B;

FIG. 45A is a cross-sectional view showing a semiconductor device according to another example of the fourth embodiment, and FIG. 45B is a two-dimensional perspective view of the semiconductor device according to the other example of the fourth embodiment; and

FIG. 46A is a cross-sectional view showing a semiconductor device according to still another example of the fourth embodiment, and FIG. 45B is a two-dimensional perspective view of the semiconductor device according to the still other example of the fourth embodiment.

### DETAILED DESCRIPTION

A description will be given below of embodiments using the drawings. Throughout all the drawings, like components are designated by like reference numerals and a description thereof is omitted appropriately.

### First Embodiment

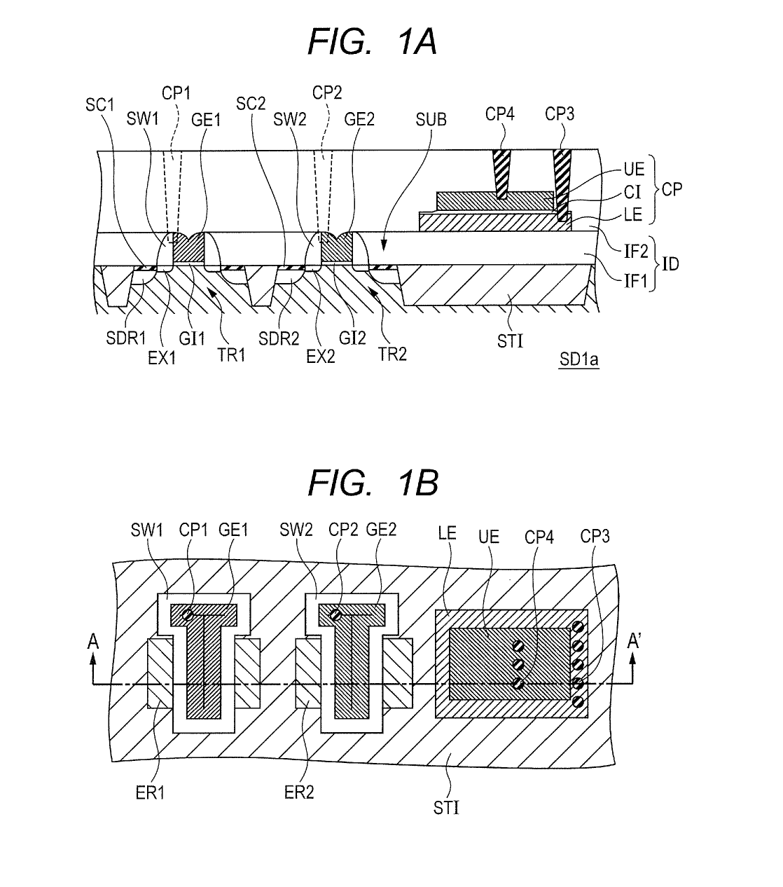

FIG. 1A is a cross-sectional view of a semiconductor device SD1a in a first embodiment. FIG. 1B is a two-dimensional perspective view of the semiconductor device SD1a in the present embodiment. FIG. 1A is a cross-sectional view along the line A-A′ of FIG. 1B.

As shown in FIGS. 1A and 1B, the semiconductor device SD1a includes a first transistor TR1, a second transistor TR2, an interlayer insulating film ID, a first contact plug CP1, a second contact plug CP2, an isolation film STI, and a capacitor element CP. The first transistor TR1 is formed over a substrate SUB. The second transistor T2 is also formed over the substrate SUB. The channel of the second transistor TR2 has a conductivity type different from that of the channel of the first transistor TR1. The interlayer insulating film ID is formed over the substrate SUB. The interlayer insulating film ID is formed over the substrate SUB. The interlayer insulating film ID covers the first transistor TR1 and the second transistor TR2. The first transistor TR1 includes a first gate electrode GE1 and a first source/drain region SDR1. The first gate electrode GE1 is formed over the substrate SUB. The first gate electrode GE1 contains a metal. The first source/drain region SDR1 is formed in a surface of the substrate SUB in lateral relation to the first gate electrode GE1. The second transistor TR2 includes a second gate electrode GE2 and a second source/drain region SDR2. The second gate electrode GE2 is formed over the substrate SUB. The second gate electrode GE2 contains a metal. The second source/drain region SDR2 is formed in the surface of the substrate SUB in lateral relation to the second gate electrode GE2. The interlayer insulating film ID includes a first insulating film IF1 and a second insulating film IF2. The first insulating film IF1 is formed over the first source/drain region SDR1 and the second source/drain region SDR2. The second insulating film IF2 is formed over the first insulating film IF1. The first contact plug CP1 extends through the second insulating film IF2 to reach the first gate electrode GE1. The second contact plug CP2 extends through the second insulating film IF2 to reach the second gate electrode GE2. The isolation film STI is formed in the surface of the substrate SUB. The capacitor element CP is formed within the region overlapping the isolation film STI in planar view. The capacitor element CP includes a lower electrode LE, an upper electrode UE, and a capacitor insulating film CI. Each of the lower electrode LE and the upper electrode UE contains a metal. The upper electrode UE is formed over the lower electrode LE. The capacitor insulating film CI is formed between the lower electrode LE and the upper electrode UE. The lower electrode LE and the upper electrode UE are formed over the first insulating film IF1 to be embedded in the second insulating film IF2.

In the semiconductor device SD1a, each of the lower electrode IE and the upper electrode UE of the capacitor element CP contains a metal. Thus, in the present embodiment, in the interlayer insulating film ID, the capacitor element CP can be formed which has the electrodes each containing a metal.

Using FIGS. 1A and 1B, a detailed description will be given of the semiconductor device SD1a. In the surface of a substrate SUB, the isolation film STI is formed. As a result, in the surface of the substrate SUB, an element formation region ER1 and an element formation region ER2 are defined, as shown in FIG. 1B. The element formation region ER1 and the element formation region ER2 are electrically insulated from each other by the isolation film STI. In the element formation region ER1, the first transistor TR1 is formed. On the other hand, in the element formation region ER2, the second transistor TR2 is formed. The first transistor TR1 and the second transistor TR2 have channels of different conductivity types. In the present embodiment, the first transistor TR1 is an n-type-channel transistor. On the other hand, the second transistor TR2 is a p-type-channel transistor. In this case, the element formation region ER1 is a p-type well. On the other hand, the element formation region ER2 is an n-type well. The substrate SUB may also be a semiconductor substrate (e.g., a silicon substrate). Over the isolation film STI, the capacitor element CP is formed.

The first transistor TR1 includes the first gate electrode GE1 and the first source/drain region SDR1. The first transistor TR1 also includes a first gate insulating film GI1, a first silicide film SC1, a first sidewall SW1, and a first extension region EX1. The first gate insulating film GI1 is formed over the substrate SUB. The first gate insulating film GI1 may be formed of a silicon dioxide film (SiO₂), a silicon oxynitride film (SiON film), or a high-dielectric-constant film (e.g., a hafnium silicate film (HfSiO) or a nitrogen-added hafnium silicate film). The thickness of the first gate insulating film GI1 is, e.g., 1 nm to 50 nm. The first gate electrode GE1 is formed over the substrate SUB via the first gate insulating film GI1. The first gate electrode GE1 contains a metal. In the present embodiment, the first gate electrode GE1 is formed of a metal or a metal compound (e.g., a metal nitride, a metal carbide, or a silicide). The thickness of the first gate electrode GE1 is, e.g., 100 nm. Over the respective side surfaces of the first gate insulating film GI1 and the first gate electrode GE1, the first sidewall SW1 is formed. The first sidewall SW1 is formed of an insulating film. The first sidewall SW1 may be formed of an oxide film (e.g., a silicon dioxide film). On both sides of the first gate electrode GE1, in the surface of the substrate SUB, the first source/drain region SDR1 is formed. In the present embodiment, the conductivity type of the first source/drain region SDR1 is an n-type. In the first source/drain region SDR1, over the surface of the substrate SUB, the first silicide film SC1 is formed. The first silicide film SC1 may be formed of a Ni silicide, a Pt silicide, a Co silicide, a Ti silicide, or a Ni silicide containing Pt (Ni₁₋ₓPtₓSi (0<x<1)). In planar view, between the first gate electrode GE1 and the first source/drain region SDR1, the first extension region EX1 is formed. In the present embodiment, the conductivity type of the first extension region EX1 is an n-type.

The second transistor TR2 includes the second gate electrode GE2 and the second source/drain region SDR2. The second transistor TR2 also includes a second gate insulating film GI2, a second silicide film SC2, a second sidewall SW2, and a second extension region EX2. The second gate insulating film GI2 is formed over the substrate SUB. The second gate insulating film GI2 may be formed of a silicon dioxide film (SiO₂), a silicon oxynitride film (SiON film), or a high-dielectric-constant film (e.g., a hafnium silicate film (HfSiO) or a nitrogen-added hafnium silicate film). The thickness of the second gate insulating film GI2 is, e.g., 1 nm to 50 nm. The second gate electrode GE2 is formed over the substrate SUB via the second gate insulating film GI2. The second gate electrode GE2 contains a metal. In the present embodiment, the second gate electrode GE2 is formed of a metal or a metal compound (e.g., a metal nitride, a metal carbide, or a silicide). The thickness of the second gate electrode GE2 is, e.g., 100 nm. Over the respective side surfaces of the second gate insulating film GI2 and the second gate electrode GE2, the second sidewall SW2 is formed. The second sidewall SW2 is formed of an insulating film. The second sidewall SW2 may be formed of an oxide film (e.g., a silicon dioxide film). On both sides of the second gate electrode GE2, in the surface of the substrate SUB, the second source/drain region SDR2 is formed. In the present embodiment, the conductivity type of the second source/drain region SDR2 is a p-type. In the second source/drain region SDR2, over the surface of the substrate SUB, the second silicide film SC2 is formed. The second silicide film SC2 may be formed of a Ni silicide, a Pt silicide, a Co silicide, a Ti silicide, or a Ni silicide containing Pt (Ni₁₋ₓPtₓSi (0<x<1)). In planar view, between the second gate electrode GE2 and the second source/drain region SDR2, the second extension region EX2 is formed. In the present embodiment, the conductivity type of the second extension region EX2 is a p-type.

The first transistor TR1 and the second transistor TR2 are covered with the interlayer insulating film ID. The interlayer insulating film ID is formed over the substrate SUB. The interlayer insulating film ID may also be formed of a silicon dioxide film or a low-dielectric-constant film. The interlayer insulating film ID includes the first insulating film IF1 and the second insulating film IF2. The second insulating film IF2 is formed over the first insulating film IF1. The height of the position at which the interface between the first insulating film IF1 and the second insulating film IF2 is formed may also be the same as the height of the top of each of the first sidewall SW1 and the second sidewall SW2, as shown in FIG. 1A.

In the second insulating film IF2, the first contact plug CP1 and the second contact plug CP2 are formed. The first contact plug CP1 extends through the second insulating film IF2 to reach the first gate electrode GE1. The first contact plug CP1 may also reach an inner portion of the first gate electrode GE1. The second contact plug CP2 extends through the second insulating film IF2 to reach the second gate electrode GE2. The second contact plug CP2 may also reach an inner portion of the second gate electrode GE2. Each of the first contact plug CP1 and the second contact plug CP2 is formed of a conductive member. For the conductive member, a metal (e.g., copper or tungsten) or polysilicon may be used.

The capacitor element CP includes the lower electrode LE, the capacitor insulating film CI, and the upper electrode UE. The upper electrode UE is formed over the lower electrode LE. The capacitor insulating film CI is formed between the lower electrode LE and the upper electrode UE. Each of the lower electrode LE and the upper electrode UE contains a metal. In the present embodiment, each of the lower electrode LE and the upper electrode UE is formed of a metal or a metal compound (e.g., a metal nitride, a metal carbide, or a silicide). The capacitor element CP is formed within the region overlapping the isolation film STI in planar view. Each of the lower electrode LE and the upper electrode UE is formed over the first insulating film IF1 to be embedded in the second insulating film IF2.

To the lower electrode LE, a third contact plug CP3 is coupled. To the upper electrode UE, a fourth contact plug CP4 is coupled. The third contact plug CP3 extends through the second insulating film IF2 to reach the lower electrode LE. The third contact plug CP3 may also reach an inner portion of the lower electrode LE. The fourth contact plug CP2 extends through the second insulating film IF2 to reach the upper electrode UE. The fourth contact plug CP4 may also reach an inner portion of the upper electrode UE. Each of the third contact plug CP3 and the fourth contact plug CP4 is formed of a conductive member. For the conductive member, a metal (e.g., copper or tungsten) or polysilicon may be used. It may also be possible to form a plurality of the third contact plugs CP3. In this case, as shown in FIG. 1B, the third contact plugs CP3 may also be formed on a straight line parallel with the extending direction of each of the first gate electrode GE1 and the second gate electrode GE2. It may also be possible to form a plurality of the fourth contact plugs CP4. In this case, as shown in FIG. 1B, the fourth contact plugs CP4 may also be formed on a straight line parallel with the extending direction of each of the first gate electrode GE1 and the second gate electrode GE2.

In the present embodiment, each of the lower electrode LE and the upper electrode UE is formed in a flat plate shape. Also, in the present embodiment, the lower electrode LE and the upper electrode UE are arranged to be parallel with each other with respect to the surface direction of the substrate SUB. The shape of each of the lower electrode LE and the upper electrode UE in planar view is not particularly limited and may also be, e.g., a polygon (e.g., a rectangle) or a circle. In the present embodiment, each of the lower electrode LE and the upper electrode UE is formed to have a rectangular shape in planar view, as shown in FIG. 1B. In the present embodiment, the area of the lower electrode LE in planar view is larger than the area of the upper electrode UE in planar view, as shown in FIG. 1B. As shown in FIG. 1B, the upper electrode UE is formed within the region overlapping the lower electrode LE in planar view. This allows the third contact plugs CP3 to be coupled to the surface of the lower electrode LE at positions at which the upper electrode UE does not overlap the lower electrode LE.

In the present embodiment, a sidewall surrounding the lower electrode LE in planar view is not formed. Accordingly, the edge portion of the lower electrode LE in planar view is in direct contact with the second insulating film IF2. Likewise, in the present embodiment, a sidewall surrounding the upper electrode UE in planar view is not formed. Accordingly, the edge portion of the upper electrode UE in planar view is in direct contact with the second insulating film IF2.

The capacitor insulating film CI is formed of an insulating film. For the insulating film, a silicon dioxide film, a silicon nitride film, or a metal oxide (e.g., tantalum oxide, zirconium oxide, hafnium oxide, lanthanum oxide, or yttrium oxide) may be used. The thickness of the capacitor insulating film CI is determined by a capacitance/breakdown voltage required of the capacitor element CP. In the present embodiment, the thickness of the capacitor insulating film CI is about 5 nm to 100 nm. In the present embodiment, the thickness of the capacitor insulating film CI at a position at which the upper electrode UE does not overlap the capacitor insulating film CI in planar view may be smaller than the thickness of the capacitor insulating film CI at a position at which the upper electrode UE overlaps the capacitor insulating film CI in planar view, as shown in FIG. 1A. Note that, when the capacitor insulating film CI is formed at a position at which the upper electrode UE does not overlap the capacitor insulating film CI in planar view, each of the third contact plugs CP3 extends through the capacitor insulating film CI to be coupled to the lower electrode LE, as shown in FIG. 1A.

In the present embodiment, the lower electrode LE and the first gate electrode GE1 are formed of the same material. Likewise, the upper electrode EU and the second gate electrode GE2 are formed of the same material. In the present embodiment, each of the lower electrode LE and the first gate electrode GE1 contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x< and 0<y<1). On the other hand, each of the upper electrode UE and the second gate electrode GE2 contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1). The metal or metal compound of each of the lower electrode LE and the first gate electrode GE1 and the metal or metal compound of each of the upper electrode UE and the second gate electrode GE2 may also be formed of different elements. In another example, the metal or metal compound of each of the lower electrode LE and the first gate electrode GE1 and the metal or metal compound of each of the upper electrode UE and the second gate electrode GE2 may also be formed of a plurality of identical elements and have different composition ratios. In this case, when, e.g., the metal of each of the lower electrode LE and the first gate electrode GE1 and the metal of each of the upper electrode UE and the second gate electrode GE2 are each represented by, e.g., TiₓN₁₋ₓ, it follows that the value of x in each of the lower electrode LE and the first gate electrode GE1 is different from the value of x in each of the upper electrode UE and the second gate electrode GE2. In still another example, the metal or metal compound of each of the lower electrode LE and the first gate electrode GE1 and the metal or metal compound of each of the upper electrode UE and the second gate electrode GE2 may also be formed of a plurality of identical elements and have the same composition ratio. In the present embodiment, the thickness of the lower electrode LE is about 5 nm to 200 nm. On the other hand, the thickness of the upper electrode UE is about 5 nm to 200 nm.

In the present embodiment, each of the first gate electrode GE1 and the second gate electrode GE2 is formed in a letter-T shape in planar view, as shown in FIG. 1B. Each of the first sidewall SW1 and the second sidewall SW2 is formed in a letter-T shape so as to surround the first gate electrode GE1 and the second gate electrode GE2 in planar view. In the present embodiment, as shown in FIG. 1B, the first contact plug CP1 may also be coupled to the first gate electrode GE1 in the region not overlapping the element formation region ER1 in planar view. Likewise, as shown in FIG. 1B, the second contact plug CP2 may also be coupled to the second gate electrode GE2 in the region not overlapping the element formation region ER2 in planar view.

In the semiconductor device SD1a, each of the lower electrode LE and upper electrode UE of the capacitor element CP contains a metal. Thus, in the present embodiment, in the interlayer insulating film ID, the capacitor element CP can be formed which has the electrodes each containing a metal.

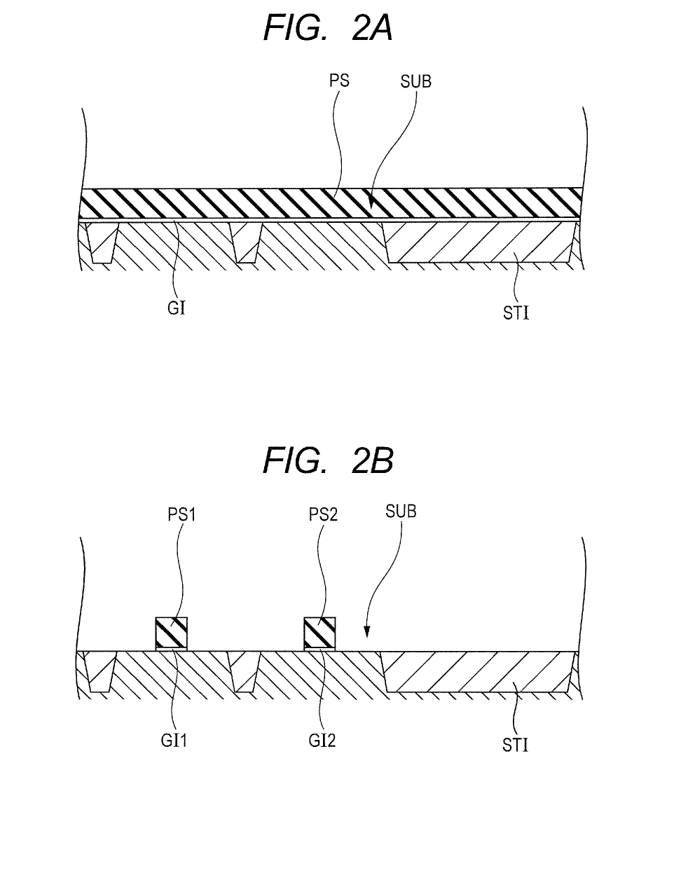

Next, using FIGS. 2A to 12B, a detailed description will be given of a manufacturing method of the semiconductor device SD1a in the present embodiment. FIGS. 2A to 12B are cross-sectional views showing the manufacturing method of the semiconductor device SD1a in the present embodiment.

First, in the substrate SUB, the isolation film STI is formed. This defines the element formation regions ER1 and ER2. For the substrate SUB, a semiconductor device (e.g., a silicon substrate) may also be used. In the present embodiment, the isolation film STI is formed of STI (Shallow Trench Isolation). Next, by ion implantation, the element formation region ER1 is doped with a p-type impurity and the element formation region ER2 is doped with an n-type impurity. As a result, in the element formation region ER1, a p-type well is formed while, in the element formation region ER2, an n-type well is formed. As the impurity with which the element formation region ER1 is to be doped, boron may be used. On the other hand, as the impurity with which the element formation region ER2 is to be doped, phosphorus or arsenic may be used. Next, over the substrate SUB, the insulating film GI is formed. Of the insulating film GI, each of the first gate insulating film GI1 and the second gate insulating film GI2 is formed. The insulating film GI may be formed of a silicon dioxide film (SiO₂), a silicon oxynitride film (SiON film), or a high-dielectric-constant film (e.g., a hafnium silicate film (HfSiO) or a nitrogen-added hafnium silicate film). The thickness of the insulating film GI may be controlled to be, e.g., 1 nm to 50 nm. Then, over the insulating film GI, the polysilicon film PS is formed (FIG. 2A). The polysilicon film PS is formed of polysilicon. Of the polysilicon film PS, each of dummy gate electrodes is formed. The thickness of the polysilicon film PS may be controlled to be, e.g., 100 nm.

Next, the polysilicon film PS and the insulating film GI are patterned. In this manner, on the element formation region ER1 side, the first gate insulating film GI1 and the first polysilicon film PS1 are formed. On the other hand, on the element formation region ER2 side, the second gate insulating film GI2 and the second polysilicon film PS2 are formed (FIG. 2B).

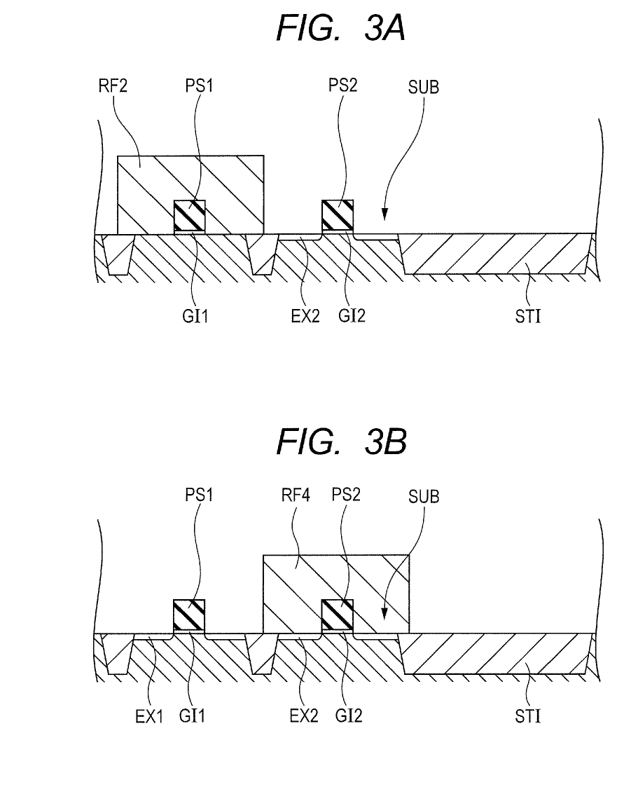

Next, in the element formation region ER1, a resist film RF2 is formed, as shown in FIG. 3A. On the other hand, the element formation region ER2 is doped with a p-type impurity by ion implantation. By the ion implantation, in the element formation region ER2, the second extension region EX2 is formed in the surface of the substrate SUB. As the impurity with which the element formation region ER2 is to be doped, boron may be used.

Next, the resist film RF2 is removed. Then, in the element formation region ER2, a resist film RF4 is formed, as shown in FIG. 3B. On the other hand, the element formation region ER1 is doped with an n-type impurity by ion implantation. By the ion implantation, in the element formation region ER1, the first extension region EX1 is formed in the surface of the substrate SUB. As the impurity with which the element formation region ER1 is to be doped, phosphorus or arsenic may be used.

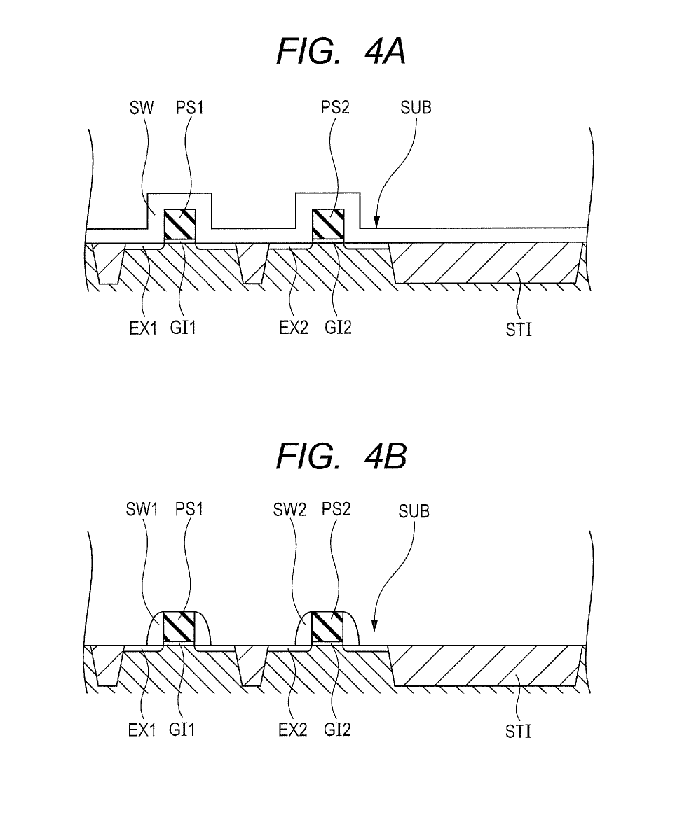

Next, the resist film RF4 is removed. Then, over the surface of the substrate SUB, an insulating film SW is formed (FIG. 4A). The insulating film SW covers the first extension region EX1, the second extension region EX2, the first polysilicon film PS1, and the second polysilicon PS2. The insulating film SW may be formed of an oxide film (e.g., a silicon dioxide film).

Next, by etching back the insulating film SW, the first sidewall SW1 and the second sidewall SW2 are formed (FIG. 4B). The first sidewall SW1 is formed so as to surround the first gate insulating film GI1 and the first polysilicon film PS1 in planar view. On the other hand, the second sidewall SW2 is formed so as to surround the second gate insulating film GI2 and the second polysilicon film PS2 in planar view.

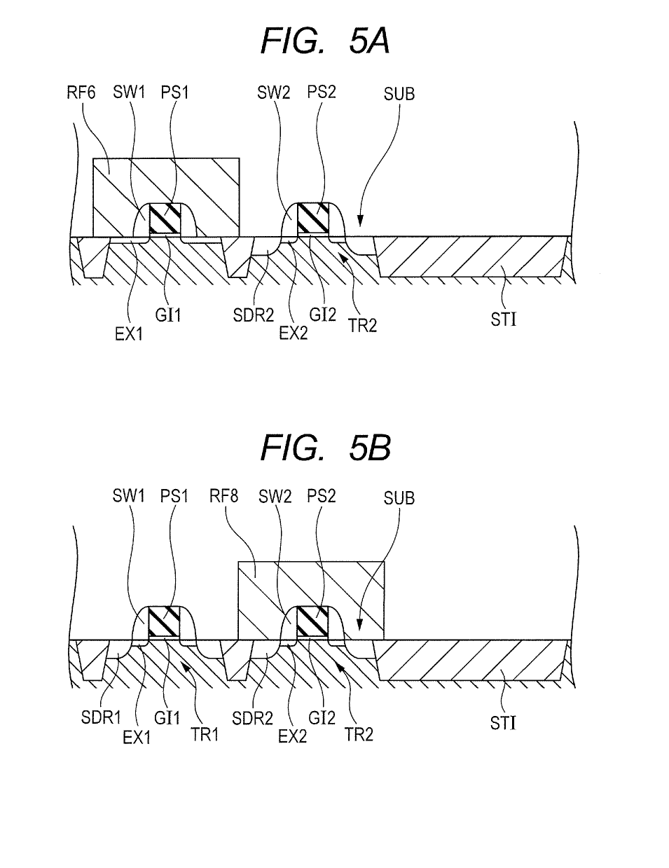

Next, in the element formation region ER1, as shown in FIG. 5A, a resist film RF6 is formed. On the other hand, the element formation region ER2 is doped with a p-type impurity by ion implantation. By the ion implantation, in the element formation region ER2, the second source/drain region SDR2 is formed in the surface of the substrate SUB. As the impurity with which the element formation region ER2 is to be doped, boron may be used.

Next, the resist film RF6 is removed. Then, in the element formation region ER2, as shown in FIG. 5B, a resist film RF8 is formed. On the other hand, the element formation region ER1 is doped with an n-type impurity by ion implantation. By the ion implantation, in the element formation region ER1, the first source/drain region SDR1 is formed in the surface of the substrate SUB. As the impurity with which the element formation region ER1 is to be doped, phosphorus or arsenic may be used.

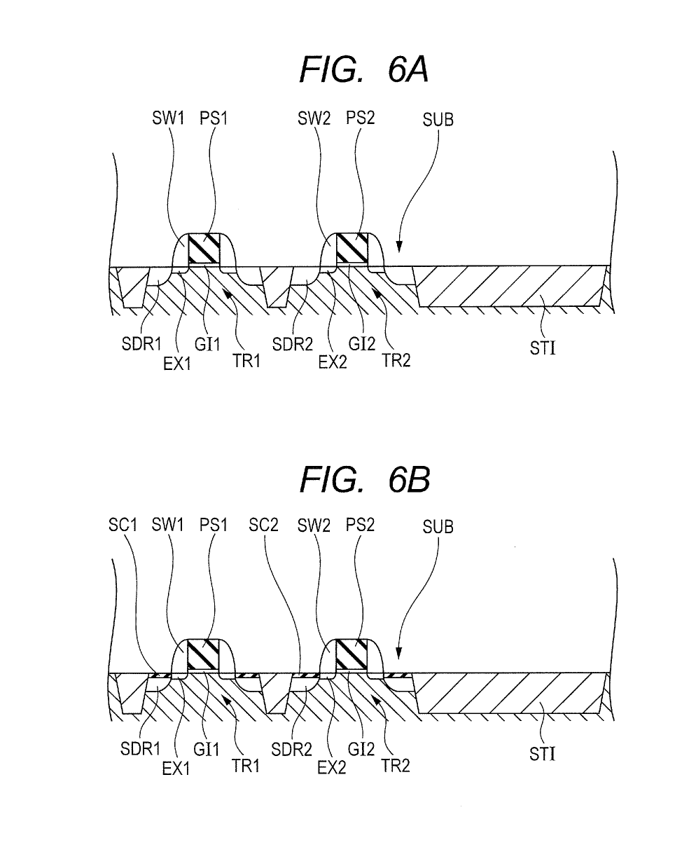

Next, the resist film RF8 is removed (FIG. 6A). Then, a metal film (not shown) is formed over the substrate SUB. The metal film covers the first source/drain region SDR1, the second source/drain region SDR2, the first sidewall SW1, the second sidewall SW2, the first polysilicon film PS1, and the second polysilicon film PS2. For the metal film, Ni, Pt, Co, or Ti may be used. Then, the metal film is heated. Thus, in the surface of the first source/drain region SDR1, the first silicide film SC1 is formed while, in the surface of the second source/drain region SDR2, the second silicide film SC2 is formed (FIG. 6B). In FIG. 6B, it is not shown that a silicide is formed over the surface of each of the first polysilicon film PS1 and the second polysilicon film PS2. However, in the present embodiment, a silicide may also be formed over the surface of each of the first second polysilicon film PS1 and the second polysilicon film PS2.

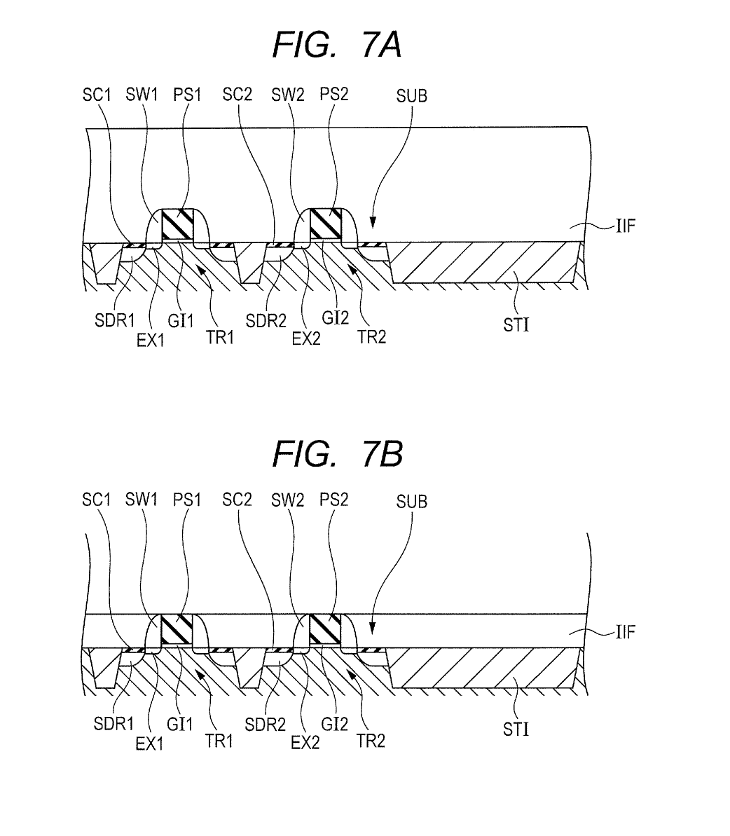

Next, the insulating film IF1 is formed over the substrate SUB (FIG. 7A). The insulating film FI1 may be formed of a silicon dioxide film or a low-dielectric-constant film. As a result, the first polysilicon film PS1 and the second polysilicon film PS2 are embedded in the insulating film IF1.

Next, the surface of the insulating film IF1 is polished to be planarized. For the polishing of the insulating film IF1, CMP (Chemical Mechanical Polishing) may be used. As shown in FIG. 7B, the insulating film IF1 is polished until the first polysilicon film PS1 and the second polysilicon film PS2 are exposed. In this case, as shown in FIG. 7B, the insulating film IF1 may also be polished until the height of the surface of the insulating film IF1 becomes equal to the height of each of the first sidewall SW1 and the second sidewall SW2.

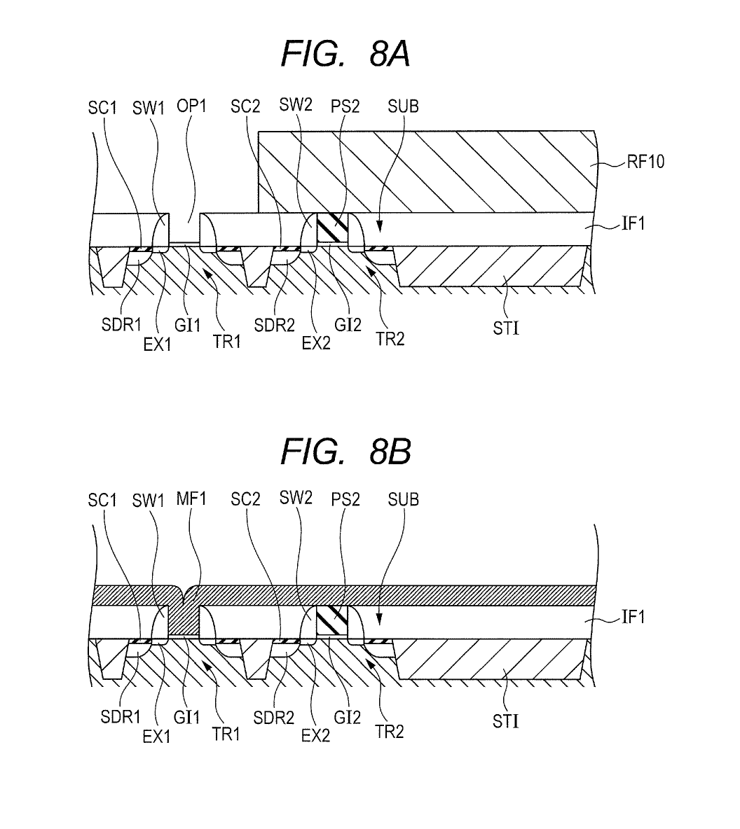

Next, in the region other than the element formation region ER1, a resist film RF10 is formed over the substrate SUB, as shown in FIG. 8A. Then, by etching, the first polysilicon film PS1 is removed. As a result, a first opening OP1 is formed inwardly of the first sidewall SW1 (FIG. 8A). The first opening OP1 is defined by the inner wall of the first sidewall SW1. In the present embodiment, the first gate insulating film GI1 is exposed through the first opening OP1, as shown in FIG. 8A.

Next, the resist film RF10 is removed. Then, over the substrate SUB, a first metal film MF1 is formed. As a result, the first opening OP1 is filled with the first metal film MF1 (FIG. 8B). As shown in FIG. 8B, the first metal film MF1 is formed not only over the element formation region ER1, but also over the element formation region ER2 and the isolation film STI. Of the first metal film MF1, each of the first gate electrode GE1 and the upper electrode UE is formed. The first metal film MF1 contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1). The thickness of the first metal film MF1 may be controlled to be, e.g., 5 nm to 200 nm over the isolation region STI.

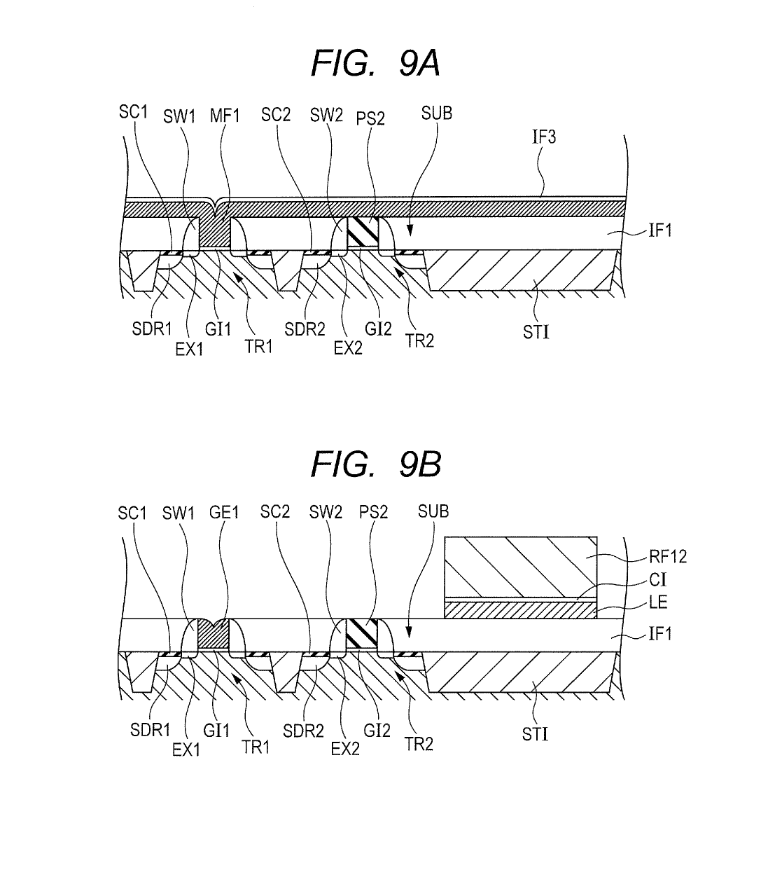

Next, over the first metal film MF1, an insulating film IF3 is formed (FIG. 9A). Of the insulating film IF3, the capacitor insulating film CI is formed. The thickness of the insulating film IF3 may be controlled to be, e.g., 5 nm to 100 nm. The insulating film IF may be formed of a silicon dioxide film, a silicon nitride film, or a metal oxide (e.g., tantalum oxide, zirconium oxide, hafnium oxide, lanthanum oxide, or yttrium oxide).

Next, over the isolation film STI, a resist film RF12 is formed, as shown in FIG. 9B. Then, using the resist film RF12 as a mask, the insulating film IF3 and the first metal film MF1 are etched. As a result, in the element formation region ER1, the first gate electrode GE1 is formed while, over the isolation film STI, the lower electrode LE and the capacitor insulating film CI1 are formed (FIG. 9B). In the present embodiment, the lower electrode LE is formed over the first insulating film IF1, as shown in FIG. 9B. Each of the first gate electrode GE1 and the lower electrode LE is formed of the first metal film MF1. Thus, the first gate electrode GE1 and the lower electrode LE are formed of the same material.

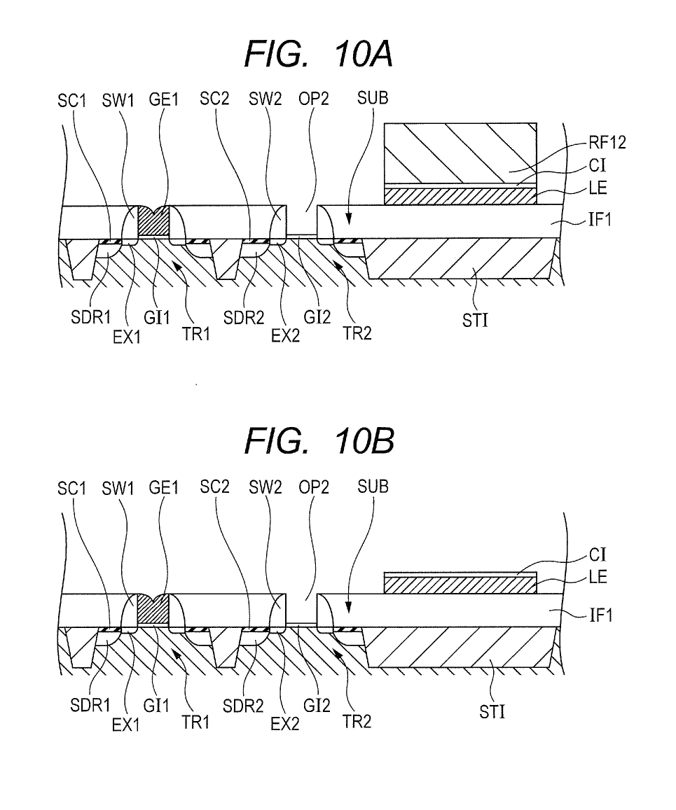

Next, by etching, the second polysilicon film PS2 is removed. As a result, a second opening OP2 is formed inwardly of the second sidewall SW2 (FIG. 10A). The second opening OP2 is defined by the inner wall of the second sidewall SW2. In the present embodiment, the second gate insulating film GI2 is exposed through the second opening OP2, as shown in FIG. 10A.

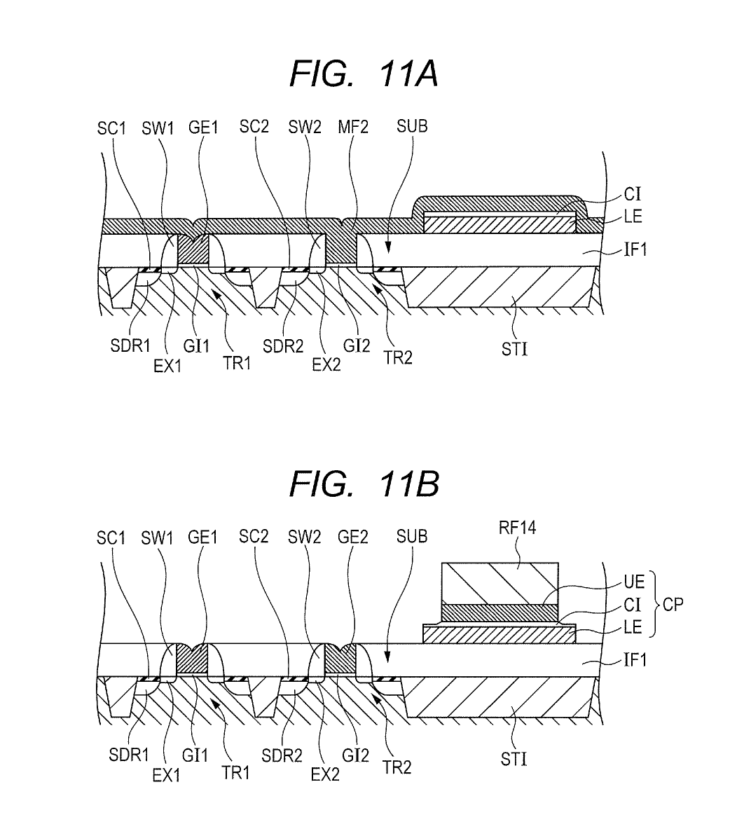

Next, the resist film RF12 is removed (FIG. 10B). Then, over the substrate SUB, a second metal film MF2 is formed. As a result, the second opening OP2 is filled with the second metal film MF2 (FIG. 11A). As shown in FIG. 11A, the second metal film MF2 is formed not only over the element formation region ER2, but also over the element formation region ER1 and the isolation film STI. Of the second metal film MF2, each of the second gate electrode GE2 and the upper electrode UE is formed. The second metal film MF2 contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1). The thickness of the second metal film MF2 may be controlled to be, e.g., 5 nm to 200 nm over the lower electrode LE.

Next, over the isolation film STI, a resist film RF14 is formed over the second metal film MF2, as shown in FIG. 11B. In the present embodiment, the area of the resist film RF14 in planar view is smaller than the area of the lower electrode LE in planar view. The resist film RF14 is formed within the region overlapping the lower electrode LE in planar view. Then, using the resist film R14 as a mask, the second metal film MF2 is etched. In the etching, an etching rate is selected so as to stop the etching at the insulating film IF1 and the capacitor insulating film CI. As a result, in the element formation region ER2, the second gate electrode GE2 is formed while, over the isolation film STI, the upper electrode UE is formed (FIG. 11B). Thus, over the isolation film STI, the capacitor element CP is formed. Each of the second gate electrode GE2 and the upper electrode UE is formed of the second metal film ME2. Thus, the second gate electrode GE2 and the upper electrode UE are formed of the same material. With the resist film RF14 of the present embodiment, the area of the upper electrode UE in planar view is smaller than the area of the lower electrode LE in planar view, while the upper electrode UE is formed within the region overlapping the lower electrode LE in planar view. In the present embodiment, at a position at which the capacitor insulating film CI does not overlap the resist film RF14, a part or the whole of the capacitor insulating film CI is removed by etching together with the second metal film MF2. As a result, the thickness of the capacitor insulating film CI at a position at which the upper electrode UE does not overlap the capacitor insulating film CI in planar view may be smaller than the thickness of the capacitor insulating film CI at a position at which the upper electrode UE overlaps the capacitor insulating film CI in planar view, as shown in FIG. 11B.

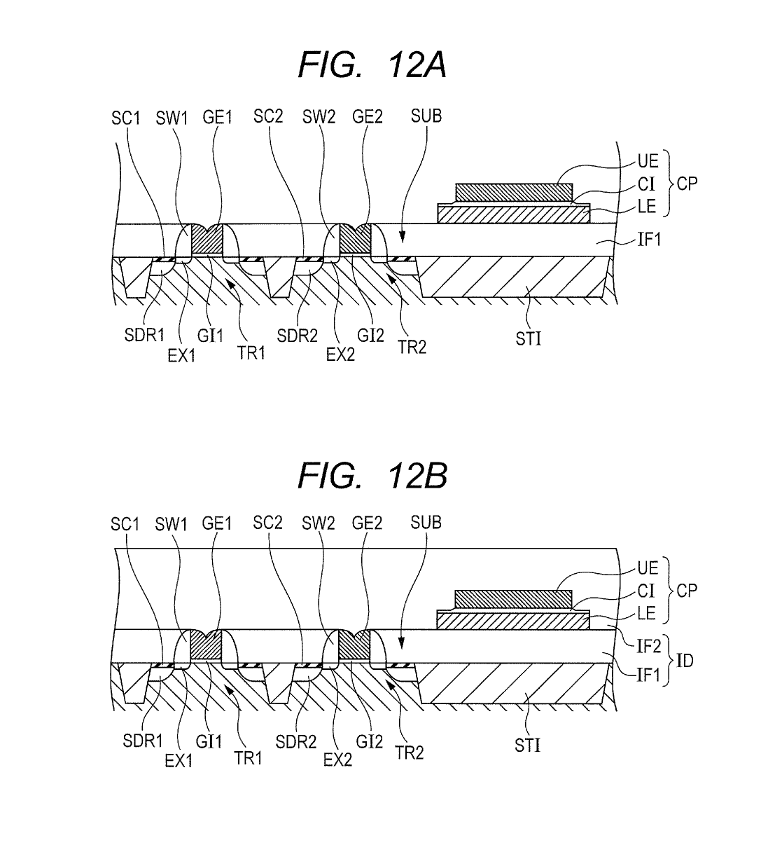

Next, the resist film RF14 is removed (FIG. 12A). Then, over the substrate SUB, the second insulating film IF2 is formed (FIG. 12B). The second insulating film IF2 covers the first gate electrode GE1, the second gate electrode GE2, and the upper electrode UE. In this manner, the interlayer insulating film ID is formed. The second insulating film IF2 may be formed of a silicon dioxide film or a low-dielectric-constant film. In the present embodiment, the first insulating film IF1 may be polished in the step shown in FIG. 7B until the height of the surface of the first insulating film IF becomes equal to the height of each of the first sidewall SW1 and the second sidewall SW2. In this case, the height of the position at which the interface between the first insulating film IF1 and the second insulating film IF2 is formed is equal to the height of the top of each of the first sidewall SW1 and the second sidewall SW2.

Next, in the second insulating film IF2, contact holes (not shown) are formed. The contact holes are filled with conductive members to form the first contact plug CP1, the second contact plug CP2, the third contact plugs CP3, and the fourth contact plugs CP4. In this manner, the semiconductor device SD1a shown in FIG. 1A is formed.

In the present embodiment, each of the first gate electrode GE1 and the lower electrode LE is formed of the first metal film MF1. Each of the second gate electrode GE2 and the upper electrode UE is formed of the second metal film MF2. Accordingly, in the present embodiment, the capacitor element CP including the electrodes each containing a metal is formed in the smaller number of process steps.

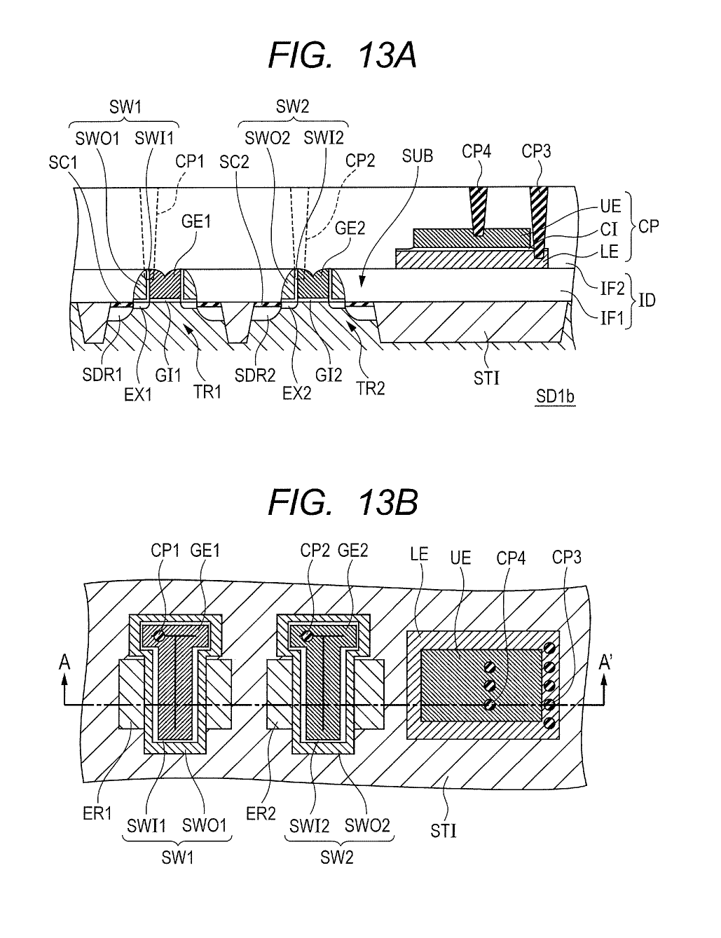

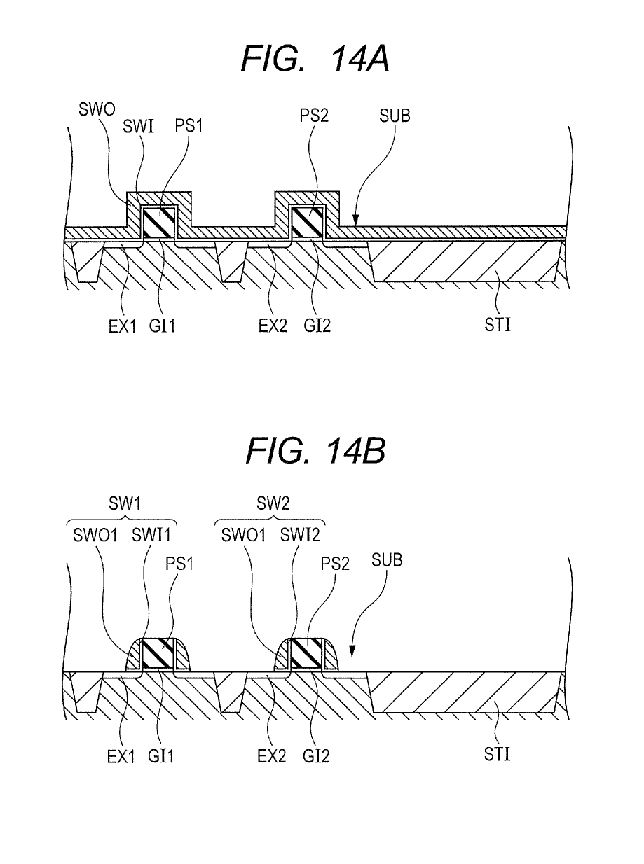

Next, using FIGS. 13A, 13B, 14A, and 14B, a description will be given of another example of the present embodiment. FIG. 13A is a cross-sectional view showing a semiconductor device SD1b in the other example of the first embodiment. FIG. 13B is a two-dimensional perspective view of the semiconductor device SD1b in the present embodiment. FIG. 13A is a cross-sectional view along the line A-A′ of FIG. 13B. The semiconductor device SD1b shown in FIGS. 13A and 13B has the same configuration as that of the semiconductor device SD1a shown in FIGS. 1A and 1B except that the first sidewall SW1 includes a sidewall SWI1 and a sidewall SWO1 and the second sidewall SW2 includes a sidewall SWI2 and a sidewall SWO2.

The sidewall SWI1 is in contact with the surface of the substrate SUB and with the respective side surfaces of the first gate insulating film GI1 and the first gate electrode GE1. The sidewall SWI1 is formed along the surface of the substrate SUB and the respective side surfaces of the first gate insulating film GI1 and the first gate electrode GE1. Accordingly, the sidewall SWI1 has a letter-L shape when viewed in the A-A′ direction. Likewise, the sidewall SWI2 is in contact with the surface of the substrate SUB and with the second gate insulating film GI2 and the second gate electrode GE2. The sidewall SWI2 is formed along the surface of the substrate SUB and the respective side surfaces of the second gate insulating film GI2 and the second gate electrode GE2. Accordingly, the sidewall SWI2 has a letter-L shape when viewed in the A-A′ direction. The sidewalls SWI1 and SWI2 are formed so as to respectively surround the first gate electrode GE1 and the second gate electrode GE2 in planar view. In the present embodiment, the respective film thicknesses of the sidewalls SWI1 and SWI2 may be generally the same.

The sidewall SWO1 is formed over the surface of the substrate SUB via the sidewall SWI1 and also over the side surfaces of the first gate electrode GE1 via the sidewall SWI1. Likewise, the sidewall SWO2 is formed over the surface of the substrate SUB via the sidewall SWI2 and also over the side surfaces of the second gate electrode GE2 via the sidewall SWI2. The sidewalls SWO1 and SWO2 are formed so as to respectively surround the first gate electrode GE1 and the second gate electrode GE2 in planar view.

Each of the sidewalls SWI1, SWI2, SWO1, and SWO2 is formed of an insulating film. In the present embodiment, each of the sidewalls SWI1 and SWI2 may be formed of an oxide film (e.g., a silicon dioxide film). On the other hand, each of the sidewalls SWO1 and SWO2 may be formed of a nitride film (e.g., a silicon nitride film). In the present embodiment, the sidewalls SWI1 and SWI2 may be formed of the same material. The sidewalls SWO1 and SWO2 may be formed of the same material.

Next, using FIGS. 14A and 14B, a description will be given of a method of forming the semiconductor device SD1b. FIGS. 14A and 14B are cross-sectional views each showing a manufacturing method of the semiconductor device SD1b in the present embodiment.

First, in the same manner as in the semiconductor device SD1a, the steps shown in FIGS. 2A, 2B, 3A, and 3B are performed. Then, over the surface of the substrate SUB, an insulating film SWI is formed. The insulating film SWI covers the first extension region EX1, the second extension region EX2, the first polysilicon film PS1, and the second polysilicon film PS2. In the present embodiment, the insulating film SW1 may be formed of an oxide film (e.g., a silicon dioxide film). Then, over the insulating film SWI, an insulating film SWO is formed (FIG. 14A). In the present embodiment, the insulating film SWO may be formed of a nitride film (e.g., a silicon nitride film).

Next, by etching back the insulating films SWI and SWO, the first sidewall SW1 and the second sidewall SW2 are formed (FIG. 14B). In this case, when the insulating film SWI has a uniform thickness over the substrate SUB, the respective film thicknesses of the sidewalls SWI1 and SWI2 are generally the same. In the present embodiment, each of the sidewalls SWI1 and SWI2 is formed of the insulating film SWI. Thus, the sidewalls SWI1 and SWI2 are formed of the same material. Likewise, each of the sidewalls SWO1 and SWO2 is formed of the insulating film SWO. Thus, the sidewalls SWO1 and SWO2 are formed of the same material.

Next, in the same manner as in the semiconductor device SD1a, the process steps shown in FIGS. 5A to 12B are performed. In this manner, the semiconductor device SD1b is formed.

In the semiconductor device SD1b also, each of the first gate electrode GE1 and the lower electrode LE is formed of the first metal film MF1. Each of the second gate electrode GE2 and the upper electrode UE is formed of the second metal film MF2. Accordingly, in the present embodiment, the capacitor element CP including the electrodes each containing a metal is formed in a smaller number of process steps.

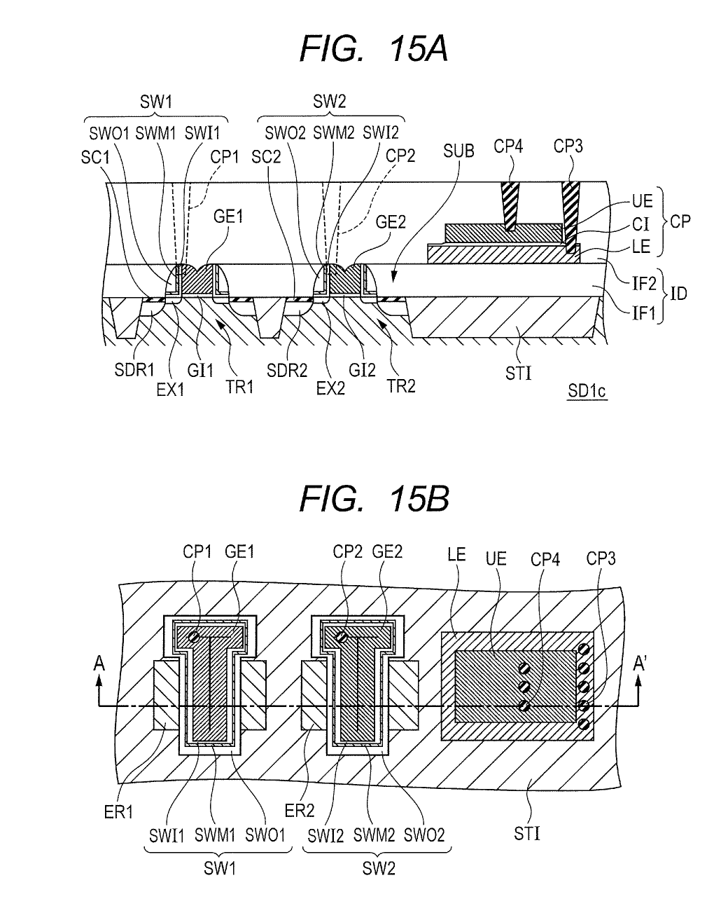

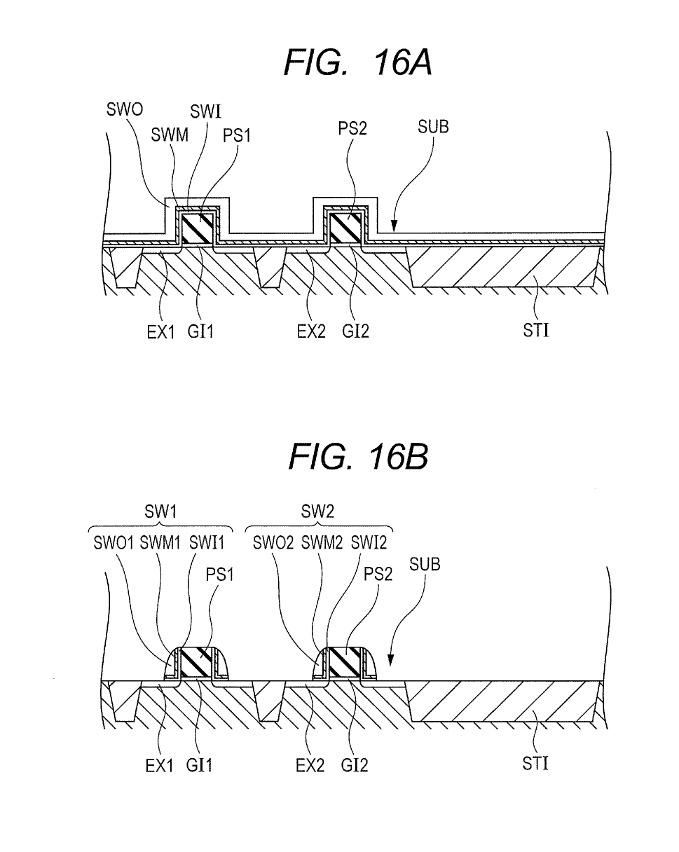

Next, using FIGS. 15A, 15B, 16A, and 16B, a description will be given of still another example of the present embodiment. FIG. 15A is a cross-sectional view showing a semiconductor device SD1c in the still other example of the first embodiment. FIG. 15B is a two-dimensional perspective view of the semiconductor device SD1c in the present embodiment. FIG. 15A is a cross-sectional view along the line A-A′ of FIG. 15B. The semiconductor device SD1c shown in FIGS. 15A and 15B has the same configuration as that of the semiconductor device SD1a shown in FIGS. 1A and 1B except that the first sidewall SW1 includes the sidewall SWI1, a sidewall SWM1, and the sidewall SWO1 and the second sidewall SW2 includes the sidewall SWI2, a sidewall SWM2, and the sidewall SWO2.

Using FIGS. 15A and 15B, a detailed description will be given of the semiconductor device SD1c. In the semiconductor device SD1c, the first transistor TR1 includes the first sidewall SW1 and the second transistor TR2 includes the second sidewall SW2. The first sidewall SW1 includes the sidewalls SWI1, SWM1, and SWO1. On the other hand, the second sidewall SW2 includes the sidewalls SWI2, SWM2, and SWO2.

The sidewall SWI1 is in contact with the surface of the substrate SUB and with the respective side surfaces of the first gate insulating film GI1 and the first gate electrode GE1. The sidewall SWI1 is formed along the surface of the substrate SUB and the respective side surfaces of the first gate insulating film GI1 and the first gate electrode GE1. Accordingly, the sidewall SWI1 has a letter-L shape when viewed in the A-A′ direction. Likewise, the sidewall SWI2 is in contact with the surface of the substrate SUB and with the second gate insulating film GI2 and the second gate electrode GE2. The sidewall SWI2 is formed along the surface of the substrate SUB and the respective side surfaces of the second gate insulating film GI2 and the second gate electrode GE2. Accordingly, the sidewall SWI2 has a letter-L shape when viewed in the A-A′ direction. The sidewalls SWI1 and SWI2 are formed so as to respectively surround the first gate electrode GE1 and the second gate electrode GE2 in planar view. In the present embodiment, the respective film thicknesses of the sidewalls SWI1 and SWI2 may be generally the same.

The sidewall SWM1 is formed over the surface of the substrate SUB via the sidewall SWI1 and also over the side surfaces of the first gate electrode GE1 via the sidewall SWI1. The sidewall SWM1 is formed along the sidewall SMI1. Accordingly, the sidewall SWM1 has a letter-L shape when viewed in the A-A′ direction. Likewise, the sidewall SWM2 is formed over the surface of the substrate SUB via the sidewall SWI2 and also over the side surfaces of the second gate electrode GE2 via the sidewall SWI2. The sidewall SWM2 is formed along the sidewall SMI2. Accordingly, the sidewall SWM2 has a letter-L shape when viewed in the A-A′ direction. The sidewalls SWM1 and SWM2 are formed so as to respectively surround the first gate electrode GE1 and the second gate electrode GE2 in planar view. In the present embodiment, the respective film thicknesses of the sidewalls SWM1 and SWM2 may be generally the same.

The sidewall SWO1 is formed over the surface of the substrate SUB via the sidewalls SWI1 and SWM1 and also over the side surfaces of the first gate electrode GE1 via the sidewalls SWI1 and SWM1. Likewise, the sidewall SWO2 is formed over the surface of the substrate SUB via the sidewalls SWI2 and SWM2 and also over the side surfaces of the second gate electrode GE2 via the sidewalls SWI2 and SWM2. The sidewalls SWO1 and SWO2 are formed so as to respectively surround the first gate electrode GE1 and the second gate electrode GE2 in planar view.

Each of the sidewalls SWI1, SWI2, SWM1, SWM2, SWO1, and SWO2 is formed of an insulating film. In the present embodiment, each of the sidewalls SWI1, SWI2, SWO1, and SWO2 may be formed of an oxide film (e.g., a silicon dioxide film). On the other hand, each of the sidewalls SWM1 and SWM2 may be formed of a nitride film (e.g., a silicon nitride film). In the present embodiment, the sidewalls SWI1 and SWI2 may be formed of the same material. The sidewalls SWM1 and SWM2 may be formed of the same material. The sidewalls SWO1 and SWO2 may be formed of the same material.

Next, using FIGS. 16A and 16B, a description will be given of a method of forming the semiconductor device SD1c. FIGS. 16A and 16B are cross-sectional views each showing a manufacturing method of the semiconductor device SD1c in the present embodiment.

First, in the same manner as in the semiconductor device SD1a, the steps shown in FIGS. 2A, 2B, 3A, and 3B are performed. Then, over the surface of the substrate SUB, the insulating film SWI is formed. The insulating film SWI covers the first extension region EX1, the second extension region EX2, the first polysilicon film PS1, and the second polysilicon film PS2. In the present embodiment, the insulating film SW1 may be formed of an oxide film (e.g., a silicon dioxide film). Then, over the insulating film SWI, an insulating film SWM is formed. In the present embodiment, the insulating film SWM may be formed of a nitride film (e.g., a silicon nitride film). Then, over the insulating film SWM, the insulating film SWO is formed (FIG. 16A). In the present embodiment, the insulating film SWO may be formed of an oxide film (e.g., a silicon dioxide film).

Next, by etching back the insulating films SWI, SMW, and SWO, the first sidewall SW1 and the second sidewall SW2 are formed (FIG. 16B). In this case, when the insulating film SWI has a uniform thickness over the substrate SUB, the respective film thicknesses of the sidewalls SWI1 and SWI2 are generally the same. Likewise, when the insulating film SWM has a uniform thickness over the substrate SUB, the respective film thicknesses of the sidewalls SWM1 and SWM2 are generally the same. In the present embodiment, each of the sidewalls SWI1 and SWI2 is formed of the insulating film SWI. Thus, the sidewalls SWI1 and SWI2 are formed of the same material. Likewise, each of the sidewalls SWM1 and SWM2 is formed of the insulating film SWM. Thus, the sidewalls SWM1 and SWM2 are formed of the same material. Likewise, each of the sidewalls SWO1 and SWO2 is formed of the insulating film SWO. Thus, the sidewalls SWO1 and SWO2 are formed of the same material.

Next, in the same manner as in the semiconductor device SD1a, the process steps shown in FIGS. 5A to 12B are performed. In this manner, the semiconductor device SD1c is formed.

In the semiconductor device SD1c also, each of the first gate electrode GE1 and the lower electrode LE is formed of the first metal film MF1. Each of the second gate electrode GE2 and the upper electrode UE is formed of the second metal film MF2. Accordingly, in the present embodiment, the capacitor element CP including the electrodes each containing a metal is formed in a smaller number of process steps.

In the present embodiment, the first gate electrode GE1 of the n-type first transistor TR1 and the lower electrode LE are formed of the same material (first metal film MF1) and the second gate electrode GE2 of the p-type second transistor TR2 and the upper electrode UE are formed of the same material (second metal film MF2). In another example, it may also be possible that the second gate electrode GE2 of the p-type second transistor TR2 and the lower electrode LE are formed of the same material (first metal film MF1) and the first gate electrode GE1 of the n-type first transistor TR1 and the upper electrode UE are formed of the same material (second metal film MF2). In either case, the first metal film MF1 forming the lower electrode LE is embedded in the first opening OP1 of the first transistor TR1 or in the second opening OP2 of the second transistor TR2 before the second metal film MF2 is embedded.

In the present embodiment, each of the first gate electrode GE1, the second gate electrode GE2, the lower electrode LE, and the upper electrode UE is formed in a single layer. In another example, it may also be possible that each of the first gate electrode GE1, the second gate electrode GE2, the lower electrode LE, and the upper electrode UE is formed in a plurality of layers. In this case, the order in which the layers are stacked for the first gate electrode GE1 is the same as the order in which the layers are stacked for the lower electrode LE, while the order in which the layers are stacked for the second gate electrode GE2 is the same as the order in which the layers are stacked for the upper electrode UE.

In the present embodiment, each of the first gate electrode GE1, the second gate electrode GE2, the lower electrode LE, and the upper electrode UE contains a metal. In another example, it may also be possible that each of the first gate electrode GE1, the second gate electrode GE2, the lower electrode LE, and the upper electrode UE is formed of a material (e.g., polysilicon) other than a metal. In this case also, the first gate electrode GE1 and the lower electrode LE are formed of the same material and the second gate electrode GE2 and the upper electrode UE are formed of the same material.

### Second Embodiment

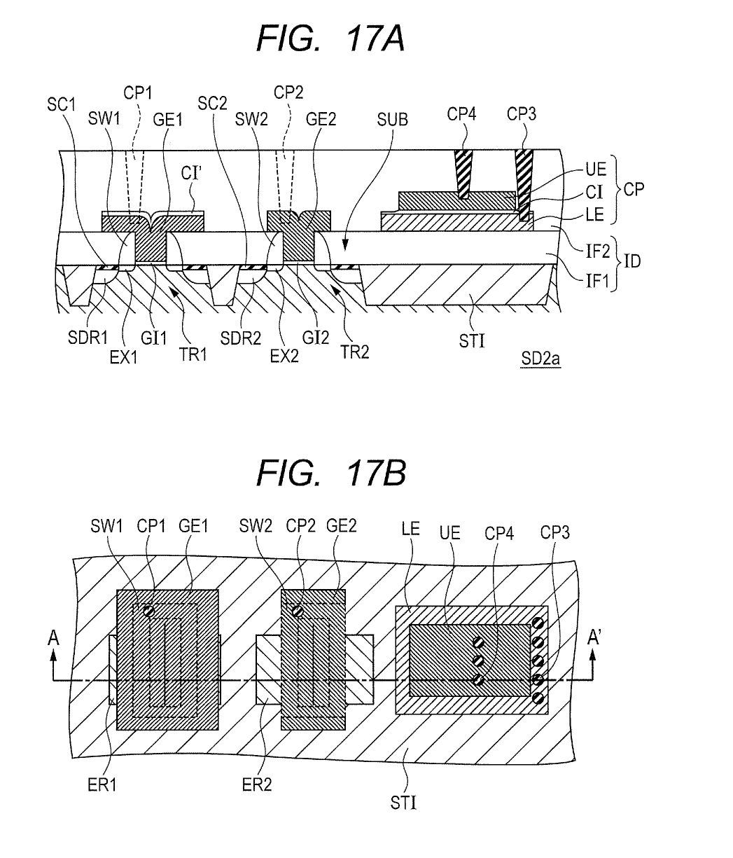

FIG. 17A is a cross-sectional view of a semiconductor device SD2a in a second embodiment. FIG. 17B is a two-dimensional perspective view of the semiconductor device SD2a in the present embodiment. FIG. 17A is a cross-sectional view along the line A-A′ of FIG. 17B.

In the semiconductor device SD2a, the first gate electrode GE1 is formed to be embedded in the first opening OP1. The edge portion of the first gate electrode GE1 in planar view overlies the first insulating film IF1 outside the region overlapping the first opening OP1 in planar view. Likewise, the second gate electrode GE2 is formed to be embedded in the second opening OP2. The edge portion of the second gate electrode GE2 in planar view overlies the first insulating film IF1 outside the region overlapping the second opening OP2 in planar view. The semiconductor device SD2a has a configuration different in the foregoing components from that of the semiconductor device SD1a. The configuration of the semiconductor device SD2a is otherwise the same as that of the semiconductor device SD1a in the first embodiment except for the components particularly mentioned in the second embodiment.

In the semiconductor device SD2a, each of the lower electrode LE and the upper electrode UE of the capacitor element CP contains a metal. Thus, in the present embodiment, in the interlayer insulating film ID, the capacitor element CP can be formed which has the electrodes each containing a metal.

Using FIGS. 17A and 17B, a detailed description will be given of the semiconductor device SD2a. In the semiconductor device SD2a, the first gate electrode GE1 is formed to be embedded in the first opening OP1. The edge portion of the first gate electrode GE1 in planar view overlies the first insulating film IF1 outside the region overlapping the first opening OP1 in planar view. Likewise, the second gate electrode GE2 is formed to be embedded in the second opening OP2. The edge portion of the second gate electrode GE2 in planar view overlies the first insulating film IF1 outside the region overlapping the second opening OP2 in planar view.

In the present embodiment, the film thickness of the lower electrode LE may be generally equal to the film thickness of the portion of the first gate electrode GE1 which overlies the first insulating film IF1 outside the region where the first gate electrode GE1 overlaps the first opening OP1 in planar view. Likewise, the film thickness of the upper electrode UE may be generally equal to the film thickness of the portion of the second gate electrode GE2 which overlies the first insulating film IF1 outside the region where the second gate electrode GE2 overlaps the second opening OP2 in planar view.

In the present embodiment, the semiconductor device SD2a may further include an insulating film CI′. The insulating film CI′ is formed between the first gate electrode GE1 and the second insulating film IF2. The insulating film CI′ is formed of the same material as that of the capacitor insulating film CI. In the case where the insulating film CI′ is formed over the first gate electrode GE1, the first contact plug CP1 extends through the insulating film CI′ to be coupled to the first gate electrode GE1.

In the semiconductor device SD2a, each of the lower electrode LE and the upper electrode UE of the capacitor element CP contains a metal. Thus, in the present embodiment, in the interlayer insulating film ID, the capacitor element CP can be formed which has the electrodes each containing a metal.

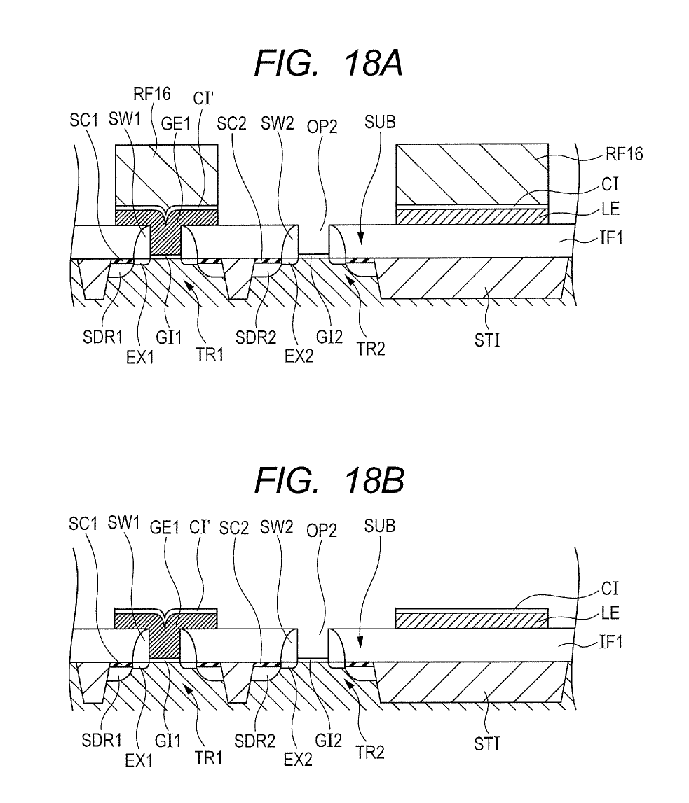

Next, using FIGS. 18A to 20B, a detailed description will be given of a manufacturing method of the semiconductor device SD2a in the present embodiment. FIGS. 18A to 20B are cross-sectional views showing the manufacturing method of the semiconductor device SD2a in the present embodiment.

First, in the same manner as for the semiconductor device SD1a, the process steps shown in FIGS. 2A to 9A are performed. Then, as shown in FIG. 18A, a resist film RF16 is formed over the element formation region ER1 and the isolation film STI. In the present embodiment, the resist film RF16 over the element formation region ER1 is formed so as to overlap not only a first region overlapping the first opening OP1 in planar view, but also a peripheral region of the first region in planar view. Then, using the resist film RF16 as a mask, the insulating film IF3 and the first metal film MF1 are etched. As a result, in the element formation region ER1, the first gate electrode GE1 and the insulating film CI′ are formed while, over the isolation film STI, the lower electrode LE and the capacitor insulating film CI are formed. In the present embodiment, as shown in FIG. 18A, the lower electrode LE is formed over the insulating film IF1. In the present embodiment, the resist film RF16 over the element formation region ER1 prevents the first metal film MF1 and the insulating film IF3 from being etched in the first region and the peripheral region of the first region. Consequently, the edge portion of the first gate electrode GE1 in planar view overlies the first insulating film IF1 outside the region overlapping the first opening OP1 in planar view.

In the present embodiment, each of the first gate electrode GE1 and the lower electrode LE is formed of the first metal film MF1. Accordingly, the first gate electrode GE1 and the lower electrode LE are formed of the same material. When the first metal film MF1 has a uniform thickness over the substrate SUB, the thickness of the lower electrode LE is generally equal to the thickness of the portion of the first gate electrode GE1 which overlies the first insulating film IF1 outside the region where the first gate electrode GE1 overlies the first opening OP1 in planar view. Each of the insulating film CI′ and the capacitor insulating film CI is formed of the insulating film IF3. Thus, the insulating film CI′ and the capacitor insulating film CI are formed of the same material. Then, by further performing etching, the second polysilicon film PS2 is removed. As a result, the second opening OP2 is formed inwardly of the second sidewall SW2 (FIG. 18A). The second opening OP2 is defined by the inner wall of the second sidewall SW2. In the present embodiment, as shown in FIG. 18A, the second gate insulating film GI2 is exposed through the second opening OP2.

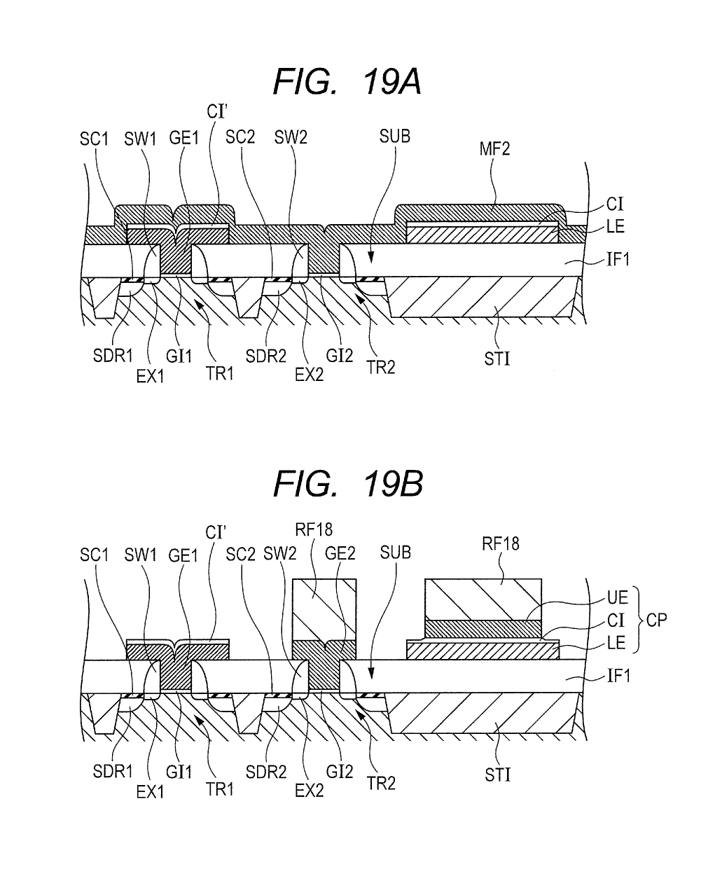

Next, the resist film RF16 is removed (FIG. 18B). Then, the second metal film MF2 is formed over the substrate SUB. As a result, the second opening OP2 is filled with the second metal film MF2 (FIG. 19A). As shown in FIG. 19A, the second metal film MF2 is formed not only over the element formation region ER2, but also over the element formation region ER1 and the isolation film STI.

Next, as shown in FIG. 19B, over the element formation region ER2 and the isolation film STI, a resist film RF18 is formed over the second metal film MF2. In the present embodiment, the resist film RF18 over the element formation region ER2 is formed so as to overlap not only a second region overlapping the second opening OP2 in planar view, but also a peripheral region of the second region in planar view. In the present embodiment, the area of the resist film RF18 over the isolation film STI in planar view is smaller than the area of the lower electrode LE in planar view. The resist film RF18 over the isolation film STI is formed within the region overlapping the lower electrode LE in planar view. Then, using the resist film RF18 as a mask, the second metal film MF2 is etched. In the etching, an etching rate is elected so as to strop the etching at the first insulating film IF1, the insulating film CI′, and the capacitor insulating film CI. As a result, in the element formation region ER2, the second gate electrode GE2 is formed while, over the isolation film STI, the upper electrode UE is formed (FIG. 19B). In this manner, over the isolation film STI, the capacitor element CP is formed. In the present embodiment, each of the second gate electrode GE2 and the upper electrode UE is formed of the second metal film MF2. Thus, the second gate electrode GE2 and the upper electrode UE are formed of the same material.

In the present embodiment, the resist film RF18 over the element formation region ER2 prevents the second metal film MF2 from being etched in the second region and the peripheral region of the second region. As a result, the edge portion of the second gate electrode GE2 in planar view overlies the first insulating film IF1 outside the region overlapping the second opening OP2 in planar view. Consequently, each of the second gate electrode GE2 and the upper electrode UE is formed of the second metal film MF2. Thus, the second gate electrode GE2 and the upper electrode UE are formed of the same material. With the resist film RF18 of the present embodiment, the area of the upper electrode UE in planar view is smaller than the area of the lower electrode LE in planar view and the upper electrode UE is formed within the region overlapping the lower electrode LE in planar view. In the present embodiment, at a position at which the capacitor insulating film CI does not overlap the resist film RF18, a part or the whole of the capacitor insulating film CI is removed by the etching together with the second metal film MF2. As a result, the thickness of the capacitor insulating film CI at a position at which the upper electrode UE does not overlap the capacitor insulating film CI in planar view may be smaller than the thickness of the capacitor insulating film CI at which the upper electrode UE overlaps the capacitor insulating film CI in planar view, as shown in FIG. 19B.

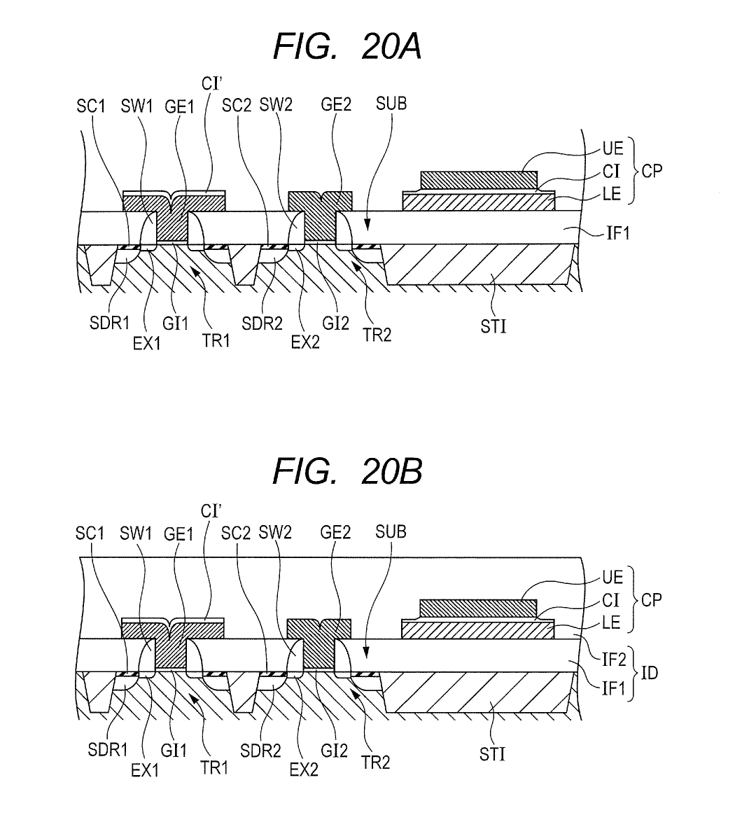

Next, the resist film RF18 is removed (FIG. 20A). Then, over the substrate SUB, the second insulating film IF2 is formed (FIG. 20B). The second insulating film IF2 covers the first gate electrode GE1, the second gate electrode GE2, and the upper electrode UE. Thus, the interlayer insulating film IF is formed. The second insulating film IF2 may be formed of a silicon dioxide film or a low-dielectric-constant film.

Next, in the second insulating film IF2, contact holes (not shown) are formed. The contact holes are filled with conductive members to form the first contact plug CP1, the second contact plug CP2, the third contacts plugs CP3, and the fourth contact plugs CP4. In this manner, the semiconductor device SD2a shown in FIG. 17A is formed.

In the present embodiment, each of the first gate electrode GE1 and the lower electrode LE is formed of the first metal film MF1. Each of the second gate electrode GE2 and the upper electrode UE is formed of the second metal film MF2. Accordingly, in the present embodiment, the capacitor element CP including the electrodes each containing a metal is formed in the smaller number of process steps.

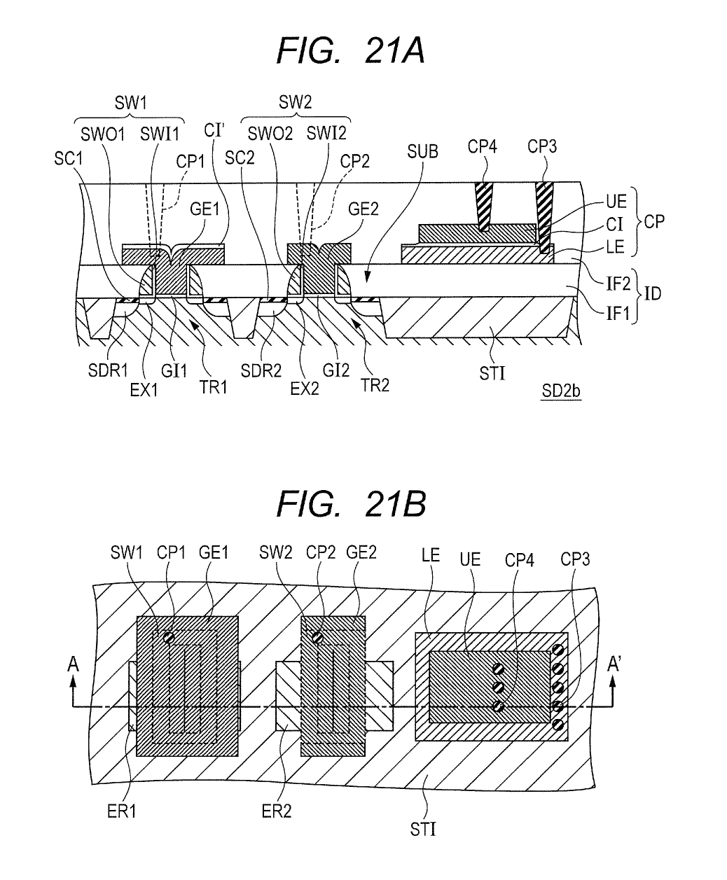

Next, using FIGS. 21A and 21B, a description will be given of another example of the present embodiment. FIG. 21A is a cross-sectional view showing a semiconductor device SD2b in the other example of the second embodiment. FIG. 21B is a two-dimensional perspective view of the semiconductor device SD2b in the present embodiment. FIG. 21A is a cross-sectional view along the line A-A′ of FIG. 21B. The semiconductor device SD2b shown in FIGS. 21A and 21B has the same configuration as that of the semiconductor device SD2a shown in FIGS. 17A and 17B except that the first sidewall SW1 includes the sidewalls SWI1 and SWO1 and the second sidewall SW2 includes the sidewalls SWI2 and SWO2. The first sidewall SW1 and the second sidewall SW2 in the semiconductor device SD2b shown in FIGS. 21A and 21B have the same configurations as those of the first sidewall SW1 and the second sidewall SW2 in the semiconductor device SD1b shown in FIGS. 13A and 13B. A method of forming the first sidewall SW1 and the second sidewall SW2 in the semiconductor device SD2b shown in FIGS. 21A and 21B includes the steps shown in FIGS. 14A and 14B similarly to that in the semiconductor device SD1b shown in FIGS. 13A and 13B.

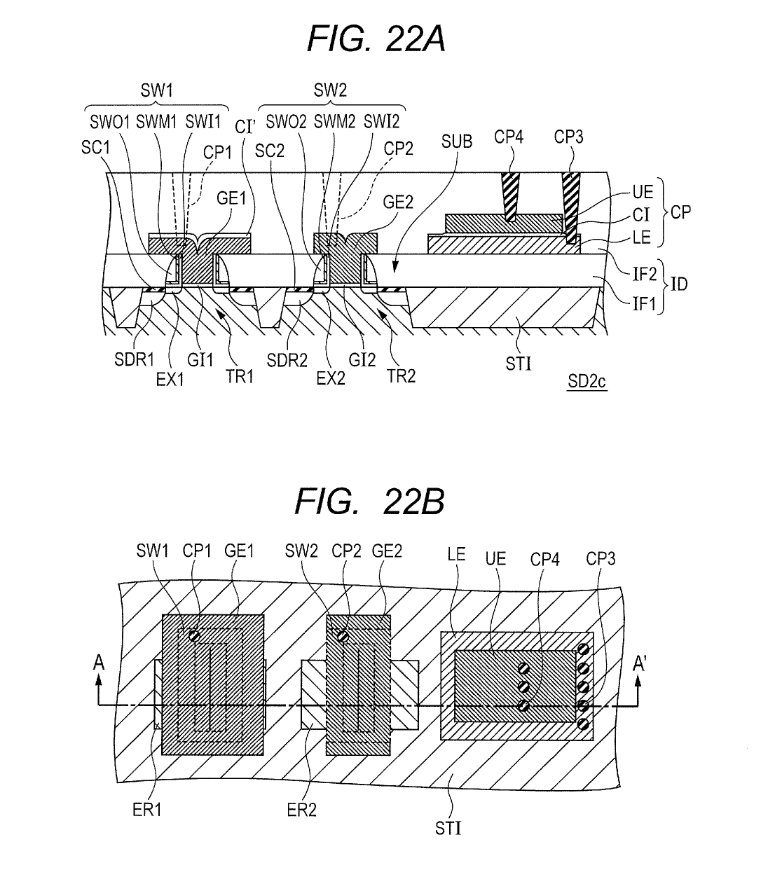

Next, using FIGS. 22A and 22B, a description will be given of still another example of the present embodiment. FIG. 22A is a cross-sectional view showing a semiconductor device SD2c in the still other example of the second embodiment. FIG. 22B is a two-dimensional perspective view of the semiconductor device SD2c in the present embodiment. FIG. 22A is a cross-sectional view along the line A-A′ of FIG. 22B. The semiconductor device SD2c shown in FIGS. 22A and 22B has the same configuration as that of the semiconductor device SD2a shown in FIGS. 17A and 17B except that the first sidewall SW1 includes the sidewalls SWI1, SWM1, and SWO1 and the second sidewall SW2 includes the sidewalls SWI2, SWM2, and SWO2. The first sidewall SW1 and the second sidewall SW2 in the semiconductor device SD2c shown in FIGS. 22A and 22B have the same configurations as those of the first sidewall SW1 and the second sidewall SW2 in the semiconductor device SD1c shown in FIGS. 15A and 15B. A method of forming the first sidewall SW1 and the second sidewall SW2 in the semiconductor device SD2c shown in FIGS. 22A and 22B includes the steps shown in FIGS. 16A and 16B similarly to that in the semiconductor device SD1c shown in FIGS. 15A and 15B.

In the present embodiment, the first gate electrode GE1 of the n-type first transistor TR1 and the lower electrode LE are formed of the same material (first metal film MF1) and the second gate electrode GE2 of the p-type second transistor TR2 and the upper electrode UE are formed of the same material (second metal film MF2). In another example, it may also be possible that the second gate electrode GE2 of the p-type second transistor TR2 and the lower electrode LE are formed of the same material (first metal film MF1) and the first gate electrode GE1 of the n-type first transistor TR1 and the upper electrode UE are formed of the same material (second metal film MF2). In either case, the first metal film MF1 forming the lower electrode LE is embedded in the first opening OP1 of the first transistor TR1 or in the second opening OP2 of the second transistor TR2 before the second metal film MF2 is embedded.

In the present embodiment, each of the first gate electrode GE1, the second gate electrode GE2, the lower electrode LE, and the upper electrode UE is formed in a single layer. In another example, it may also be possible that each of the first gate electrode GE1, the second gate electrode GE2, the lower electrode LE, and the upper electrode UE is formed in a plurality of layers. In this case, the order in which the layers are stacked for the first gate electrode GE1 is the same as the order in which the layers are stacked for the lower electrode LE, while the order in which the layers are stacked for the second gate electrode GE2 is the same as the order in which the layers are stacked for the upper electrode UE.

In the present embodiment, each of the first gate electrode GE1, the second gate electrode GE2, the lower electrode LE, and the upper electrode UE contains a metal. In another example, it may also be possible that each of the first gate electrode GE1, the second gate electrode GE2, the lower electrode LE, and the upper electrode UE is formed of a material (e.g., polysilicon) other than a metal. In this case also, the first gate electrode GE1 and the lower electrode LE are formed of the same material and the second gate electrode GE2 and the upper electrode UE are formed of the same material.

### Third Embodiment

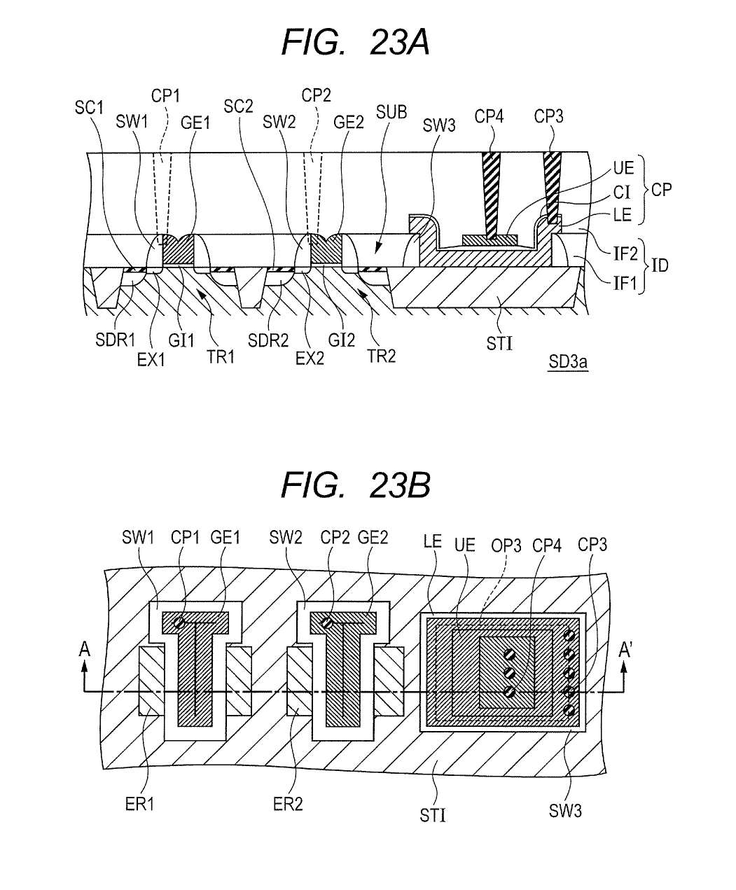

FIG. 23A is a cross-sectional view of a semiconductor device SD3a in a third embodiment. FIG. 23B is a two-dimensional perspective view of the semiconductor device SD3a in the present embodiment. FIG. 23A is a cross-sectional view along the line A-A′ of FIG. 23B.

The semiconductor device SD3a includes a third sidewall SW3. The third sidewall SW3 is formed over the isolation film STI to be embedded in the first insulating film IF1. The first insulating film IF1 is formed with a third opening OP3. The third opening OP3 is defined by the inner wall of the third sidewall SW3. The lower electrode LE is formed to be embedded in the third opening 3. The semiconductor device SD3a has a configuration different in the foregoing components from that of the semiconductor device SD1a. The configuration of the semiconductor device SD3a is otherwise the same as that of the semiconductor device SD1a in the first embodiment except for the components particularly mentioned in the third embodiment.

In the semiconductor device SD3a, each of the lower electrode LE and the upper electrode UE of the capacitor element CP contains a metal. Thus, in the present embodiment, in the interlayer insulating film ID, the capacitor element CP can be formed which has the electrodes each containing a metal.

Using FIGS. 23A and 23B, a detailed description will be given of the semiconductor device SD3a. The semiconductor device SD3a includes the third sidewall SW3. The third sidewall SW3 is formed over the isolation film STI. The third sidewall SW3 is formed of an insulating film. The third sidewall SW3 may be formed of an oxide film (e.g., a silicon dioxide film). The third sidewall SW3 may be formed of the same material as that of each of the first sidewall SW1 and the second sidewall SW1. The first insulating film IF1 is formed with the third opening OP3. The third opening OP3 is defined by the inner wall of the third side wall SW3. In the present embodiment, the area of the third opening OP3 in planar view is larger than the area of the first opening OP1 in planar view and the area of the second opening OP2 in planar view, as shown in FIG. 23A. The lower electrode LE is formed to be embedded in the third opening OP3. In the present embodiment, the edge portion of the lower electrode LE in planar view overlies the first insulating film IF1 outside the region overlapping the third opening OP3 in planar view. In this case, as shown in FIG. 23A, the capacitor insulating film CI may also be formed over the portion of the lower electrode LE which overlies the first insulating film IF1 outside the region where the lower electrode LE overlaps the third opening OP3 in planar view.

In the present embodiment, the lower electrode LE is formed to be depressed along the third opening OP3. The surface of the lower electrode LE is formed with a small opening SOP. The small opening SOP is defined by the depression of the lower electrode LE. In the present embodiment, as shown in FIGS. 23A and 23B, the upper electrode UE may also be formed within the region overlapping the small opening SOP in planar view. In this case, it follows that the upper electrode UE has a portion overlapping the lower electrode LE in a height direction.

To the lower electrode LE, the third contact plugs CP3 are coupled. To the upper electrode UE, the fourth contact plugs CP4 are coupled. In the present embodiment, as shown in FIG. 23A, the third contact plugs CP3 may extend through the capacitor insulating film CI to reach the lower electrode LE. In the present embodiment, the height of the surface of each of the portions of the lower electrode LE which are coupled to the third contact plugs CP3 may be higher than the height of the surface of each of the portions of the upper electrode UE which are coupled to the fourth contact plugs CP4.

In the semiconductor device SD3a, each of the lower electrode LE and the upper electrode UE of the capacitor element CP contains a metal. Thus, in the present embodiment, in the interlayer insulating film ID, the capacitor element CP can be formed which has the electrodes each containing a metal.

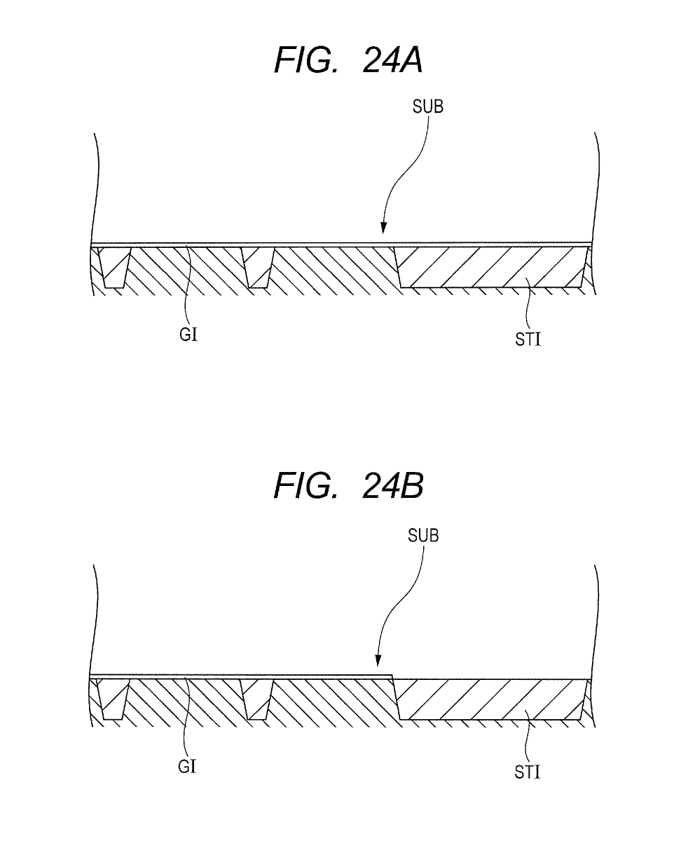

Next, using FIGS. 24A to 32B, a detailed description will be given of a manufacturing method of the semiconductor device SD3a in the present embodiment. FIGS. 24A to 32B are cross-sectional views showing the manufacturing method of the semiconductor device SD3a in the present embodiment.

First, in the substrate SUB, the isolation film STI is formed. This defines the element formation regions ER1 and ER2. Next, by ion implantation, the element formation region ER1 is doped with a p-type impurity and the element formation region ER2 is doped with an n-type impurity. As a result, in the element formation region ER1, a p-type well is formed while, in the element formation region ER2, an n-type well is formed. Next, over the substrate SUB, the insulating film GI is formed (FIG. 24A). Of the insulating film GI, each of the first gate insulating film GI1 and the second gate insulating film GI2 is formed. The insulating film GI may be formed of a silicon dioxide film (SO₂), a silicon oxynitride film (SiON film), or a high-dielectric-constant film (e.g., a hafnium silicate film (HfSiO) or a nitrogen-added hafnium silicate film). The thickness of the insulating film GI may also be controlled to be, e.g., 1 nm to 50 nm.

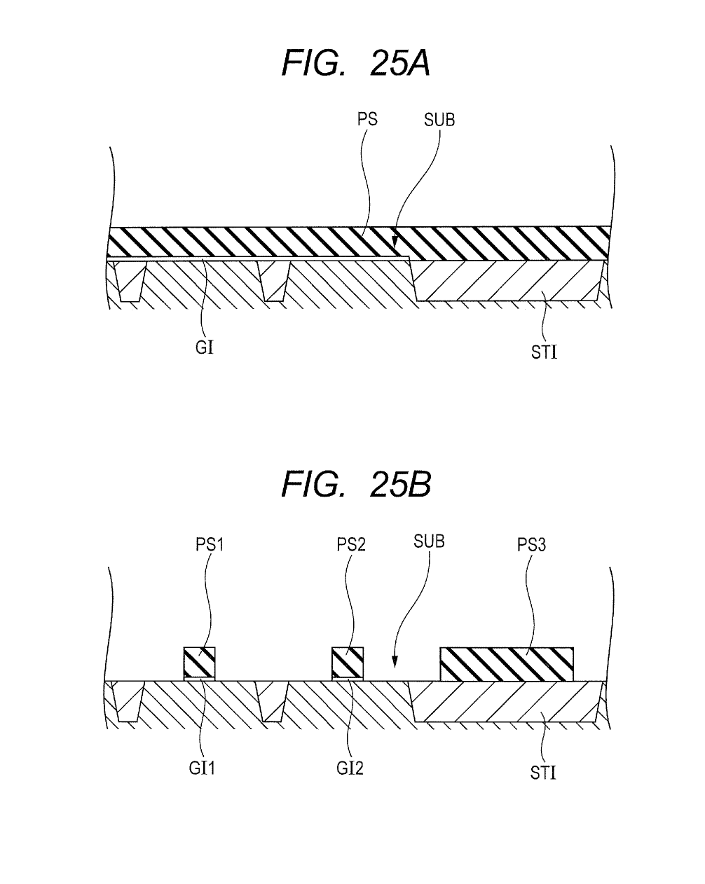

Next, the insulating film GI over the isolation film STI is removed therefrom, as shown in FIG. 24B. Then, over the substrate SUB, the polysilicon film PS is formed (FIG. 25A). The polysilicon film PS is formed of polysilicon. Of the polysilicon film PS, each of dummy gate electrodes is formed. The thickness of the polysilicon film PS may also be controlled to be, e.g., 100 nm.

Next, the polysilicon film PS and the insulating film GI are patterned. In this manner, on the element formation region ER1 side, the first gate insulating film GI1 and the first polysilicon film PS1 are formed. On the element formation region ER2 side, the second gate insulating film GI2 and the second polysilicon film PS2 are formed. Over the isolation film STI, a third polysilicon film PS3 is formed (FIG. 25B).

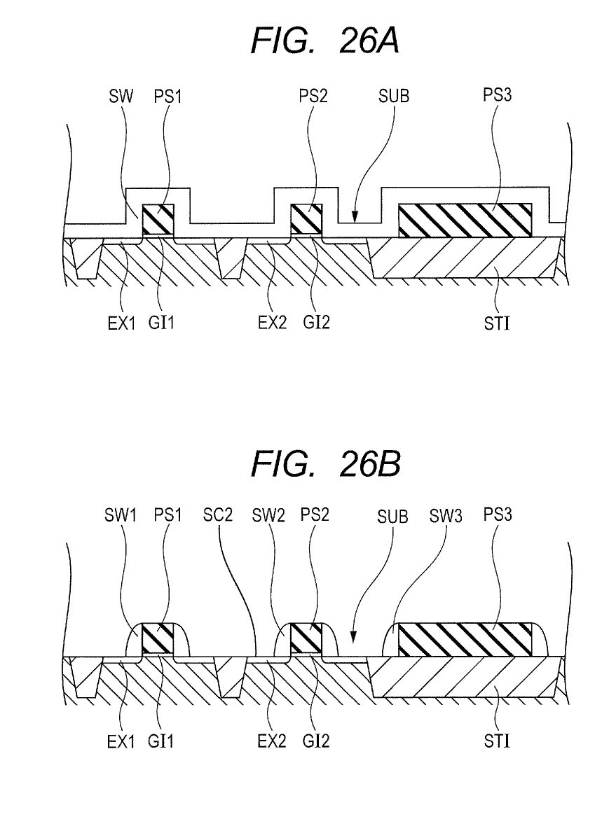

Next, in the same manner as in the steps shown in FIGS. 3A and 3B, in the element formation region ER1, the first extension region EX1 is formed in the surface of the substrate SUB while, in the element formation region ER2, the second extension region EX2 is formed in the surface of the substrate SUB. Then, as shown in FIG. 26A, over the surface of the substrate SUB, the insulating film SW is formed. The insulating film SW covers the first extension region EX1, the second extension region EX2, the first polysilicon film PS1, the second polysilicon film PS2, and the third polysilicon film PS3.

Next, by etching back the insulating film SW, the first sidewall SW1, the second sidewall SW2, and the third sidewall SW3 are formed (FIG. 26B). The first sidewall SW1 is formed so as to surround the first gate insulating film GI1 and the first polysilicon film PS1 in planar view. The second sidewall SW2 is formed so as to surround the second gate insulating film GI2 and the second polysilicon film PS2 in planar view. The third sidewall SW3 is formed so as to surround the third polysilicon film PS3 in planar view. In the present embodiment, each of the first sidewall SW1, the second sidewall SW2, and the third sidewall SW3 is formed of the insulating film SW. Thus, the first sidewall SW1, the second sidewall SW2, and the third sidewall SW3 are formed of the same material.

Next, in the same manner as in the steps shown in FIGS. 5A and 5B, in the element formation region ER1, the first source/drain region SDR1 is formed in the surface of the substrate SUB while, in the element formation region ER2, the second source/drain region SDR2 is formed in the surface of the substrate SUB. Then, in the same manner as in the steps shown in FIGS. 6A and 6B, the first silicide film SC1 is formed over the surface of the first source/drain region SDR1, while the second silicide film SC2 is formed over the surface of the second source/drain region SDR2.

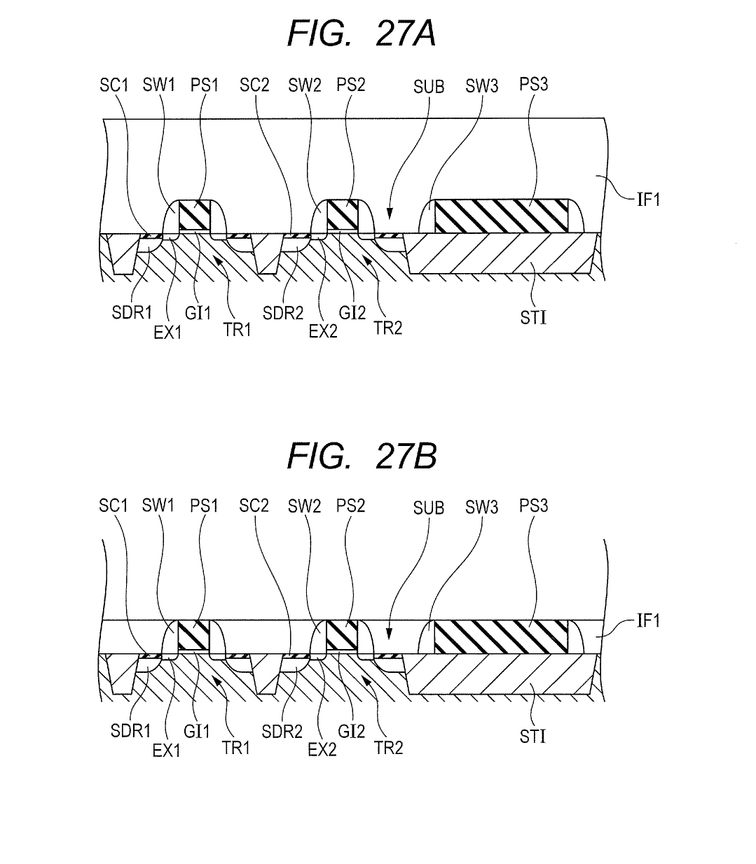

Next, the first insulating film IF1 is formed over the substrate SUB (FIG. 27A). The first insulating film FI1 may also be formed of a silicon dioxide film or a low-dielectric-constant film. As a result, the first polysilicon film PS1, the second polysilicon film PS2, and the third polysilicon film PS3 are embedded in the first insulating film IF1.

Next, the surface of the first insulating film IF1 is polished to be planarized. For the polishing of the first insulating film IF1, CMP may be used. As shown in FIG. 27B, the first insulating film IF1 is polished until the first polysilicon film PS1, the second polysilicon film PS2, and the third polysilicon film PS3 are exposed. In this case, as shown in FIG. 27B, the first insulating film IF1 may also be polished until the height of the surface of the first insulating film IF1 becomes equal to the height of each of the first sidewall SW1, the second sidewall SW2, and the third sidewall SW3.

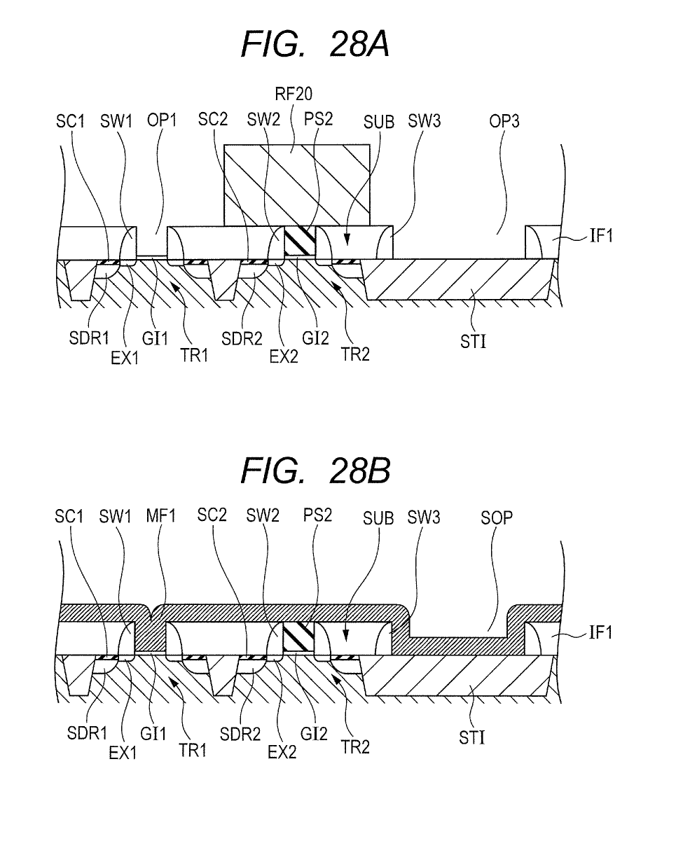

Next, in the element formation region ER2, a resist film RF20 is formed over the substrate SUB, as shown in FIG. 28A. Then, by etching, the first polysilicon film PS1 and the third polysilicon film PS3 are removed. As a result, the first opening OP1 is formed inwardly of the first sidewall SW1 and the third opening OP3 is formed inwardly of the third sidewall SW3 (FIG. 28A). The first opening OP1 is defined by the inner wall of the first sidewall SW1. The third opening OP3 is defined by the inner wall of the third sidewall SW3. In the present embodiment, the first gate insulating film GI1 is exposed through the first opening OP1, as shown in FIG. 28A. Likewise, the isolation film STI is exposed through the third opening OP3, as shown in FIG. 28A. In the present embodiment, the area of the third opening OP3 in planar view is larger than the area of the first opening OP1 in planar view.

Next, the resist film RF20 is removed. Then, over the substrate SUB, a first metal film MF1 is formed. As a result, each of the first opening OP1 and the third opening OP3 is filled with the first metal film MF1 (FIG. 28B). As shown in FIG. 28B, the first metal film MF1 is formed not only over the element formation region ER1 and the isolation film STI, but also over the element formation region ER2. Of the first metal film MF1, each of the first gate electrode GE1 and the upper electrode UE is formed. In the present embodiment, the first metal film MF1 is formed to a thickness which allows roughness due to the third opening OP3 to remain in the surface of the first metal film MF1. As a result, within the region overlapping the third opening OP3 in planar view, the small opening SOP is formed. The small opening SOP is defined by the surface of the first metal film MF1. The first metal film MF1 contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1). The thickness of the first metal film MF1 may be controlled to be, e.g., 5 nm to 200 nm over the isolation region STI.

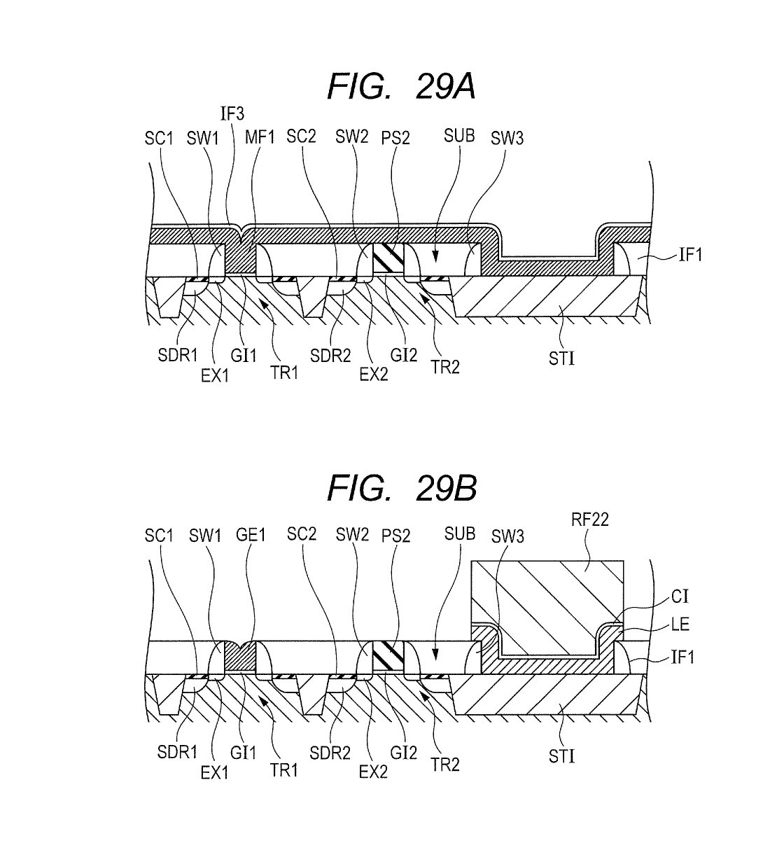

Next, over the first metal film MF1, the insulating film IF3 is formed (FIG. 29A). Of the insulating film IF3, the capacitor insulating film CI1 is formed. The thickness of the insulating film IF3 may be, e.g., 5 nm to 100 nm. The insulating film IF may be formed of a silicon dioxide film, a silicon nitride film, or a metal oxide (e.g., tantalum oxide, zirconium oxide, hafnium oxide, lanthanum oxide, or yttrium oxide).

Next, over the isolation film STI, a resist film RF22 is formed, as shown in FIG. 29B. In the present embodiment, the resist film RF22 is formed so as to overlap not only a third region overlapping the third opening OP3 in planar view, but also a peripheral region of the third region in planar view. Then, using the resist film RF22 as a mask, the insulating film IF3 and the first metal film MF1 are etched. As a result, in the element formation region ER1, the first gate electrode GE1 is formed while, over the isolation film STI, the lower electrode LE and the capacitor insulating film CI1 are formed (FIG. 29B). In the present embodiment, the lower electrode LE is formed to be embedded in the third opening OP3, as shown in FIG. 29B. In the present embodiment, the resist film RF22 prevents the first metal film MF1 and the insulating film IF3 from being etched in the third region and the peripheral region of the third region. As a result, the edge portion of the lower electrode LE in planar view overlies the first insulating film IF1 outside the region overlapping the third opening OP3 in planar view. In the present embodiment, each of the first gate electrode GE1 and the lower electrode LE is formed of the first metal film MF1. Thus, the first gate electrode GE1 and the lower electrode LE are formed of the same material.

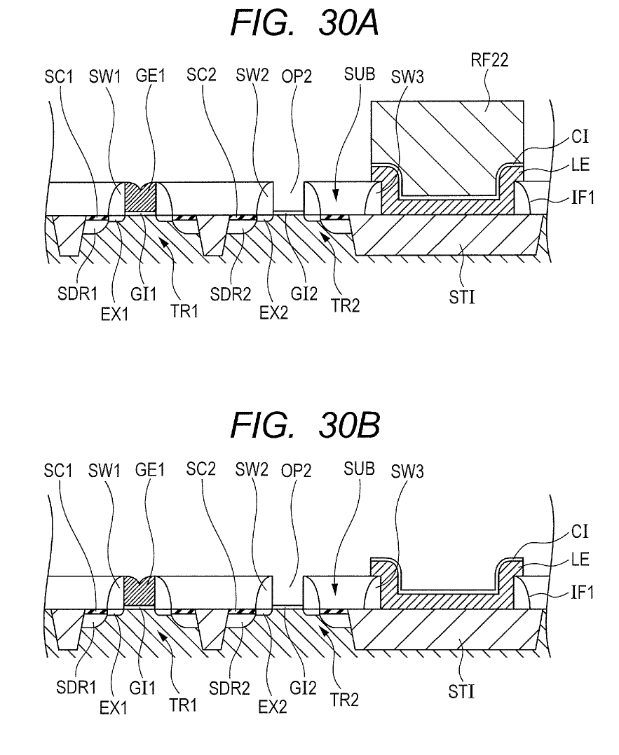

Next, by further performing etching, the second polysilicon film PS2 is removed. As a result, the second opening OP2 is formed inwardly of the second sidewall SW2 (FIG. 30A). The second opening OP2 is defined by the inner wall of the second sidewall SW2. In the present embodiment, the second gate insulating film GI2 is exposed through the second opening OP2, as shown in FIG. 30A. In the present embodiment, the area of the second opening OP2 in planar view is smaller than the area of the third opening OP3 in planar view.

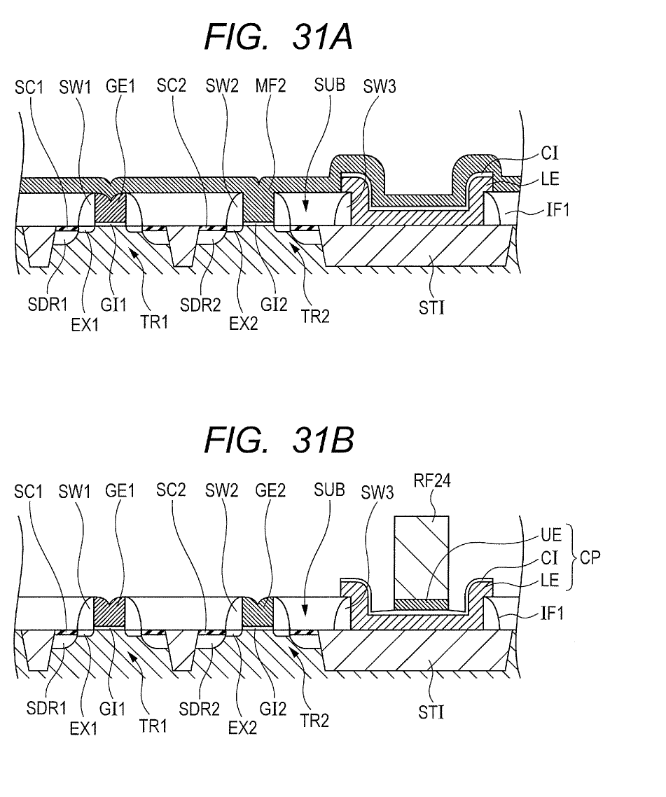

Next, the resist film RF22 is removed (FIG. 30B). Then, over the substrate SUB, the second metal film MF2 is formed. As a result, the second opening OP2 is filled with the second metal film MF2 (FIG. 31A). As shown in FIG. 31A, the second metal film MF2 is formed not only over the element formation region ER2, but also over the element formation region ER1 and the isolation film STI. The second metal film MF2 contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1). The thickness of the second metal film MF2 may be controlled to be, e.g., 5 nm to 200 nm over the lower electrode LE.

Next, over the isolation film STI, a resist film RF24 is formed over the second metal film MF2, as shown in FIG. 31B. In the present embodiment, the resist film RF24 over the isolation film STI is formed within the region overlapping the small opening SOP in planar view. Then, using the resist film R24 as a mask, the second metal film MF2 is etched. In the etching, an etching rate is selected so as to stop the etching at the first insulating film IF1 and the capacitor insulating film CI. As a result, in the element formation region ER2, the second gate electrode GE2 is formed while, over the isolation film STI, the upper electrode UE is formed (FIG. 31B). Thus, over the isolation film STI, the capacitor element CP is formed. In the present embodiment, each of the second gate electrode GE2 and the upper electrode UE is formed of the second metal film ME2. Thus, the second gate electrode GE2 and the upper electrode UE are formed of the same material.

In the present embodiment, due to the resist film RF24, the upper electrode UE is formed within the region overlapping the small opening SOP in planar view. In this case, when the respective film thicknesses of the lower electrode LE and the capacitor insulating film CI are determined appropriately, the upper electrode UE has a portion overlapping the lower electrode LE in the height direction. In the present embodiment, at a position at which the capacitor insulating film CI does not overlap the resist film RF24, a part or the whole of the capacitor insulating film CI is removed by etching together with the second metal film MF2. As a result, the thickness of the capacitor insulating film CI at the position at which the upper electrode UE does not overlap the capacitor insulating film CI in planar view may be smaller than the thickness of the capacitor insulating film CI at a position at which the upper electrode UE overlaps the capacitor insulating film CI in planar view, as shown in FIG. 31B.

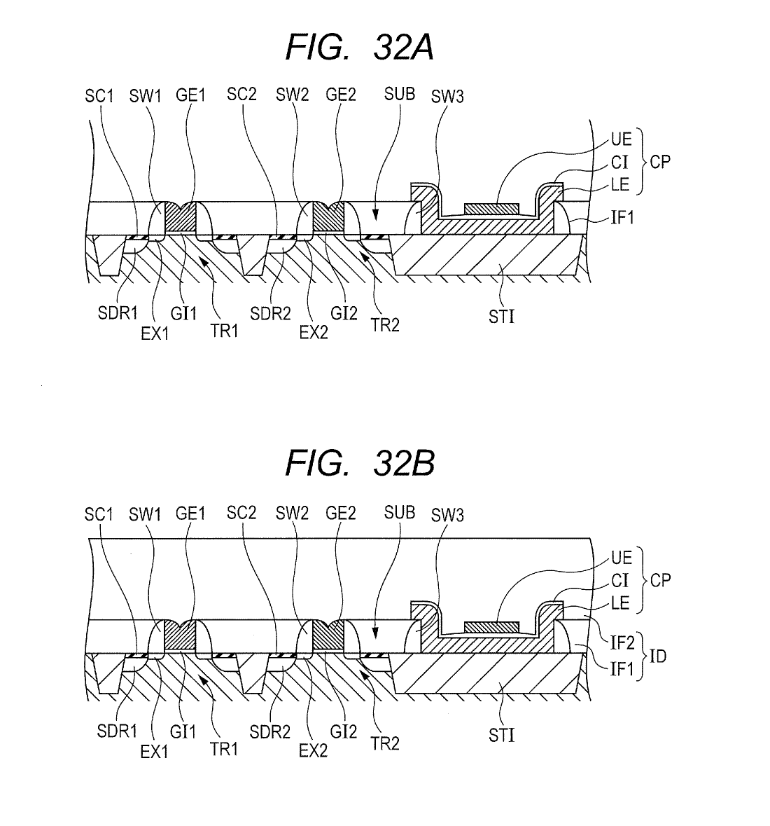

Next, the resist film RF24 is removed (FIG. 32A). Then, over the substrate SUB, the second insulating film IF2 is formed (FIG. 32B). The second insulating film IF2 covers the first gate electrode GE1, the second gate electrode GE2, and the upper electrode UE. In this manner, the interlayer insulating film ID is formed. The second insulating film IF2 may be formed of a silicon dioxide film or a low-dielectric-constant film.

Next, in the second insulating film IF2, contact holes (not shown) are formed. The contact holes are filled with conductive members to form the first contact plug CP1, the second contact plug CP2, the third contact plugs CP3, and the fourth contact plugs CP4. In this manner, the semiconductor device SD3a shown in FIG. 23A is formed.

In the present embodiment, each of the first gate electrode GE1 and the lower electrode LE is formed of the first metal film MF1. Each of the second gate electrode GE2 and the upper electrode UE is formed of the second metal film MF2. Accordingly, in the present embodiment, the capacitor element CP including the electrodes each containing a metal is formed in the smaller number of process steps.

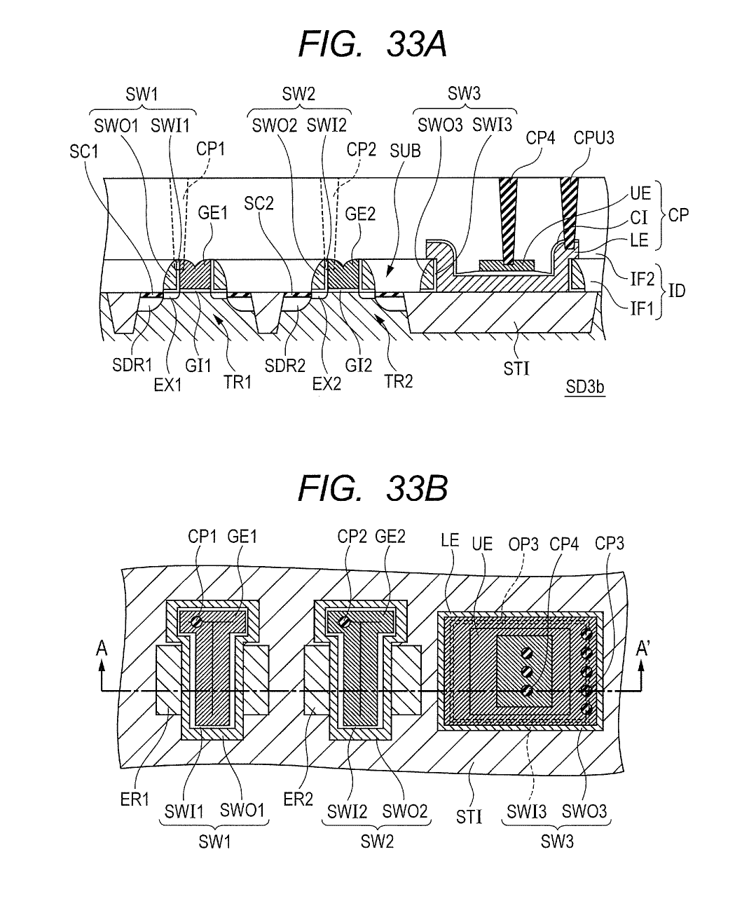

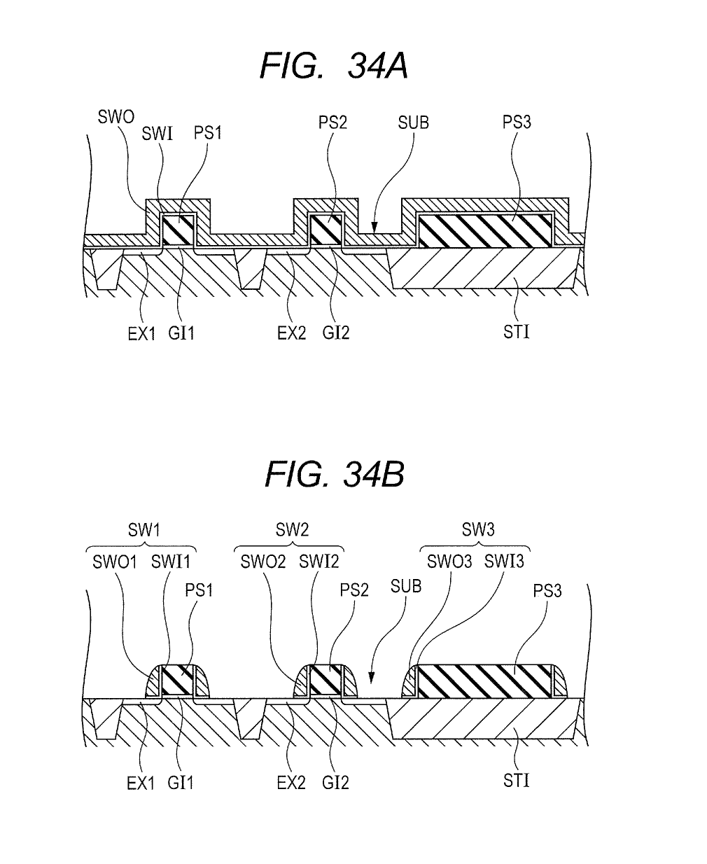

Next, using FIGS. 33A, 33B, 34A, and 34B, a description will be given of another example of the present embodiment. FIG. 33A is a cross-sectional view showing a semiconductor device SD3b in the other example of the third embodiment. FIG. 33B is a two-dimensional perspective view of the semiconductor device SD3b in the present embodiment. FIG. 33A is a cross-sectional view along the line A-A′ of FIG. 33B. The semiconductor device SD3b shown in FIGS. 33A and 33B has the same configuration as that of the semiconductor device SD3a shown in FIGS. 23A and 23B except that the first sidewall SW1 includes the sidewalls SWI1 and SWO1, the second sidewall SW2 includes the sidewalls SWI2 and SWO2, and the third sidewall SW3 includes a sidewall SWI3 and a sidewall SWO3.

A detailed description will be given of the semiconductor device SD3b shown in FIGS. 33A and 33B. The first sidewall SW1 and the second sidewall SW2 in the semiconductor device SD3b shown in FIGS. 33A and 33B have the same configurations as those of the first sidewall SW1 and the second sidewall SW2 in the semiconductor device SD1b shown in FIGS. 13A and 13B. The semiconductor device SD3b further includes the third sidewall SW3. The third sidewall SW3 includes the sidewalls SWI3 and SWO3.

The sidewall SWI3 is in contact with the surface of the substrate SUB and with the side surface of the portion of the lower electrode LE which is embedded in the third opening OP3 (embedded portion of the lower electrode LE). The sidewall SWI3 is formed along the surface of the substrate SUB and the side surface of the embedded portion of the lower electrode LE. Accordingly, the sidewall SWI3 has a letter-L shape when viewed in the A-A′ direction. The sidewall SWI3 is formed so as to surround the embedded portion of the lower electrode LE in planar view. In the present embodiment, the respective film thicknesses of the sidewalls SWI1, SWI2, and SWI3 may be generally the same.

The sidewall SWO3 is formed over the surface of the substrate SUB via the sidewall SWI3 and also formed over the side surface of the embedded portion of the lower electrode LE via the sidewall SWI3. The sidewall SWO3 is formed so as to surround the embedded portion of the lower electrode LE in planar view.

Each of the sidewalls SWI1, SWI2, SWI3, SWO1, SWO2, and SWO3 is formed of an insulating film. In the present embodiment, each of the sidewalls SWI1, SWI2, and SWI3 may be formed of an oxide film (e.g., a silicon dioxide film). On the other hand, each of the sidewalls SWO1, SWO2, and SWO3 may be formed of a nitride film (e.g., a silicon nitride film). In the present embodiment, the sidewalls SWI1, SWI2, and SWI3 may be formed of the same material. The sidewalls SWO1, SWO2, and SWO3 may be formed of the same material.

Next, using FIGS. 34A and 34B, a description will be given of a method of forming the semiconductor device SD3b. FIGS. 34A and 34B are cross-sectional views each showing a manufacturing method of the semiconductor device SD3b in the present embodiment.

First, in the same manner as in the semiconductor device SD3a, the steps shown in FIGS. 24A, 24B, 25A, and 25B are performed. Then, over the surface of the substrate SUB, the insulating film SWI is formed. The insulating film SWI covers the first extension region EX1, the second extension region EX2, the first polysilicon film PS1, the second polysilicon film PS2, and the third polysilicon film PS3. In the present embodiment, the insulating film SW1 may be formed of an oxide film (e.g., a silicon dioxide film). Then, over the insulating film SWI, an insulating film SWO is formed (FIG. 34A). In the present embodiment, the insulating film SWO may be formed of a nitride film (e.g., a silicon nitride film).

Next, by etching back the insulating films SWI and SWO, the first sidewall SW1, the second sidewall SW2, and the third sidewall SW3 are formed (FIG. 34B). In this case, when the insulating film SWI has a uniform thickness over the substrate SUB, the respective thicknesses of the first sidewall SW1, the second sidewall SW2, and the third sidewall SW3 are generally the same. In the present embodiment, each of the sidewalls SWI1, SWI2, and SWI3 is formed of the insulating film SWI. Thus, the sidewalls SWI1, SWI2, and SWI3 are formed of the same material. Likewise, each of the sidewalls SWO1, SWO2, and SWO3 is formed of the insulating film SWO. Thus, the sidewalls SWO1, SWO2, and SWO3 are formed of the same material.

Next, in the same manner as in the semiconductor device SD1a, steps including the process steps shown in FIGS. 27A to 32B are performed. In this manner, the semiconductor device SD3b is formed.

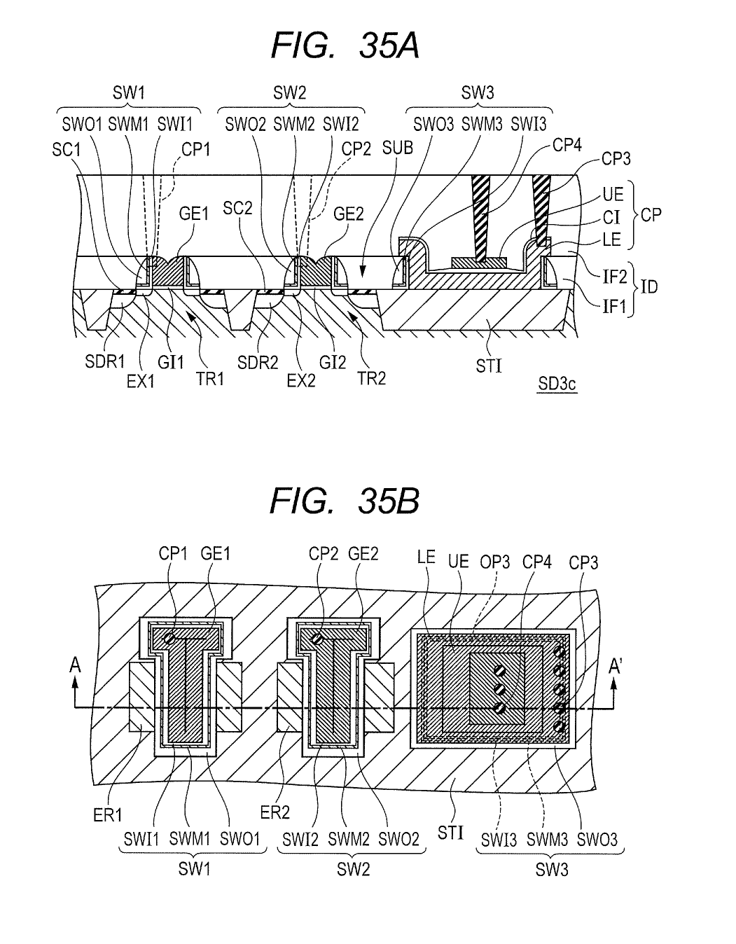

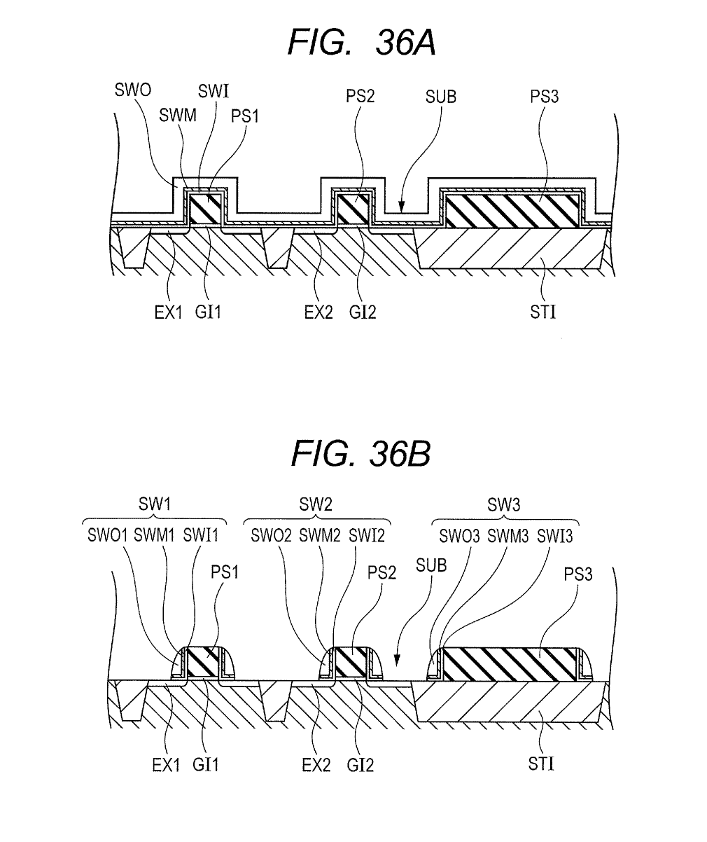

Next, using FIGS. 35A, 35B, 36A, and 36B, a description will be given of still another example of the present embodiment. FIG. 35A is a cross-sectional view showing a semiconductor device SD3c in the still other example of the third embodiment. FIG. 35B is a two-dimensional perspective view of the semiconductor device SD3c in the present embodiment. FIG. 35A is a cross-sectional view along the line A-A′ of FIG. 35B. The semiconductor device SD3c shown in FIGS. 35A and 35B has the same configuration as that of the semiconductor device SD3a shown in FIGS. 23A and 23B except that the first sidewall SW1 includes the sidewalls SWI1, SWM1, and SWO1, the second sidewall SW2 includes the sidewalls SWI2, SWM2, and SWO2, and the third sidewall SW3 includes the sidewall SWI3, a sidewall SWM3, and the sidewall SWO3.

A detailed description will be given of the semiconductor device SD3c shown in FIGS. 35A and 35B. The first sidewall SW1 and the second sidewall SW2 in the semiconductor device SD3c shown in FIGS. 35A and 35B have the same configurations as those of the first sidewall SW1 and the second sidewall SW2 in the semiconductor device SD1c shown in FIGS. 15A and 15B. The semiconductor device SD3c further includes the third sidewall SW3. The third sidewall SW3 includes the sidewalls SWI3, SWM3, and SWO3.

The sidewall SWI1 is in contact with the surface of the substrate SUB and with the side surface of the portion of the lower electrode LE which is embedded in the third opening OP3 (embedded portion of the lower electrode LE). The sidewall SW13 is formed along the surface of the substrate SUB and the side surface of the embedded portion of the lower electrode LE. Accordingly, the sidewall SWI3 has a letter-L shape when viewed in the A-A′ direction. The sidewall SWI3 is formed so as to surround the embedded portion of the lower electrode LE in planar view. In the present embodiment, the respective film thicknesses of the sidewalls SWI1, SWI2, and SWI3 may be generally the same.

The sidewall SWM3 is formed over the surface of the substrate SUB via the sidewall SWI3 and also over the side surface of the portion of the lower electrode LE which is embedded in the third opening OP3 (embedded portion of the lower electrode LE) via the sidewall SWI3. The sidewall SWM3 is formed along the sidewall SMI3. Accordingly, the sidewall SWM3 has a letter-L shape when viewed in the A-A′ direction. The sidewall SWM3 is formed so as to surround the embedded portion of the lower electrode LE in planar view. In the present embodiment, the respective film thicknesses of the sidewalls SWM1, SWM2, and SWM3 may be generally the same.

The sidewall SWO3 is formed over the surface of the substrate SUB via the sidewalls SWI3 and SWM3 and also over the side surface of the embedded portion of the lower electrode LE via the sidewalls SWI3 and SWM3. The sidewall SWO3 is formed so as to surround the embedded portion of the lower electrode LE in planar view.

Each of the sidewalls SWI1, SWI2, SWI3, SWM1, SWM2, SWM3, SWO1, SWO2, and SWO3 is formed of an insulating film. In the present embodiment, each of the sidewalls SWI1, SWI2, and SWI3 may be formed of an oxide film (e.g., a silicon dioxide film). Each of the sidewalls SWM1, SWM2, and SWM3 may be formed of a nitride film (e.g., a silicon nitride film). Each of the sidewalls SWO1, SWO2, and SWO3 may be formed of an oxide film (e.g., a silicon dioxide film). In the present embodiment, the sidewalls SWI1, SWI2, and SWI3 may be formed of the same material. The sidewalls SWM1, SWM2, and SWM3 may be formed of the same material. The sidewalls SWO1, SWO2, and SWO3 may be formed of the same material.

In the semiconductor device SD3c also, each of the first gate electrode GE1 and the lower electrode LE is formed of the first metal film MF1. Each of the second gate electrode GE2 and the upper electrode UE is formed of the second metal film MF2. Accordingly, in the present embodiment, the capacitor element CP including the electrodes each containing a metal is formed in the smaller number of process steps.

Next, using FIGS. 36A and 36B, a description will be given of a method of forming the semiconductor device SD3c. FIGS. 36A and 36B are cross-sectional views each showing a manufacturing method of the semiconductor device SD3c in the present embodiment.

First, in the same manner as in the semiconductor device SD3a, the steps shown in FIGS. 24A, 24B, 25A, and 25B are performed. Then, over the surface of the substrate SUB, the insulating film SWI is formed. The insulating film SWI covers the first extension region EX1, the second extension region EX2, the first polysilicon film PS1, the second polysilicon film PS2, and the third polysilicon film PS3. In the present embodiment, the insulating film SW1 may be formed of an oxide film (e.g., a silicon dioxide film). Then, over the insulating film SWI, the insulating film SWM is formed. In the present embodiment, the insulating film SWM may be formed of a nitride film (e.g., a silicon nitride film). Then, over the insulating film SWM, the insulating film SWO is formed (FIG. 36A). In the present embodiment, the insulating film SWO may be formed of an oxide film (e.g., a silicon dioxide film).

Next, by etching back the insulating films SWI, SMW, and SWO, the first sidewall SW1, the second sidewall SW2, and the third sidewall SW3 are formed (FIG. 36B). In this case, when the insulating film SWI has a uniform thickness over the substrate SUB, the respective film thicknesses of the sidewalls SWI1, SWI2, and SWI3 are generally the same. Likewise, when the insulating film SWM has a uniform thickness over the substrate SUB, the respective film thicknesses of the sidewalls SWM1, SWM2, and SWM3 are generally the same. In the present embodiment, each of the sidewalls SWI1, SWI2, and SWI3 is formed of the insulating film SWI. Thus, the sidewalls SWI1, SWI2, SWI3 are formed of the same material. Likewise, each of the sidewalls SWM1, SWM2, and SWM3 is formed of the insulating film SWM. Thus, the sidewalls SWM1, SWM2, and SWM3 are formed of the same material. Likewise, each of the sidewalls SWO1, SWO2, and SWO3 is formed of the insulating film SWO. Thus, the sidewalls SWO1, SWO2, and SWO3 are formed of the same material.

Next, in the same manner as in the semiconductor device SD3a, steps including the process steps shown in FIGS. 27A to 32B are performed. In this manner, the semiconductor device SD3c is formed.

In the semiconductor device SD3c also, each of the first gate electrode GE1 and the lower electrode LE is formed of the first metal film MF1. Each of the second gate electrode GE2 and the upper electrode UE is formed of the second metal film MF2. Accordingly, in the present embodiment, the capacitor element CP including the electrodes each containing a metal is formed in a smaller number of process steps.

In the present embodiment, the first gate electrode GE1 of the n-type first transistor TR1 and the lower electrode LE are formed of the same material (first metal film MF1) and the second gate electrode GE2 of the p-type second transistor TR2 and the upper electrode UE are formed of the same material (second metal film MF2). In another example, it may also be possible that the second gate electrode GE2 of the p-type second transistor TR2 and the lower electrode LE are formed of the same material (first metal film MF1) and the first gate electrode GE1 of the n-type first transistor TR1 and the upper electrode UE are formed of the same material (second metal film MF2). In either case, the first metal film MF1 forming the lower electrode LE is embedded in the first opening OP1 of the first transistor TR1 or in the second opening OP2 of the second transistor TR2 before the second metal film MF2 is embedded.

In the present embodiment, in the step shown in FIG. 29B, the resist film RF22 is not formed over the element formation region ER1. In another example, it may also be possible that, in the same manner as in the step shown in FIG. 18A in the second embodiment, the resist film RF22 is formed over the element formation region ER1. In this case, the semiconductor device SD3a in the present embodiment can include the first gate electrode GE1 and the insulating film CI′ in the semiconductor device SD2a in the second embodiment.

In the present embodiment, each of the first gate electrode GE1, the second gate electrode GE2, the lower electrode LE, and the upper electrode UE is formed in a single layer. In another example, it may also be possible that each of the first gate electrode GE1, the second gate electrode GE2, the lower electrode LE, and the upper electrode UE is formed in a plurality of layers. In this case, the order in which the layers are stacked for the first gate electrode GE1 is the same as the order in which the layers are stacked for the lower electrode LE, while the order in which the layers are stacked for the second gate electrode GE2 is the same as the order in which the layers are stacked for the upper electrode UE.

In the present embodiment, each of the first gate electrode GE1, the second gate electrode GE2, the lower electrode LE, and the upper electrode UE contains a metal. In another example, it may also be possible that each of the first gate electrode GE1, the second gate electrode GE2, the lower electrode LE, and the upper electrode UE is formed of a material (e.g., polysilicon) other than a metal. In this case also, the first gate electrode GE1 and the lower electrode LE are formed of the same material and the second gate electrode GE2 and the upper electrode UE are formed of the same material.

### Fourth Embodiment

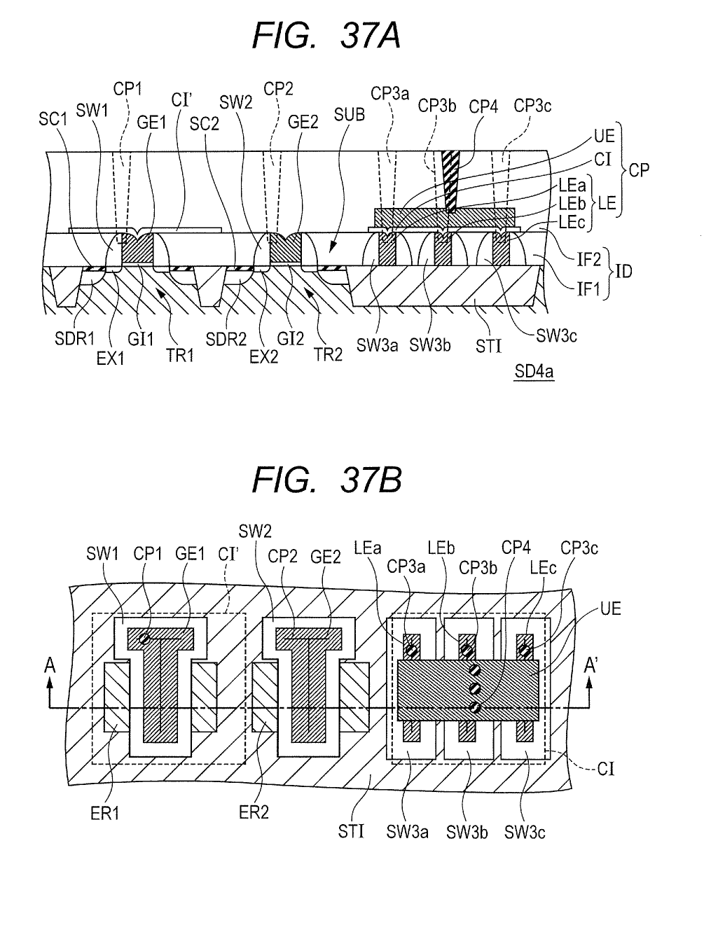

FIG. 37A is a cross-sectional view of a semiconductor device SD4a in a fourth embodiment. FIG. 37B is a two-dimensional perspective view of the semiconductor device SD4a in the present embodiment. FIG. 37A is a cross-sectional view along the line A-A′ of FIG. 37B.

In the semiconductor device SD4a, a plurality of third sidewalls SW3a, SW3b, and SW3c define a plurality of third openings OP3a, OP3b, and OP3c. The third openings OP3a, OP3b, and OP3c are respectively filled with lower electrodes LEa, LEb, and LEc. The lower electrodes LEa, LEb, and LEc are electrically insulated from each other via the third sidewalls SW3a, SW3b, and SW3c and the first insulating film IF1. The semiconductor device SD4a has a configuration different in the foregoing components from that of the semiconductor device SD3a. The configuration of the semiconductor device SD4a is otherwise the same as that of the semiconductor device SD3a in the third embodiment except for the components particularly mentioned in the fourth embodiment.

In the semiconductor device SD4a, each of the lower electrode LE and the upper electrode UE of the capacitor element CP contains a metal. Thus, in the present embodiment, in the interlayer insulating film ID, the capacitor element CP can be formed which has the electrodes each containing a metal.

Using FIGS. 37A and 37B, a detailed description will be given of the semiconductor device SD4a. In the semiconductor device SD4a, the plurality of third sidewalls SW3a, SW3b, and SW3c respectively define the plurality of third openings OP3a, OP3b, and OP3c. Each of the third sidewalls SW3a, SW3b, and SW3c is formed of an insulating film. Each of the third sidewalls SW3a, SW3b, and SW3c may be formed of an oxide film (e.g., a silicon dioxide film). The third sidewalls SW3a, SW3b, and SW3c may be formed of the same material. The third sidewalls SW3a, SW3b, and SW3c may be formed of the same material as that of each of the first sidewall SW1 and the second sidewall SW2. In the present embodiment, the respective areas of the third openings OP3a, OP3b, and OP3c in planar view may be the same. The respective areas of the third openings OP3a, OP3b, and OP3c in planar view may be smaller than the area of the first opening OP1 and the area of the second opening OP2 in planar view. In the present embodiment, the third openings OP3a, OP3b, and OP3c are respectively filled with the lower electrodes LEa, LEb, and LEc. The lower electrodes LEa, LEb, and LEc are electrically isolated from each other via the third sidewalls SW3a, SW3b, and SW3c and the first insulating film IF1. In FIGS. 37A and 37B, the number of the third openings is three, but the number of the third openings in the present embodiment is not limited to three. In the present embodiment, the number of the third openings may be plural or one.

In the present embodiment, the capacitor insulating film CI is formed in the form of a sheet to cover the plurality of third openings OP3a, OP3b, and OP3c. The semiconductor device SD4a may also further include the insulating film CI′. The insulating film CI′ is formed between the first gate electrode GE1 and the second insulating film IF2. In this case, the capacitor insulating film CI and the insulating film CI′ are formed of the same material. In the present embodiment, as shown in FIG. 37A, the capacitor insulating film CI is in contact with the surface of the first insulating film IF1 outside the region overlapping the third openings OP3a, OP3b, and OP3c in planar view. Likewise, the insulating film CI′ is in contact with the surface of the first insulating film IF1 outside the region overlapping the first opening OP1 in planar view. In the present embodiment, as shown in FIG. 37B, the upper electrode UE is formed within the region overlapping the capacitor insulating film CI in planar view.

In the present embodiment, the third contact plugs CP3a, CP3b, and CP3c are respectively coupled to the lower electrodes LEa, LEb, and LEc, as shown in FIGS. 37A and 37B. As shown in FIGS. 37B, the third contact plugs CP3a, CP3b, and CP3c may also be formed on a straight line extending in a direction orthogonal to the extending directions of the lower electrodes LEa, LEb, and LEc. When the third contact plugs CP3a, CP3b, and CP3c are formed in the region where the third contact plugs CP3a, CP3b, and CP3c overlap the capacitor insulating film CI in planar view, the third contact plugs CP3a, CP3b, and CP3c extend through the capacitor insulating film CI to respectively reach the lower electrodes LEa, LEb, and LEc. In the present embodiment, as shown in FIG. 37B, a plurality of the fourth contact plugs CP4 may also be formed. In this case, as shown in FIG. 37B, the fourth contact plugs CP4 may also be formed on a straight line extending in the extending directions of the lower electrodes LEa, LEb, and LEc.

In the semiconductor device SD4a, each of the lower electrodes LEa, LEb, and LEc and the upper electrode UE of the capacitor element CP contains a metal. Thus, in the present embodiment, in the interlayer insulating film ID, the capacitor element CP can be formed which has the electrodes each containing a metal.

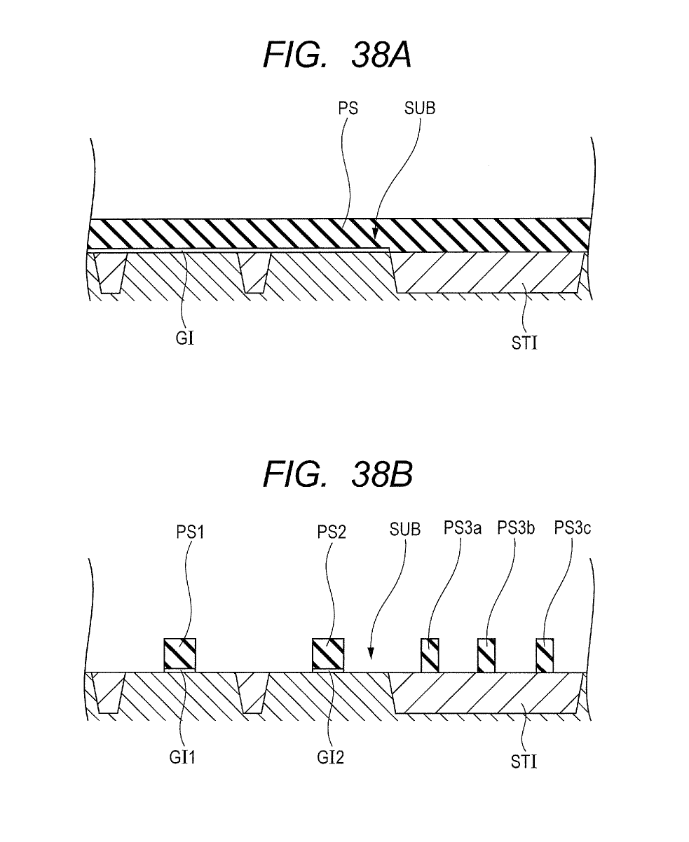

Next, using FIGS. 38A to 44B, a detailed description will be given of a manufacturing method of the semiconductor device SD4a in the present embodiment. FIGS. 38A to 44B are cross-sectional views showing the manufacturing method of the semiconductor device SD4a in the present embodiment.

First, in the same manner as for the semiconductor device SD3a, the process steps shown in FIGS. 24A and 24B are performed. Then, over the substrate SUB, the polysilicon film PS is formed (FIG. 38A). The polysilicon film PS is formed of polysilicon. Of the polysilicon film PS, each of dummy gate electrodes is formed. The thickness of the polysilicon film PS may be controlled to be, e.g., 100 nm.

Next, the polysilicon film PS and the insulating film GI are patterned. In this manner, on the element formation region ER1 side, the first gate insulating film GI1 and the first polysilicon film PS1 are formed. On the other hand, on the element formation region ER2 side, the second gate insulating film GI2 and the second polysilicon film PS2 are formed. Over the isolation film STI, third polysilicon films PS3a, PS3b, and PS3c are formed (FIG. 38B).

Next, in the same manner as in the steps shown in FIGS. 3A and 3B, the first extension region EX1 and the second extension region EX2 are formed. Then, in the same manner as in the steps shown in FIGS. 26A and 26B, the first sidewall SW1, the second sidewall SW2, and the third sidewalls SW3a, SW3b, and SW3c are formed. Then, in the same manner as in the steps shown in FIGS. 5A and 5B, the first source/drain region SDR1 and the second source/drain region SDR2 are formed. Then, in the same manner as in the steps shown in FIGS. 6A and 6B, the first silicide film SC1 and the second silicide film SC2 are formed.

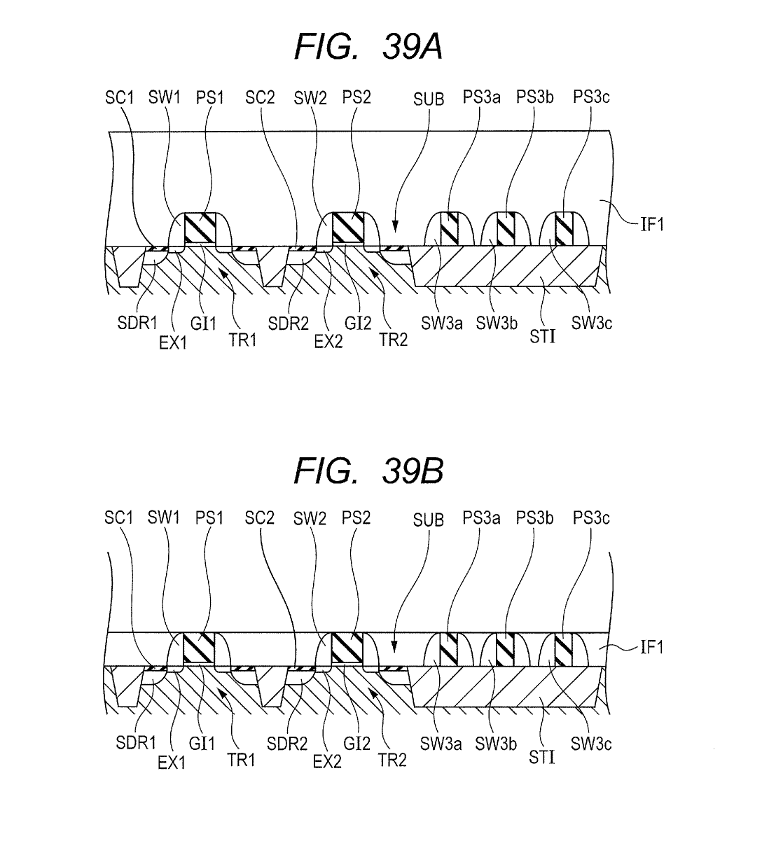

Next, the insulating film IF1 is formed over the substrate SUB (FIG. 39A). The insulating film IF1 may be formed of a silicon dioxide film or a low-dielectric-constant film. As a result, the first polysilicon film PS1, the second polysilicon film PS2, and the third polysilicon films PS3a, PS3b, and PS3c are embedded in the insulating film IF1.

Next, the surface of the insulating film IF1 is polished to be planarized. For the polishing of the insulating film IF1, CMP may be used. As shown in FIG. 39B, the insulating film IF1 is polished until the first polysilicon film PS1, the second polysilicon film PS2, and the third polysilicon films PS3a, PS3b, and PS3c are exposed. In this case, as shown in FIG. 39B, the insulating film IF1 may also be polished until the height of the surface of the insulating film IF1 becomes equal to the height of each of the first sidewall SW1, the second sidewall SW2, and the third sidewalls SW3a, SW3b, and SW3c.

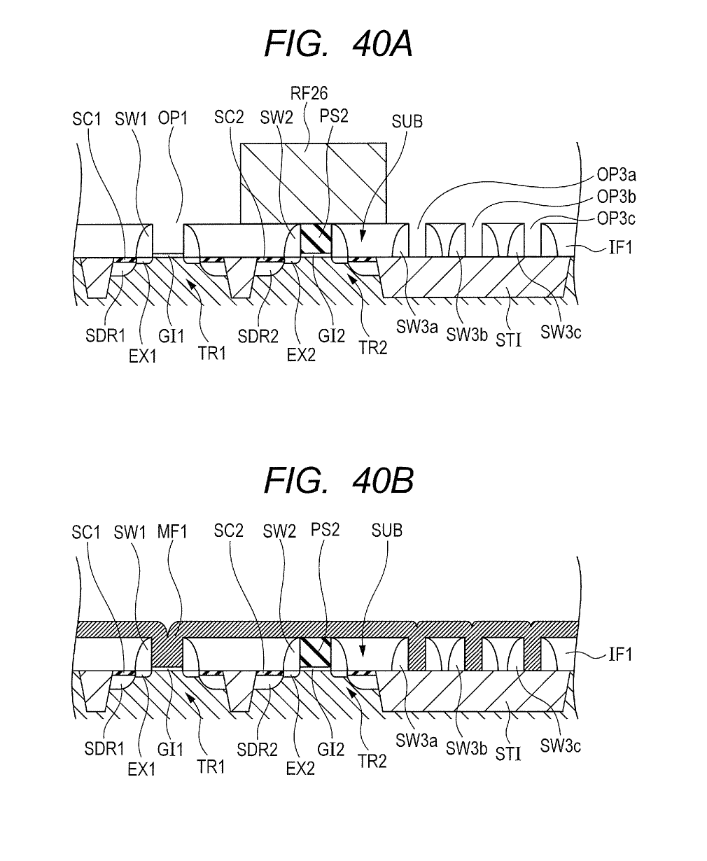

Next, in the element formation region ER2, a resist film RF26 is formed over the substrate SUB, as shown in FIG. 40A. Then, by etching, the first polysilicon film PS1, the second polysilicon film PS2, and the third polysilicon films PS3a, PS3b, and PS3c are removed. As a result, the first opening OP1 is formed inwardly of the first sidewall SW1 and the third openings OP3a, OP3b, and OP3c are respectively formed inwardly of the third sidewalls SW3a, SW3b, and SW3c (FIG. 40A). The first opening OP1 is defined by the inner wall of the first sidewall SW1. The third openings OP3a, OP3b, and OP3c are defined by the respective inner walls of the third sidewalls SW3a, SW3b, and SW3c. In the present embodiment, the first gate insulating film GI1 is exposed through the first opening OP1, as shown in FIG. 40A. Likewise, as shown in FIG. 40A, the isolation film STI is exposed through the third openings OP3a, OP3b, and OP3c. In the present embodiment, the area of each of the third openings OP3a, OP3b, and OP3c in planar view is smaller than the area of the first opening OP1 in planar view.

Next, the resist film RF26 is removed. Then, over the substrate SUB, the first metal film MF1 is formed. As a result, the first opening OP1 and the third openings OP3a, OP3b, and OP3c are filled with the first metal film MF1 (FIG. 40B). As shown in FIG. 40B, the first metal film MF1 is formed not only over the element formation region ER1 and the isolation film STI, but also over the element formation region ER2. Of the first metal film MF1, each of the first gate electrode GE1 and the lower electrode LEa, LEb, and LEc is formed. The first metal film MF1 contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1). The thickness of the first metal film MF1 may be controlled to be, e.g., 5 nm to 200 nm over the isolation region STI.

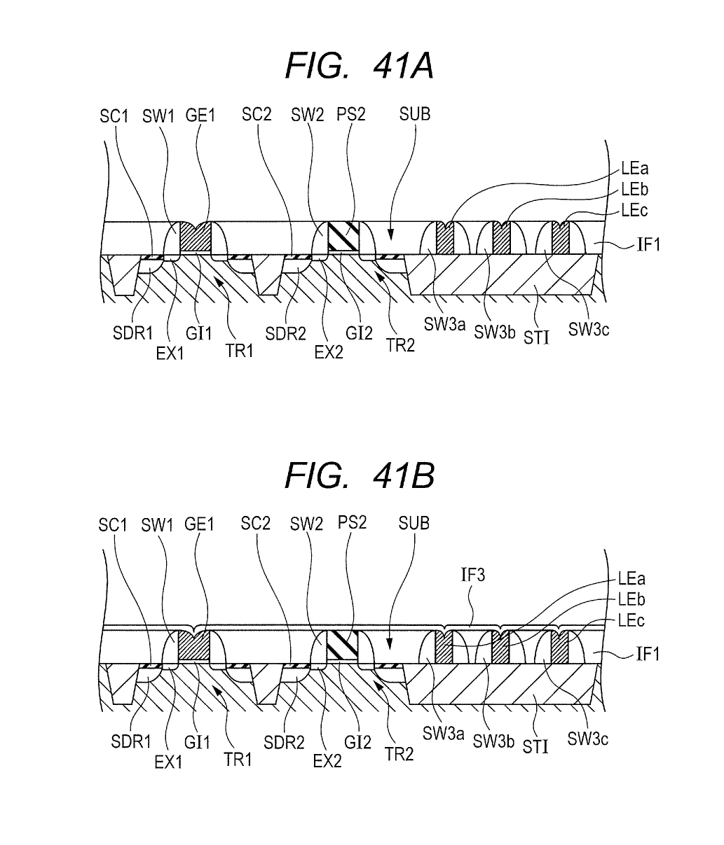

Next, the first metal film MF1 is etched. As a result, in the element formation region ER1, the first gate electrode GE1 is formed while, over the isolation film STI, the lower electrodes LEa, LEb, and LEc are formed (FIG. 41A). In the present embodiment, in etching the first metal film MF1, no resist film is formed over the substrate SUB. As shown in FIGS. 41A, the etching of the first metal film MF1 is sustained until the surface of the first insulating film IF1 is exposed. In the present embodiment, each of the first gate electrode GE1 and the lower electrodes LEa, LEb, and LEc is formed of the first metal film MF1. Thus, the first gate electrode GE1 and the lower electrodes LEa, LEb, and LEc are formed of the same material.

Next, over the substrate SUB, an insulating film IF3 is formed (FIG. 41B). Of the insulating film IF3, the capacitor insulating film CI is formed. The thickness of the insulating film IF3 may be controlled to be, e.g., 5 nm to 100 nm. The insulating film IF3 may be formed of a silicon dioxide film, a silicon nitride film, or a metal oxide (e.g., tantalum oxide, zirconium oxide, hafnium oxide, lanthanum oxide, or yttrium oxide). In the present embodiment, in forming the insulating film IF3, no resist film is formed over the substrate SUB. When the first metal film MF1 is etched until the first insulating film IF1 is exposed in the step shown in FIG. 41A, as shown in FIG. 41B, the insulating film IF3 is in contact with the surface of the first insulating film IF1 outside the region overlapping the first opening OP1 in planar view. Likewise, the insulating film IF3 is in contact with the surface of the first insulating film IF1 outside the region overlapping the third openings OP3a, OP3b, and OP3c in planar view.

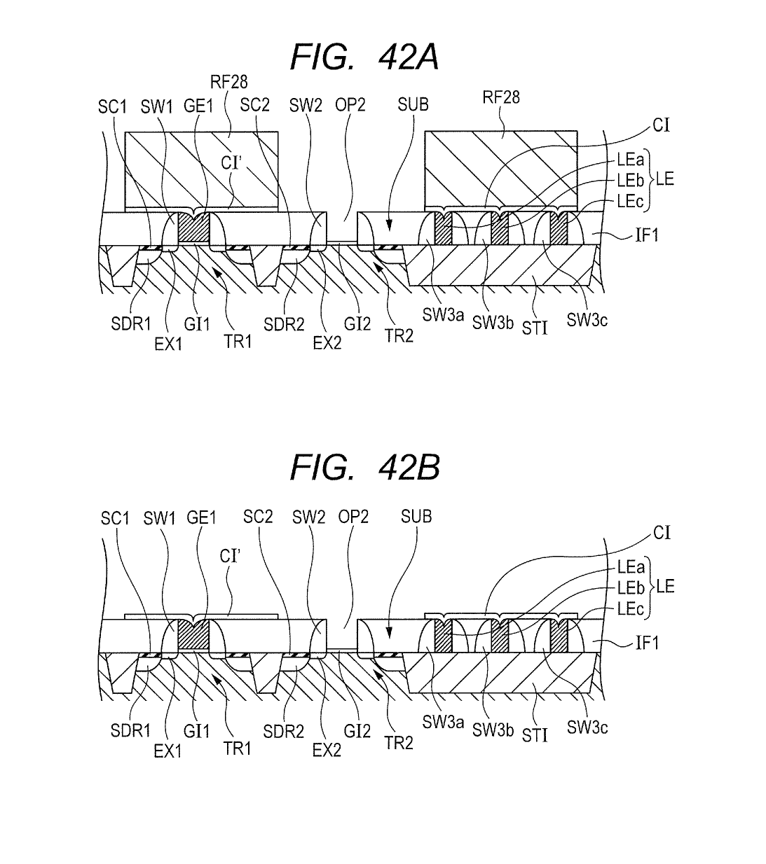

Next, over the element formation region ER1 and the isolation film STI, a resist film RF28 is formed over the substrate SUB, as shown in FIG. 42A. Then, using the resist film R28 as a mask, the insulating film IF3 is etched. In this manner, in the element formation region ER1, the insulating film CI′ is formed while, over the isolation film STI, the capacitor insulating film CI is formed (FIG. 42A). Then, by further performing etching, the second polysilicon film PS2 is removed. As a result, the second opening OP2 is formed inwardly of the second sidewall SW2 (FIG. 42A). The second opening OP2 is defined by the inner wall of the second sidewall SW2. In the present embodiment, as shown in FIG. 42A, the second gate insulating film GI2 is exposed through the second opening OP2. In the present embodiment, the area of the second opening OP2 in planar view is larger than the area of each of the third openings OP3a, OP3b, and OP3c in planar view.

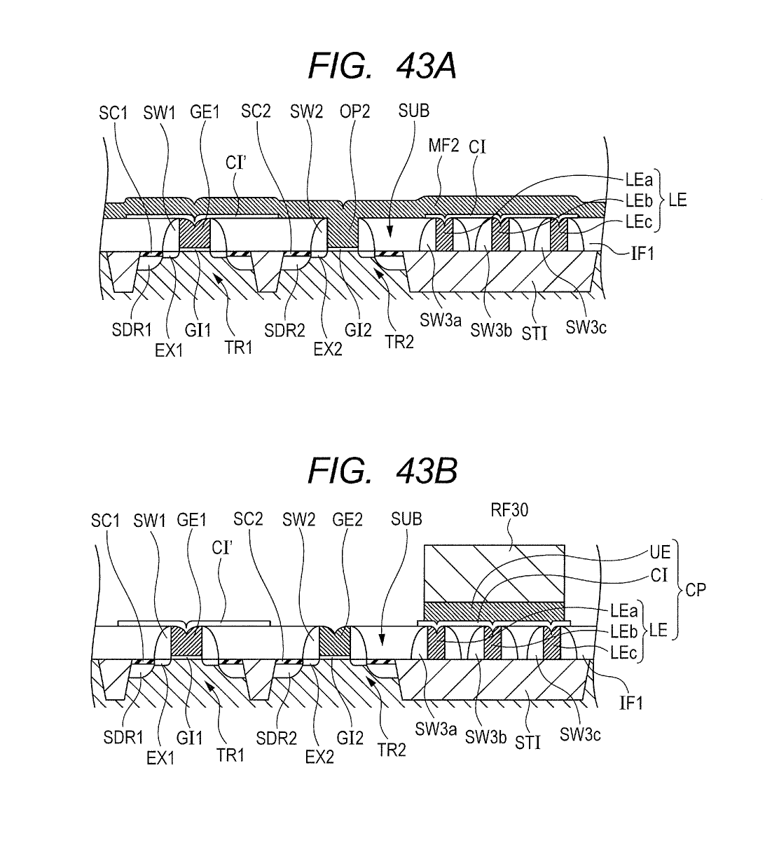

Next, the resist film RF28 is removed (FIG. 42b). Then, over the substrate SUB, the second metal film MF2 is formed. As a result, the second opening OP2 is filled with the second metal film MF2 (FIG. 43A). As shown in FIG. 43A, the second metal film MF2 is formed not only over the element formation region ER2, but also over the element formation region ER1 and the isolation film STI. The second metal film MF2 contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1). The thickness of the second metal film MF2 may be controlled to be, e.g., 5 nm to 200 nm over the lower electrodes LEa, LEb, and LEc.

Next, over the isolation film STI, a resist film RF30 is formed over the second metal film MF2, as shown in FIG. 43B. In the present embodiment, the resist film R30 is formed within the region overlapping the capacitor insulating film CI in planar view. Then, using the resist film RF30 as a mask, the second metal film MF2 is etched. In the etching, an etching rate is selected so as to stop the etching at the first insulating film IF1 and the insulating film CI′. As a result, in the element formation region ER2, the second gate electrode GE2 is formed while, over the isolation film STI, the upper electrode UE is formed (FIG. 43B). Thus, over the isolation film STI, the capacitor element CP is formed. In the present embodiment, each of the second gate electrode GE2 and the upper electrode UE is formed of the second metal film ME2. Thus, the second gate electrode GE2 and the upper electrode UE are formed of the same material. In the present embodiment, due to the resist film RF30, the upper electrode UE is formed within the region overlapping the capacitor insulating film CI in planar view.

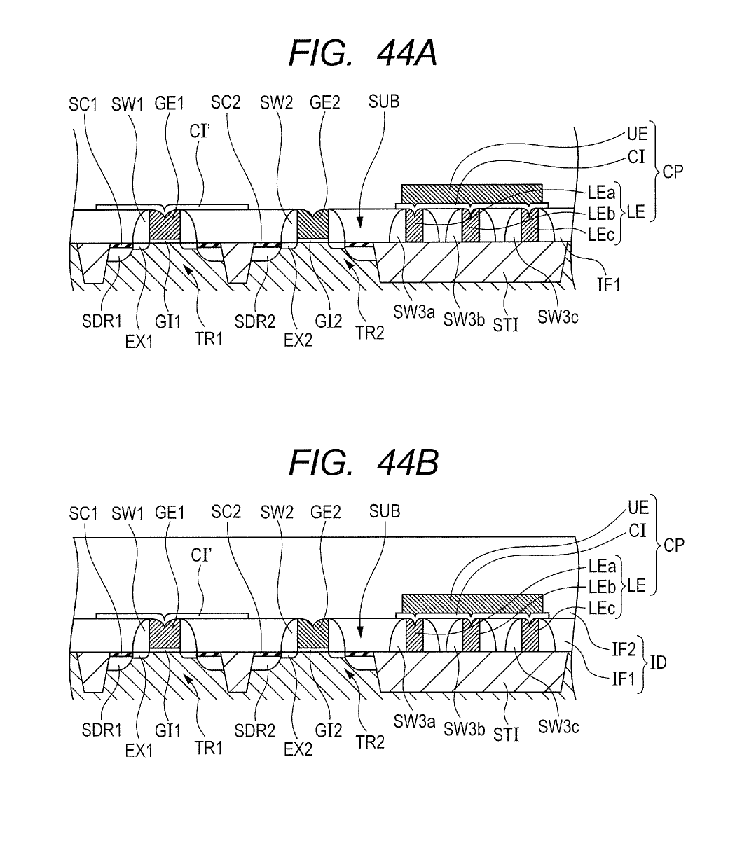

Next, the resist film RF30 is removed (FIG. 44A). Then, over the substrate SUB, the second insulating film IF2 is formed (FIG. 44B). The second insulating film IF2 covers the first gate electrode GE1, the second gate electrode GE2, and the upper electrode UE. In this manner, the interlayer insulating film ID is formed. The second insulating film IF2 may be formed of a silicon dioxide film or a low-dielectric-constant film.

Next, in the second insulating film IF2, contact holes (not shown) are formed. The contact holes are filled with conductive members to form the first contact plug CP1, the second contact plug CP2, the third contact plugs CP3a, CP3b, and CP3c, and the fourth contact plugs CP4. In this manner, the semiconductor device SD4a shown in FIG. 37A is formed.

In the present embodiment, each of the first gate electrode GE1 and the lower electrode LE is formed of the first metal film MF1. Each of the second gate electrode GE2 and the upper electrode UE is formed of the second metal film MF2. Accordingly, in the present embodiment, the capacitor element CP including the electrodes each containing a metal is formed in the smaller number of process steps.

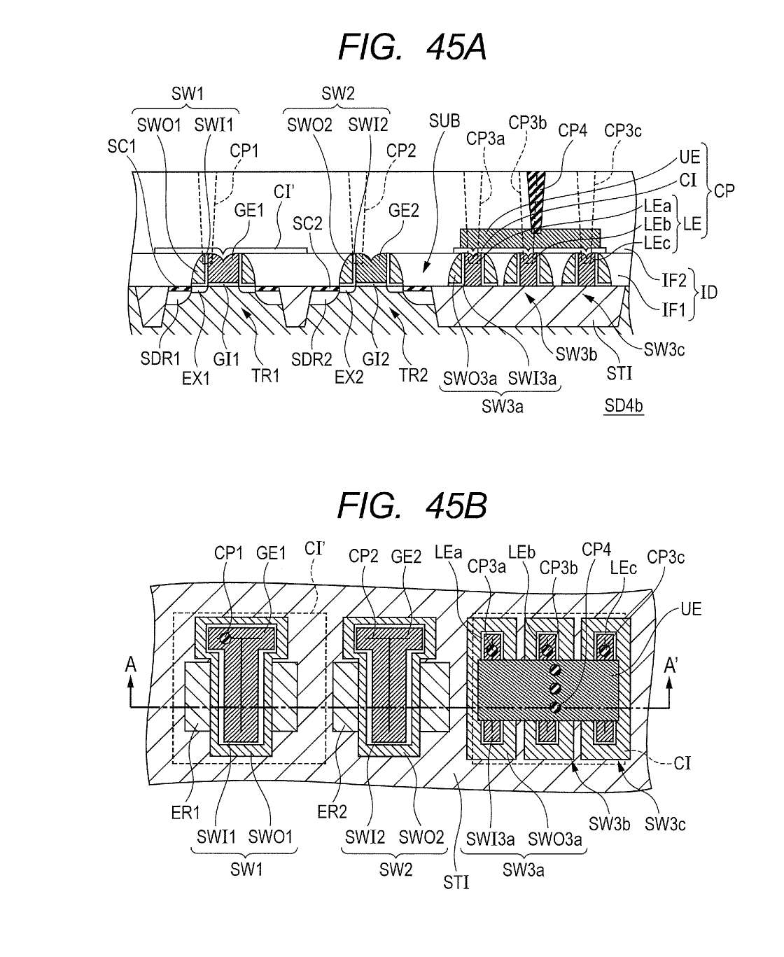

Next, using FIGS. 45A and 45B, a description will be given of another example of the present embodiment. FIG. 45A is a cross-sectional view showing a semiconductor device SD4b in the other example of the fourth embodiment. FIG. 45B is a two-dimensional perspective view of the semiconductor device SD4b in the present embodiment. FIG. 45A is a cross-sectional view along the line A-A′ of FIG. 45B. The semiconductor device SD4b shown in FIGS. 45A and 45B has the same configuration as that of the semiconductor device SD4a shown in FIGS. 37A and 37B except that the first sidewall SW1 includes the sidewalls SWI1 and SWO1, the second sidewall SW2 includes the sidewalls SWI2 and SWO2, and the third sidewall SW3a includes the sidewalls SWI3 and SWO3 (the same holds true for the third sidewalls SW3b and SW3c). The first sidewall SW1, the second sidewall SW2, and the third sidewall SW3a in the semiconductor device SD4b shown in FIGS. 45A and 45B have the same configurations as those of the first sidewall SW1, the second sidewall SW2, and the third sidewall SW3 in the semiconductor device SD3b shown in FIGS. 33A and 33B (the same holds true for the third sidewalls SW3b and SW3c). A method of forming the first sidewall SW1, the second sidewall SW2, and the third sidewalls SW3a, SW3b, and SW3c in the semiconductor device SD4b shown in FIGS. 45A and 45B includes the same steps shown in FIGS. 34A and 34B.

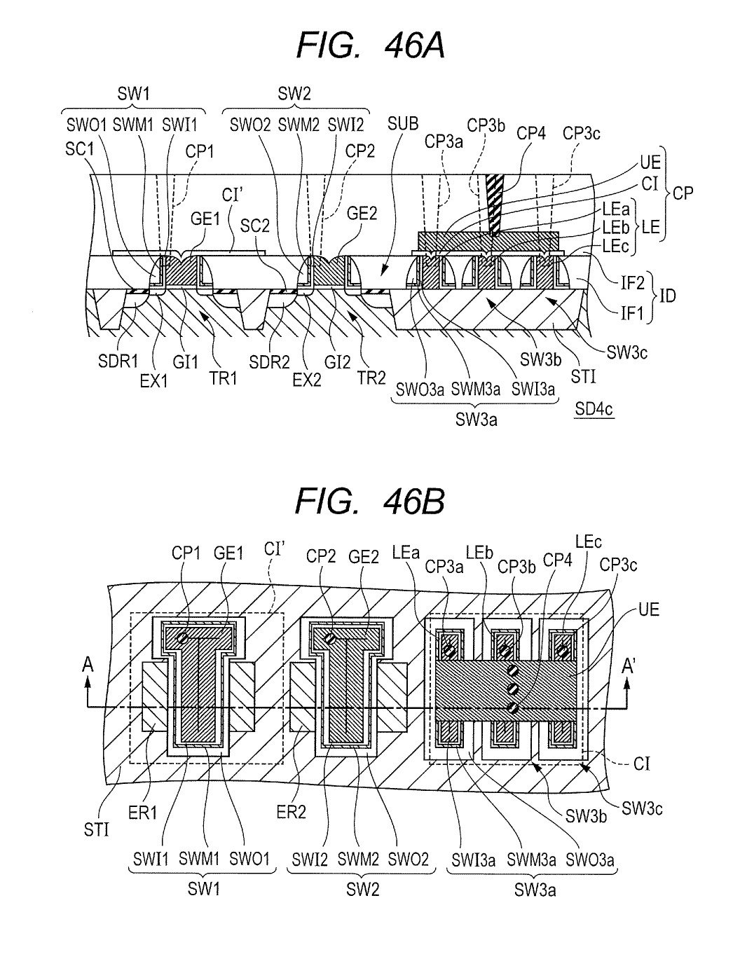

Next, using FIGS. 46A and 46B, a description will be given of still another example of the present embodiment. FIG. 46A is a cross-sectional view showing a semiconductor device SD4c in the still other example of the fourth embodiment. FIG. 46B is a two-dimensional perspective view of the semiconductor device SD4c in the present embodiment. FIG. 46A is a cross-sectional view along the line A-A′ of FIG. 46B. The semiconductor device SD4c shown in FIGS. 46A and 46B has the same configuration as that of the semiconductor device SD4a shown in FIGS. 37A and 37B except that the first sidewall SW1 includes the sidewalls SWI1, SWM1, and SWO1, the second sidewall SW2 includes the sidewalls SWI2, SWM2, and SWO2, and the third sidewall SW3a includes the sidewalls SWI3, SWM3, and SWO3 (the same holds true for the third sidewalls SW3b and SW3c). The first sidewall SW1, the second sidewall SW2, and the third sidewall SW3a in the semiconductor device SD4c shown in FIGS. 46A and 46B have the same configurations as those of the first sidewall SW1, the second sidewall SW2, and the third sidewall SW3 in the semiconductor device SD3c shown in FIGS. 35A and 35B (the same holds true for the third sidewalls SW3b and SW3c). A method of forming the first sidewall SW1, the second sidewall SW2, and the third sidewalls SW3a, SW3b, and SW3c in the semiconductor device SD4c shown in FIGS. 46A and 46B includes the same steps as the steps shown in FIGS. 36A and 36B.

In the present embodiment, the first gate electrode GE1 of the n-type first transistor TR1 and the lower electrode LE are formed of the same material (first metal film MF1) and the second gate electrode GE2 of the p-type second transistor TR2 and the upper electrode UE are formed of the same material (second metal film MF2). In another example, it may also be possible that the second gate electrode GE2 of the p-type second transistor TR2 and the lower electrode LE are formed of the same material (first metal film MF1) and the first gate electrode GE1 of the n-type first transistor TR1 and the upper electrode UE are formed of the same material (second metal film MF2). In either case, the first metal film MF1 forming the lower electrode LE is embedded in the first opening OP1 of the first transistor TR1 or in the second opening OP2 of the second transistor TR2 before the second metal film MF2 is embedded.

In the present embodiment, in the step shown in FIG. 41A, no resist film is formed over the element formation region ER1. In another example, it may also be possible that, in the same manner as in the step shown in FIG. 18A in the second embodiment, the resist film R16 may also be formed over the element formation region ER1. In this case, the semiconductor device SD4a in the present embodiment can include the first gate electrode GE1 and the insulating film CI′ in the semiconductor device SD2a in the second embodiment.

In the present embodiment, each of the first gate electrode GE1, the second gate electrode GE2, the lower electrodes LEa, LEb, and LEc, and the upper electrode UE is formed in a single layer. In another example, it may also be possible that each of the first gate electrode GE1, the second gate electrode GE2, the lower electrodes LEa, LEb, and LEc, and the upper electrode UE is formed in a plurality of layers. In this case, the order in which the layers are stacked for the first gate electrode GE1 is the same as the order in which the layers are stacked for the lower electrodes LEa, LEb, and LEc, while the order in which the layers are stacked for the second gate electrode GE2 is the same as the order in which the layers are stacked for the upper electrode UE.

In the present embodiment, each of the first gate electrode GE1, the second gate electrode GE2, the lower electrodes LEa, LEb, and LEc, and the upper electrode UE contains a metal. In another example, it may also be possible that each of the first gate electrode GE1, the second gate electrode GE2, the lower electrodes LEa, LEb, and LEc, and the upper electrode UE is formed of a material (e.g., polysilicon) other than a metal. In this case also, the first gate electrode GE1 and the lower electrodes LEa, LEb, and LEc are formed of the same material and the second gate electrode GE2 and the upper electrode UE are formed of the same material.

Note that, according to the foregoing embodiments, the following invention is disclosed.

(Note 1) A semiconductor device including a first transistor formed over a substrate, a second transistor formed over the substrate and having a channel of a conductivity type different from that of a channel of the first transistor, and an interlayer insulating film formed over the substrate to cover the first transistor and the second transistor. The first transistor includes a first gate electrode formed over the substrate, and a first source/drain region formed in a surface of the substrate in lateral relation to the first gate electrode. The second transistor includes a second gate electrode formed over the substrate, and a second source/drain region formed in the surface of the substrate in lateral relation to the second gate electrode. The interlayer insulating film includes a first insulating film formed over the first source/drain region and the second source/drain region, and a second insulating film formed over the first insulating film. The semiconductor device further includes a first contact plug extending through the second insulating film to reach the first gate electrode, a second contact plug extending through the second insulating film to reach the second gate electrode, an isolation film formed in the surface of the substrate, and a capacitor element formed within a region overlapping the isolation film in planar view. The capacitor element includes a lower electrode, an upper electrode formed over the lower electrode, and a capacitor insulating film formed between the lower electrode and the upper electrode. The lower electrode and the upper electrode are formed over the first insulating film to be embedded in the second insulating film.

(Note 2) A semiconductor device including a first transistor formed over a substrate, a second transistor formed over the substrate and having a channel of a conductivity type different from that of a channel of the first transistor, and an interlayer insulating film formed over the substrate to cover the first transistor and the second transistor. The first transistor includes a first gate electrode formed over the substrate, and a first source/drain region formed in a surface of the substrate in lateral relation to the first gate electrode. The second transistor includes a second gate electrode formed over the substrate, and a second source/drain region formed in the surface of the substrate in lateral relation to the second gate electrode. The semiconductor device further includes a first contact plug extending through the interlayer insulating film to reach the first gate electrode, a second contact plug extending through the interlayer insulating film to reach the second gate electrode, an isolation film formed in the surface of the substrate, and a capacitor element formed within a region overlapping the isolation film in planar view. The capacitor element includes a lower electrode, an upper electrode formed over the lower electrode, and a capacitor insulating film formed between the lower electrode and the upper electrode. The lower electrode and the upper electrode are formed to be embedded in the interlayer insulating film. The lower electrode and the first gate electrode are formed of the same material. The upper electrode and the second gate electrode are formed of the same material.

(Note 3) A semiconductor device including a first transistor formed over a substrate, a second transistor formed over the substrate and having a channel of a conductivity type different from that of a channel of the first transistor, and an interlayer insulating film formed over the substrate to cover the first transistor and the second transistor. The first transistor includes a first gate electrode formed over the substrate, and a first source/drain region formed in a surface of the substrate in lateral relation to the first gate electrode. The second transistor includes a second gate electrode formed over the substrate, and a second source/drain region formed in the surface of the substrate in lateral relation to the second gate electrode. The interlayer insulating film includes a first insulating film formed over the first source/drain region and the second source/drain region, and a second insulating film formed over the first insulating film. The semiconductor device further includes a first contact plug extending through the second insulating film to reach the first gate electrode, a second contact plug extending through the second insulating film to reach the second gate electrode, an isolation film formed in the surface of the substrate, a capacitor element formed within a region overlapping the isolation film in planar view, and a sidewall formed over the isolation film to be embedded in the first insulating film. The capacitor element includes a lower electrode, an upper electrode formed over the lower electrode, and a capacitor insulating film formed between the lower electrode and the upper electrode. The first insulating film is formed with an opening defined by an inner wall of the sidewall, and the lower electrode is formed to be embedded in the opening.

While the invention achieved by the present inventors has been specifically described heretofore based on the embodiments thereof, the present invention is not limited to the foregoing embodiments. It will be appreciated that various changes and modifications can be made in the invention within the scope not departing from the gist thereof.

What is claimed is:

1. A semiconductor device, comprising:
a first transistor formed over a substrate;
a second transistor formed over the substrate and having a channel of a conductivity type different from that of a channel of the first transistor; and
an interlayer insulating film formed over the substrate to cover the first transistor and the second transistor,
wherein the first transistor includes:
a first gate electrode formed over the substrate and containing a metal; and
a first source/drain region formed in a surface of the substrate in lateral relation to the first gate electrode,
wherein the second transistor includes:
a second gate electrode formed over the substrate and containing a metal; and
a second source/drain region formed in the surface of the substrate in lateral relation to the second gate electrode, and
wherein the interlayer insulating film includes:
a first insulating film formed over the first source/drain region and the second source/drain region; and
a second insulating film formed over the first insulating film,
the semiconductor device further comprising:
a first contact plug extending through the second insulating film to reach the first gate electrode;
a second contact plug extending through the second insulating film to reach the second gate electrode;
an isolation film formed in the surface of the substrate; and
a capacitor element formed within a region overlapping the isolation film in planar view,
wherein the capacitor element includes:
a lower electrode containing a metal;
an upper electrode formed over the lower electrode and containing a metal; and
a capacitor insulating film formed between the lower electrode and the upper electrode, and
wherein the lower electrode and the upper electrode are formed over the first insulating film to be embedded in the second insulating film.

2. A semiconductor device according to claim 1,
wherein each of the lower electrode and the upper electrode is formed in a flat plate shape.

3. A semiconductor device according to claim 2,
wherein an edge portion of the lower electrode in planar view is in direct contact with the second insulating film, and
wherein an edge portion of the upper electrode in planar view is in direct contact with the second insulating film.

4. A semiconductor device according to claim 1, further comprising:
a first gate insulating film formed between the substrate and the first gate electrode;
a second gate insulating film formed between the substrate and the second gate electrode;
a first sidewall formed in the first insulating film so as to surround the first gate insulating film in planar view; and
a second sidewall formed in the first insulating film so as to surround the second gate insulating film in planar view,
wherein the first insulating film is formed with a first opening defined by an inner wall of the first sidewall, the first gate electrode is formed to be embedded in the first opening, and an edge portion of the first gate electrode in planar view overlies the first insulating film outside a region overlapping the first opening in planar view, and
wherein the first insulating film is formed with a second opening defined by an inner wall of the second sidewall, the second gate electrode is formed to be embedded in the second opening, and an edge portion of the second gate electrode in planar view overlies the first insulating film outside a region overlapping the second opening in planar view.

5. A semiconductor device according to claim 4,
wherein a film thickness of the lower electrode is generally equal to a film thickness of a portion of the first gate electrode which overlies the first insulating film outside the region overlapping the first opening in planar view, and
wherein a film thickness of the upper electrode is generally equal to a film thickness of a portion of the second gate electrode which overlies the first insulating film outside the region overlapping the second opening in planar view.

6. A semiconductor device according to claim 4, further comprising:
a third insulating film formed between the first gate electrode and the second insulating film,
wherein the capacitor insulating film and the third insulating film are formed of the same material.

7. A semiconductor device, comprising:
a first transistor formed over a substrate;
a second transistor formed over the substrate and having a channel of a conductivity type different from that of a channel of the first transistor; and
an interlayer insulating film formed over the substrate to cover the first transistor and the second transistor,
wherein the first transistor includes:
a first gate electrode formed over the substrate and containing a metal; and
a first source/drain region formed in a surface of the substrate in lateral relation to the first gate electrode, and
wherein the second transistor includes:
a second gate electrode formed over the substrate and containing a metal; and
a second source/drain region formed in the surface of the substrate in lateral relation to the second gate electrode,
the semiconductor device further comprising:
a first contact plug extending through the interlayer insulating film to reach the first gate electrode;
a second contact plug extending through the interlayer insulating film to reach the second gate electrode;
an isolation film formed in the surface of the substrate; and
a capacitor element formed within a region overlapping the isolation film in planar view,
wherein the capacitor element includes:
a lower electrode containing a metal;
an upper electrode formed over the lower electrode and containing a metal; and
a capacitor insulating film formed between the lower electrode and the upper electrode,
wherein the lower electrode and the upper electrode are formed to be embedded in the interlayer insulating film,
wherein the lower electrode and the first gate electrode are formed of the same material, and
wherein the upper electrode and the second gate electrode are formed of the same material.

8. A semiconductor device according to claim 7,
wherein each of the lower electrode and the first gate electrode and each of the upper electrode and the second gate electrode are formed of different elements or formed of a plurality of identical elements and having different composition ratios.

9. A semiconductor device according to claim 7,
wherein each of the lower electrode and the first gate electrode contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1), and
wherein each of the upper electrode and the second gate electrode contains at least one metal selected from the group consisting of Ta, Ti, W, and La or at least one metal compound selected from the group consisting of TaₓN₁₋ₓ, TiₓN₁₋ₓ, WₓN₁₋ₓ, TaₓC₁₋ₓ, TiₓC₁₋ₓ, WₓC₁₋ₓ, WₓSi₁₋ₓ, WₓSi_{y}Pt_{1-x-y}, and NiₓSi₁₋ₓ (0<x<1 and 0<y<1).

10. A semiconductor device, comprising:
a first transistor formed over a substrate;
a second transistor formed over the substrate and having a channel of a conductivity type different from that of a channel of the first transistor; and
an interlayer insulating film formed over the substrate to cover the first transistor and the second transistor,
wherein the first transistor includes:
a first gate electrode formed over the substrate and containing a metal; and
a first source/drain region formed in a surface of the substrate in lateral relation to the first gate electrode,
wherein the second transistor includes:
a second gate electrode formed over the substrate and containing a metal; and
a second source/drain region formed in the surface of the substrate in lateral relation to the second gate electrode, and
wherein the interlayer insulating film includes:
a first insulating film formed over the first source/drain region and the second source/drain region; and
a second insulating film formed over the first insulating film,
the semiconductor device further comprising:
a first contact plug extending through the second insulating film to reach the first gate electrode;
a second contact plug extending through the second insulating film to reach the second gate electrode;
an isolation film formed in the surface of the substrate;
a capacitor element formed within a region overlapping the isolation film in planar view; and
a sidewall formed over the isolation film to be embedded in the first insulating film,
wherein the capacitor element includes:
a lower electrode containing a metal;
an upper electrode formed over the lower electrode and containing a metal; and
a capacitor insulating film formed between the lower electrode and the upper electrode, and
wherein the first insulating film is formed with an opening defined by an inner wall of the sidewall, and the lower electrode is formed to be embedded in the opening.

11. A semiconductor device according to claim 10,
wherein an edge portion of the lower electrode in planar view overlies the first insulating film outside a region overlapping the opening in planar view.

12. A semiconductor device according to claim 11,
wherein the lower electrode is formed to be depressed along the opening.

13. A semiconductor device according to claim 12,
wherein a surface of the lower electrode is formed with a small opening defined by the depression of the lower electrode, and the upper electrode is formed within a region overlapping the small opening in planar view and has a portion overlapping the lower electrode in a height direction.

14. A semiconductor device according to claim 13, further comprising:
a third contact plug extending through the second insulating film to reach the lower electrode; and
a fourth contact plug extending through the second insulating film to reach the upper electrode,
wherein a height of a surface of a portion of the lower electrode which is coupled to the third contact plug is higher than a height of a surface of a portion of the upper electrode which is coupled to the fourth contact plug.

15. A semiconductor device according to claim 10,
wherein a plurality of the openings are defined by a plurality of the sidewalls, the lower electrode is embedded in each of the openings, the lower electrodes in the respective openings are electrically isolated from each other via the sidewalls and the first insulating film, and
wherein the upper electrode is formed over the first insulating film to be embedded in the second insulating film.

16. A semiconductor device according to claim 10,
wherein the capacitor insulating film is in contact with a surface of the first insulating film outside a region overlapping the opening in planar view.

17. A semiconductor device according to claim 15, further comprising:
a third insulating film formed between the first gate electrode and the second insulating film,
wherein the capacitor insulating film and the third insulating film are formed of the same material.

18. A semiconductor device according to claim 15,
wherein the capacitor insulating film is formed in the form of a sheet to cover each of the lower electrodes in the respective openings.

19. A method of manufacturing a semiconductor device, comprising the steps of:
forming an isolation film in a surface of a substrate;
forming a first gate insulating film and a second gate insulating film over a portion of the substrate in which the isolation film is not formed;
forming a first dummy gate electrode over the first gate insulating film and forming a second dummy gate electrode over the second gate insulating film;
forming a first sidewall surrounding the first gate insulating film in planar view and forming a second sidewall surrounding the second gate insulating film in planar view;
forming a first source/drain region in lateral relation to the first dummy gate electrode and forming a second source/drain region in lateral relation to the second dummy gate electrode;
forming a first interlayer insulating film over the substrate so as to cover the first sidewall, the second sidewall, the first source/drain region, and the second source/drain region therewith;
removing, after the formation of the first interlayer insulating film, the first dummy gate electrode to form a first opening defined by an inner wall of the first sidewall;
forming a first metal film over the substrate to fill the first opening with the first metal film;
forming a capacitor insulating film over the first metal film;
etching, after the formation of the capacitor insulating film, the first metal film and the capacitor insulating film to form a first gate electrode in the first opening and form a first capacitor electrode and the capacitor insulating film over the isolation film;
removing, after the formation of the first gate electrode and the first capacitor electrode, the second dummy gate electrode to form a second opening defined by an inner wall of the second sidewall;
forming a second metal film over the substrate to fill the second opening with the second metal film;
etching the second metal film to form a second gate electrode in the second opening and form a second capacitor electrode over the first capacitor electrode via the capacitor insulating film; and
forming a second interlayer insulating film over the substrate so as to cover the first gate electrode, the second gate electrode, and the second capacitor electrode therewith.

20. A method of manufacturing a semiconductor device according to claim 19,
wherein the first capacitor electrode is formed over the first interlayer insulating film.

21. A method of manufacturing a semiconductor device according to claim 19,
wherein, in the step of forming the first gate electrode, the first gate electrode is formed by not etching the first metal film and the capacitor insulating film in each of a first region overlapping the first opening in planar view and a peripheral region of the first region, and
wherein, in the step of forming the second gate electrode, the second gate electrode is formed by not etching the second metal film in each of a second region overlapping the second opening in planar view and a peripheral region of the second region.

22. A method of manufacturing a semiconductor device according to claim 19,
wherein the step of forming the first dummy gate electrode and the second dummy gate electrode includes the step of forming a third dummy electrode over the isolation film,
wherein the step of forming the first sidewall and the second sidewall includes the step of forming a third sidewall surrounding the third dummy electrode in planar view,
wherein the step of forming the first opening includes the step of simultaneously removing the third dummy electrode and the first dummy gate electrode to form a third opening defined by an inner wall of the third sidewall,
wherein the step of forming the first metal film includes the step of simultaneously filling the third opening and the first opening with the first metal film, and
wherein, in the step of forming the first capacitor electrode, the first capacitor electrode and the capacitor insulating film are formed by not etching the first metal film and the capacitor insulating film in each of a third region overlapping the third opening in planar view and a peripheral region of the third region.

23. A method of manufacturing a semiconductor device according to claim 22,
wherein, in the step of filling the third opening with the first metal film, the first metal film is formed to a thickness which allows roughness due to the third opening to remain in a surface of the first metal film.

24. A method of manufacturing a semiconductor device, comprising the steps of:
forming an isolation film in a surface of a substrate;
forming a first gate insulating film and a second gate insulating film over a portion of the substrate in which the isolation film is not formed;
forming a first dummy gate electrode over the first gate insulating film, forming a second dummy gate electrode over the second gate insulating film, and forming a third dummy electrode over the isolation film;
forming a first sidewall surrounding the first dummy gate electrode in planar view, forming a second sidewall surrounding the second dummy gate electrode in planar view, and forming a third sidewall surrounding the third dummy electrode in planar view;
forming a first source/drain region in lateral relation to the first sidewall and forming a second source/drain region in lateral relation to the second sidewall;
forming a first interlayer insulating film over the substrate so as to cover the first sidewall, the second sidewall, the third sidewall, the first source/drain region, and the second source/drain region therewith;
removing, after the formation of the first interlayer insulating film, the first dummy gate electrode to form a first opening defined by an inner wall of the first sidewall and removing the third dummy electrode to form a third opening defined by an inner wall of the third sidewall;
forming a first metal film over the substrate to fill the first opening with the first metal film and fill the third opening with the first metal film;
etching the first metal film to form a first gate electrode in the first opening and form a first capacitor electrode in the third opening;
forming, after the formation of the first gate electrode and the first capacitor electrode, a capacitor insulating film over the substrate;
removing, after the formation of the capacitor insulating film, the second dummy gate electrode to form a second opening defined by an inner wall of the second sidewall;
forming a second metal film over the substrate to fill the second opening with the second metal film;
etching the second metal film to form a second gate electrode in the second opening and form a second capacitor electrode over the first capacitor electrode via the capacitor insulating film; and
forming a second interlayer insulating film over the substrate so as to cover the first gate electrode, the second gate electrode, and the second capacitor electrode therewith.

25. A method of manufacturing a semiconductor device according to claim 24,
wherein, in the step of forming the third dummy electrode, a plurality of the third dummy electrodes are formed and, in the step of forming the third sidewall, a plurality of the third sidewalls surrounding the respective third dummy electrodes in planar view are formed,
wherein, in the step of forming the third opening, the third dummy electrodes corresponding to the respective third sidewalls are removed to form a plurality of the third openings defined by the respective inner walls of the third sidewalls,
wherein, in the step of forming the first metal film, each of the third openings is filled with the first metal film, and
wherein, in the step of forming the first capacitor electrode, the first metal film is etched to form the first capacitor electrode in each of the third openings.
